(19) United States
(12) Patent Application Publication
(10) Pub. No.: US 2012/0015472 A1
(43) Pub. Date: Jan. 19, 2012

(54) METHOD OF PRODUCING SOLAR CELL MODULE

(75) Inventors: Toshiharu Hayashi, Toyko (JP); Kazuhiko Yamasaki, Naka-gun (JP); Masahide Arai, Akita-shi (JP); Satoko Ogawa, Naka-gun (JP); Wataru Shinohara, Ogaki-shi (JP)

(73) Assignees: Sanyo Electric Co., Ltd., Moriguchi-shi, Osaka (JP); MITSUBISHI MATERIALS CORPORATION, Tokyo (JP)

(21) Appl. No.: 13/138,747

(22) PCT Filed: Mar. 24, 2010
(86) PCT No.: PCT/JP2010/055013

§ 371 Date: Sep. 23, 2011

(30) Foreign Application Priority Data
Mar. 30, 2009 (JP) 2009-082027
Mar. 30, 2009 (JP) 2009-082038
Mar. 30, 2009 (JP) 2009-082057
Mar. 30, 2009 (JP) 2009-082075
Mar. 30, 2009 (JP) 2009-082111
Mar. 30, 2009 (JP) 2009-082130

(51) Int. Cl. H01L 31/18

(52) U.S. Cl. 438/80; 257/E31.126

(57) ABSTRACT

On a substrate is formed a transparent and conductive front electrode layer, on which is formed a photoelectric conversion unit that generates an electric power by a light. On the photoelectric conversion unit is formed a transparent and conductive film, on which a silver-containing back electrode layer. On the back electrode layer is formed further a back electrode reinforcing film formed by UV-irradiation of, or by heating of, or by heating after UV-irradiation of a layer that is obtained by applying a composition for reinforcing film on the back electrode layer with a wet coating method.

Provided are a solar cell module with small deterioration of power generation efficiency even under a high humidity environment and with stable performance for a long period of time and a method that can produce the solar cell module more cheaply.

### TECHNICAL FIELD

The present invention relates to a method of producing a solar cell module based on silicon with a type of thin film or multi-junction. More specifically, the present invention relates to a method of producing a solar cell module arranged with a barrier film having excellent reliability in such properties as weatherability, water resistance, and moisture resistance with a drastically simplified producing process.

### BACKGROUND ART

Recently, from a viewpoint of environmental protection, research and development on clean energy is progressing. Among them, a solar cell is receiving attention because sunlight is infinite as the source of energy and is pollution free. There are a variety of forms in a solar cell; the representative of them is a silicon solar cell based on single crystal silicon, polycrystalline silicon, amorphous silicon, and the like. There are also solar cells based on a compound; the representative of them is a CIS solar cell based on a compound such as Cu, In, Ga, Al, Se, and S in place of silicon. On the other hand, these solar cells are classified based on their forms into a type of thin film, multi-junction (tandem type), and so on. Especially, solar cells, based on a thin film, an amorphous silicon, a compound, and the like, are expected to be a main stream of a future solar cell because they are relatively cheap and easy to have a large area.

Meanwhile, the properties requested in the solar cells as mentioned above are not only high conversion efficiency of a photo energy to an electric energy but also sufficient durability, weatherability, and the like in their composition and material structure because a solar cell is generally used outdoor. For example, a solar cell is requested to generate an electric power stably over a long period of time, at least for 20 to 30 years, under outdoor environment; and thus, it is requested to have not only excellent scratch resistance, shock absorption, and the like but also such properties as high protection abilities in penetration of water (water resistance), oxygen, and moisture (moisture resistance), in surface fouling, and in accumulation of dusts. Especially, a solar cell element that constitutes a solar cell is susceptible to effects of temperature and moisture; and thus, decrease of power generation efficiency becomes a serious problem in the use under high temperature and moisture. It is assumed that this is mainly caused by deterioration of a solar cell element itself as well as increase of short-circuit current of the element due to elution and migration of a metal ion from a collector electrode that constitutes a solar cell element; and thus, various technologies have been proposed to overcome such function deterioration.

However, the actual situation is that there is no substance, material, or the like that satisfies all the foregoing conditions in a solar cell composition. For example, a fluorinated resin sheet, proposed as a surface protective layer of a solar cell module, is better in such properties as plasticity, impact resistance, lightness, and cost, but is poorer in such properties as heat resistance, water resistance, and moisture resistance, as compared with a glass and the like. In addition, a filler layer that constitutes a solar cell module generates a decomposition product by alteration or degradation during its use for a long period of time thereby causing such a problem as deterioration of solar cell performance.

In order to solve these problems, disclosed is a solar cell module comprising; a barrier layer that is arranged on surface of a solar cell element and prohibits permeation of at least a water vapor, an oxygen gas, a degradation product, or one or more kinds of an additive; a filler layer that is arranged on both surfaces of a solar cell element including the barrier layer and is comprised of a coat film or a print film formed with a filler composition mainly comprised of a filler vehicle; a weather resistant layer that is arranged on the filler layer formed on both front and back surfaces thereof and comprised of a coat film or a print film formed with a resin composition mainly comprised of a resin vehicle; and one or more of an anti-fouling or a UV-shielding layer formed on any of the foregoing layers or therebetween (see for example, Patent Document 1). In this solar cell module, an electromotive force member, such as a crystalline silicon having a pn junction structure and the like, an amorphous silicon having a p-i-n junction structure and the like, and a compound semiconductor, is formed on a glass substrate, a plastic substrate, or the like to form a solar cell element; and a barrier layer is formed on a surface opposite to the substrate that constitutes the solar cell element, namely on surface of the electromotive force member that constitutes the solar cell element. It is mentioned that, with this, excellent effects in such properties as weatherability, heat resistance, water resistance, moisture resistance, wind pressure resistance, and hail resistance can be realized.
Patent Document 1: Japanese Patent Application Laid-Open No. 2001-217441 (claim 1 and paragraph [0005])

### DISCLOSURE OF INVENTION

### Problems to be Solved by the Invention

However, the barrier layer that constitutes the invention of Patent Document 1 is a vapor-deposited inorganic oxide film formed by such method as a physical vapor deposition method such as a vacuum vapor deposition method and a sputtering method, and a chemical vapor deposition method such as a plasma chemical vapor deposition method and a photochemical vapor deposition method. Accordingly, a cumbersome process is necessary in manufacturing thereof so that there have been a problem of high running cost.

An object of the present invention is to provide a method of producing a solar cell module with small deterioration of power generation efficiency even under high moisture environment and with stable performance for along period of time by using a wet coating method with avoiding a vacuum process such as a vacuum vapor deposition method and a sputtering method as far as possible so that manufacturing cost may be decreased.

### Means for Solving the Problems

A first aspect of the present invention provides a method of producing a solar cell module, wherein the method comprises:

a step of forming a transparent and conductive front electrode layer on a substrate,

a step of forming, on the front electrode layer, one, or two or more of a photoelectric conversion unit that generates an electric power by a light,

a step of forming, on the photoelectric conversion unit, a transparent and conductive film,

a step of forming, on the transparent and conductive film, a back electrode layer, and

a step of forming, on the back electrode layer, a back electrode reinforcing film by UV-irradiation of, or by heating of, or by heating after UV-irradiation of a layer that is obtained by applying a composition for reinforcing film with a wet coating method.

A fourth aspect of the present invention is based on the first aspect, wherein the method further includes, after the step of forming the back electrode reinforcing film, a step of forming, on the reinforcing film, a barrier film by UV-irradiation of, or by heating of, or by heating after UV-irradiation of a layer that is obtained by applying a composition for barrier film on the reinforcing film with a wet coating method.

A seventeenth aspect of the present invention provides a method of producing a solar cell module, wherein the method comprises:

a step of forming a transparent and conductive front electrode layer on a substrate,

a step of forming, on the front electrode layer, one, or two or more of a photoelectric conversion unit that generates an electric power by a light,

a step of forming, on the photoelectric conversion unit, a transparent and conductive film,

a step of forming, on the transparent and conductive film, a back electrode layer, and

a step of forming, on the back electrode layer, a barrier film by UV-irradiation of, or by heating of, or by heating after UV-irradiation of a layer that is obtained by applying a composition for barrier film with a wet coating method.

### Advantages

The method of producing a solar cell module according to the first aspect of the present invention includes:

a step of forming a transparent and conductive front electrode layer on a substrate,

a step of forming, on the front electrode layer, one, or two or more of a photoelectric conversion unit that generates an electric power by a light,

a step of forming, on the photoelectric conversion unit, a transparent and conductive film,

a step of forming, on the transparent and conductive film, a back electrode layer, and

a step of forming, on the back electrode layer, a back electrode reinforcing film by UV-irradiation of, or by heating of, or by heating after UV-irradiation of a layer that is obtained by applying a composition for reinforcing film with a relatively convenient wet coating method. A hard and fine back electrode reinforcing film adherable strongly to the back electrode layer can be obtained with a wet coating method relatively easily and in a short time. As a result, the back electrode reinforcing film can protect electromagnetic properties and corrosion resistance of the back electrode layer. In addition, even when a separation groove that penetrates from the photoelectric conversion unit to the back electrode reinforcing film through the transparent and conductive film and the back electrode layer is formed by a laser scriber, delamination or drop off of each layer and film after formation of the separation groove can be avoided. Accordingly, the back electrode reinforcing film can be formed by a convenient method without using expensive and complicated manufacturing equipment having many controlling items, such as vacuum equipment. As a result, a running cost can be made cheap, and in addition, a solar cell module can be produced relatively easily even the module is made larger.

The method of producing a solar cell module according to the fourth aspect of the present invention is characterized in that the method further includes a step of forming, after the step of forming the back electrode reinforcing film, on the reinforcing film, a barrier film by UV-irradiation of, or by heating of, or by heating after UV-irradiation of a layer that is obtained by applying a composition for barrier film on the reinforcing film with a wet coating method. Because the barrier film is formed by a wet coating method, materials having different properties can be laminated-in layers intentionally. As a result, a solar cell having excellent reliability on such properties as weatherability, water resistance, and moisture resistance can be produced.

The method of producing a solar cell module according to the seventeenth aspect of the present invention includes:

a step of forming a transparent and conductive front electrode layer on a substrate,

a step of forming, on the front electrode layer, one, or two or more of a photoelectric conversion unit that generates an electric power by a light,

a step of forming, on the photoelectric conversion unit, a transparent and conductive film,

a step of forming, on the transparent and conductive film, a back electrode layer, and

a step of forming, on the back electrode layer, a barrier film by UV-irradiation of, or by heating of, or by heating after UV-irradiation of a layer that is obtained by applying a composition for barrier film with a wet coating method. Because the barrier film is formed by a wet coating method, materials having different properties can be laminated in layers intentionally. As a result, a solar cell having excellent reliability on such properties as weatherability, water resistance, and moisture resistance can be produced.

According to the method of producing a solar cell module of the present invention, a vacuum process such as a vacuum vapor deposition method and a sputtering method can be avoided as far as possible by using a wet coating method; and thus, a solar cell with small deterioration of power generation efficiency even under a high humidity environment and with stable performance for a long period of time can be produced more cheaply and without complicated processes.

### BRIEF DESCRIPTION OF DRAWINGS

FIG. 1 is an extended cross section view showing composition of an essential part of the solar cell module according to the first embodiment of the present invention.

FIG. 2 is a cross section view showing composition of the said solar cell module.

FIG. 3 is a cross section view, corresponding to FIG. 2, showing composition of the solar cell module according to another embodiment of the present invention.

FIG. 4 is an extended cross section view showing composition of an essential part of the solar cell module according to the second embodiment of the present invention.

FIG. 5 is a cross section view showing composition of the solar cell module.

FIG. 6 is a cross section view, corresponding to FIG. 5, showing composition of the solar cell module according to another embodiment of the present invention.

FIG. 7 is an extended cross section view showing composition of an essential part of the solar cell module according to the third embodiment of the present invention.

FIG. 8 is a cross section view showing composition of the said solar cell module.

FIG. 9 is a cross section view, corresponding to FIG. 8, showing composition of the solar cell module according to another embodiment of the present invention.

### BEST MODES FOR CARRYING OUT THE INVENTION

### First Embodiment

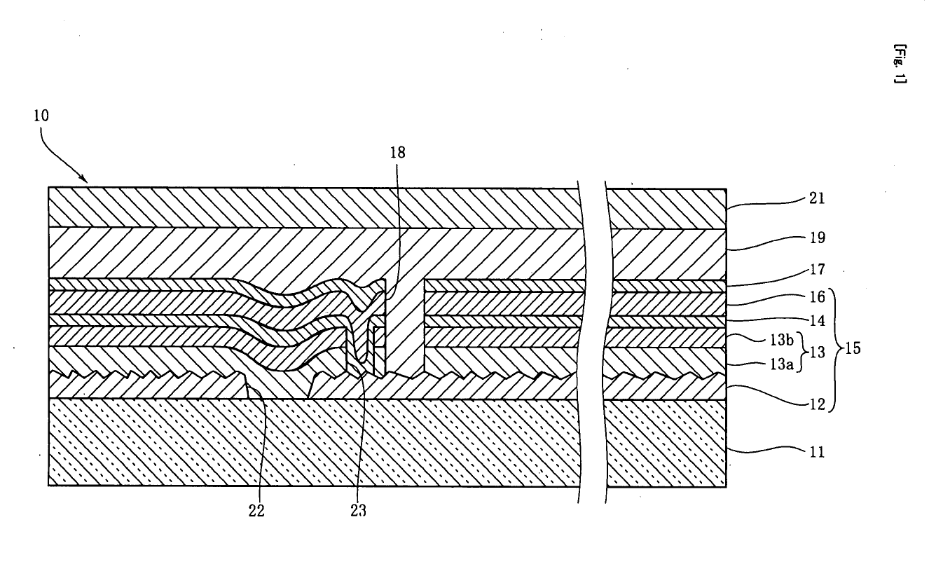

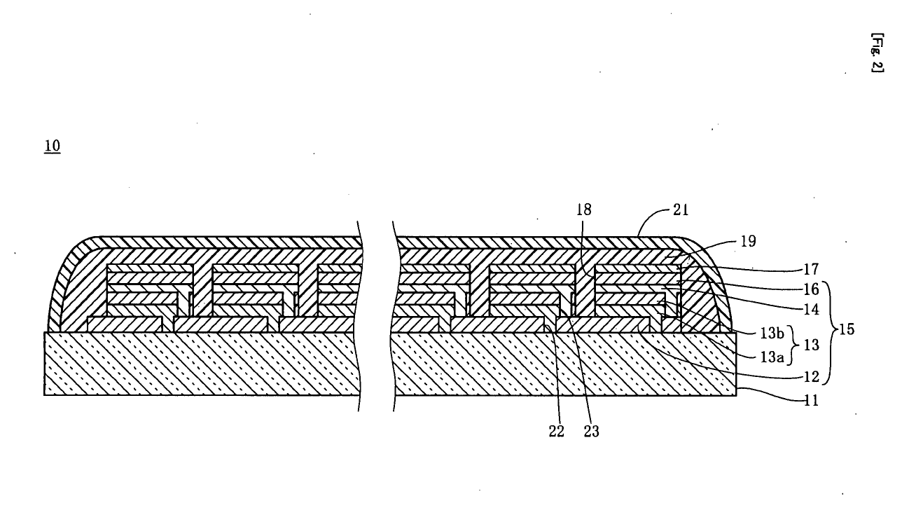

A first embodiment of the present invention is explained based on FIG. 1 to FIG. 3. As shown in FIG. 1 and FIG. 2, the thin film silicon solar cell module 10 is arranged with the substrate 11 having an insulative surface and the photovoltaic element 15 that is laminated on the substrate 11. The photovoltaic element 15 is formed on the substrate 11 by laminating the front electrode layer 12, the photoelectric conversion unit 13, the transparent and conductive film 14, and the back electrode layer 16, in this order. Further arranged is the back electrode reinforcing film 17 formed by UV-irradiation of, or by heating of, or by heating after UV-irradiation of a layer that is laminated on the photovoltaic element 15 and obtained by applying a composition for reinforcing film with a wet coating method; and the structure that is further arranged with the back film 21 laminated on the reinforcing film 17 via the filler layer 19 is included. In this embodiment, on the backside opposite to the incident light side of the substrate 11 are arranged the photovoltaic element 15, the back electrode reinforcing film 17, the filler layer 19, and the back film 21, in this order.

As shown in FIG. 1 and FIG. 2, as the substrate 11, a translucent substrate selected from any of a glass, a ceramics, and a polymer material, or a transparent laminate comprised of two or more kinds selected from the group consisting of a glass, a ceramics, a polymer material, and a silicon may be used. Example of the polymer substrate includes a substrate formed with an organic polymer such as polyimide and PET (polyethylene terephthalate).

The front electrode layer 12 is a transparent and conductive film that transmits an incident light from the substrate 11 side to the photoelectric conversion unit 13 and that has a function as another electrode of a photovoltaic element. Example of the front electrode layer 12 includes a film of ITO (composite oxides of indium oxide-tin oxide), ATO (composite oxides of antimony oxide-tin oxide), SnO₂ (tin oxide), ZnO (zinc oxide), IZO (composite oxides of indium oxide-zinc oxide), and AZO (composite oxides of aluminum oxide-zinc oxide). Further, the front electrode layer 12 maybe composed of one, or two or more of metal oxides selected from the group consisting of ZnO, In₂O₃, SnO₂, CdO, TiO₂, CdIn₂O₄, Cd₂SnO₄, and Zn₂SnO₄, wherein any of the metal oxides is doped with any of Sn, Sb, F, Ga, and Al. The front electrode layer 12 maybe formed with a heretofore known method such as, for example, a thermal CVD method, a sputtering method, a vacuum deposition method, and a wet coating method; wherein the method is not particularly restricted. When the front electrode layer 12 is formed with a wet coating method, procedures similar to those of a wet coating method to form the transparent and conductive film 14, as described later, are used. Meanwhile, the foregoing ZnO is suitable as a material for the front electrode layer 12 because ZnO has plasticity, with high light transmittance and low resistivity, and is of low cost. The front electrode layer 12 that is formed on the substrate 11 by the method as mentioned above is patterned in strips by a laser scriber. Namely, separation process is conducted to form the separation groove 22. The separation groove 22 may be formed by using the same instrument as that used for the separation groove 18, which will be described later.

On the front electrode layer 12 is formed the photoelectric conversion unit 13 that generates an electric power by a light. The photoelectric conversion unit 13 is composed of a non-crystalline (amorphous) silicon semiconductor or a crystalline silicon semiconductor. In this embodiment, the photoelectric conversion unit 13 has the first photoelectric conversion unit 13a formed by an amorphous silicon semiconductor and the second photoelectric conversion unit 13b formed by a microcrystalline silicon semiconductor. Specifically, the first photoelectric conversion unit 13a is a p-i-n type amorphous silicon layer, laminated from the side of the substrate 11 with a p-type a-Si (amorphous silicon), an i-type a-Si (amorphous silicon), and an n-type a-Si (amorphous silicon), in this order. The second photoelectric conversion unit 13b is a p-i-n type microcrystalline silicon layer, laminated from the side of the first photoelectric conversion unit 13a with a p-type μc-Si (microcrystalline silicon), an i-type μc-Si (microcrystalline silicon), and an n-type μc-Si (microcrystalline silicon), in this order. A tandem type solar cell module using the photoelectric conversion units of an i-type. a-Si (the first photoelectric conversion unit 13a) and an i-type μc-Si (the second photoelectric conversion unit 13b), as mentioned above, has a laminated structure of two semiconductors having different light absorption wavelengths; and thus a solar spectrum can be utilized effectively. In this description, the term “microcrystalline” means not only a perfect crystalline state but also a crystalline state partly containing a non-crystalline state (amorphous state). The photoelectric conversion unit 13, formed on the front electrode layer 12 by the method as mentioned above, is patterned in strips by a laser scriber. Namely, separation process is conducted to form the separation groove 23. The separation groove 23 can be formed by using the same instrument as that used for the separation groove 18, which will be described later.

Meanwhile, the photoelectric conversion unit can have any embodiment: a single-junction type comprised of any one of the amorphous silicon layer or the microcrystalline silicon layer and a multi-junction type comprised of a plurality of any one of the amorphous silicon layer and the microcrystalline silicon layer or both.

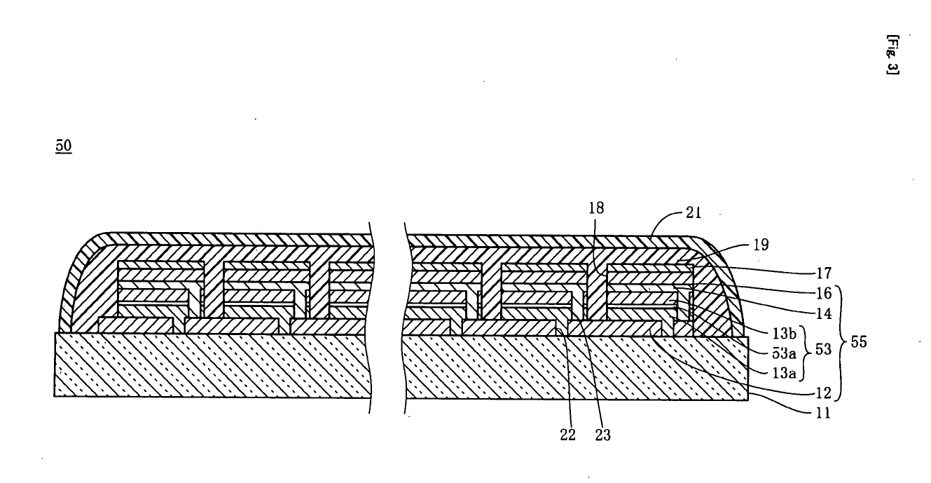

A structure such as the one comprised of a p-type a-SiC:H (amorphous silicon carbide), an i-type a-Si, and an n-type μc-Si may be possible. The structure is not particularly restricted, and can be formed by a heretofore known method such as a plasma CVD method. In addition, the intermediate layer 53a may be formed between the photoelectric conversion units, for example, in the case of the tandem structure, between the first photoelectric conversion unit 13a (amorphous silicon photoelectric conversion unit) and the second photoelectric conversion unit (microcrystalline silicon photoelectric conversion unit) 13b, as shown in FIG. 3. In the intermediate layer 53a, materials such as those used for the front electrode layer 12 and the transparent and conductive film 14 are preferably used.

On the photoelectric conversion unit 13 is formed the transparent and conductive film 14. The transparent and conductive film 14 is not particularly restricted; and the film may be formed by a heretofore known method such as a sputtering method, a vacuum vapor deposition method, a thermal CVD method, and a wet coating method. The transparent and conductive film 14 is arranged to suppress interdiffusion between the photoelectric conversion unit 13 and the back electrode layer 16 and to increase reflection efficiency of the back electrode layer 16. When the transparent and conductive film 14 is formed by a wet coating method, at first a composition for transparent and conductive film is prepared. The composition for transparent and conductive film contains conductive oxide microparticles, dispersed in a dispersing medium. The conductive oxide microparticles contained in the composition for transparent and conductive film are preferably powdered tin oxide such as ITO (Indium Tin Oxide: composite oxides of indium oxide-tin oxide) and ATO (Antimony Tin Oxide: composite oxides of antimony oxide-tin oxide); powdered zinc oxide containing one, or two or more of a metal selected from the group consisting of Al, Co, Fe, In, Sn, Ga, and Ti; and the like. Among them, ITO, ATO, AZO (Aluminum Zinc Oxide: aluminum-doped zinc oxide), IZO (Indium Zinc Oxide: composite oxides of indium oxide-zinc oxide), and TZO (Tin Zinc Oxide: composite oxides of tin-containing zinc oxide) are particularly preferable. Content of the conductive oxide microparticles in the composition for transparent and conductive film is preferably in the range between 50 and 90% by mass based on the solid component contained in the composition. The foregoing content range of the conductive oxide microparticles is determined because, when the content is below the lower limit, conductivity is undesirably decreased, and when the content is above the upper limit, adhesion is undesirably decreased. In the foregoing range, the range between 70 and 90% by mass is a particularly preferable range. To keep stability in a disperse medium, average particle diameter of the conductive oxide microparticles is preferably in the range between 10 and 100 nm, or in the range between 20 and 60 nm in particular.

The composition for transparent and conductive film contains any one of a polymer type binder curable by heating and a non-polymer type binder or both. Example of the polymer type binder includes acryl resin, polycarbonate, polyester, alkyd resin, polyurethane, acryl urethane, polystyrene, polyacetal, polyamide, polyvinyl alcohol, polyvinyl acetate, cellulose, and siloxane polymer. The polymer type binder preferably contains a metal soap, a metal complex, and a hydrolysate of a metal alkoxide, of aluminum, silicon, titanium, zirconium, chromium, manganese, iron, cobalt, nickel, silver, copper, zinc, molybdenum, and tin. The hydrolysate of a metal alkoxide includes sol and gel. Example of the non-polymer type binder includes a metal soap, a metal complex, a metal alkoxide, a halosilane, a 2-alkoxy ethanol, a β-diketone, and an alkyl acetate. The metal contained in the metal soap, the metal complex, and the metal alkoxide is aluminum, silicon, titanium, zirconium, chromium, manganese, iron, cobalt, nickel, silver, copper, zinc, molybdenum, tin, indium, or antimony. These polymer type binders and non-polymer type binders are curable by heating, whereby enabling to form the transparent and conductive film 14 having low Haze rate and low volume resistivity at low temperature. Content of these binders in the composition for transparent and conductive film is preferably in the range between 5 and 50% by mass, or in the range between 10 and 30% by mass in particular, based on the solid component contained in the composition.

Into the composition for transparent and conductive film is preferably added a coupling agent in accordance with other components to be used therein. The agent is added to increase binding properties between the conductive microparticles and the binder and to improve adhesion between the transparent and conductive film 14 formed with the composition for transparent and conductive film and the photoelectric conversion unit 13 or the back electrode layer 16. Example of the coupling agent includes a silane coupling agent, an aluminum-coupling agent, and a titanium-coupling agent.

Example of the silane-coupling agent includes vinyl triethoxysilane, γ-glycidoxypropyl trimethoxysilane, and γ-methacryloxypropyl trimethoxysilane. Example of the aluminum-coupling agent includes an aluminum-coupling agent having an acetoalkoxy group, as shown by the following formula (1). Example of the titanium-coupling agent includes titanium-coupling agents having a dialkyl pyrophosphite group, as shown by the following formulae (2) to (4), and a titanium-coupling agent having a dialkyl phosphite group, as shown by the following formula (5).

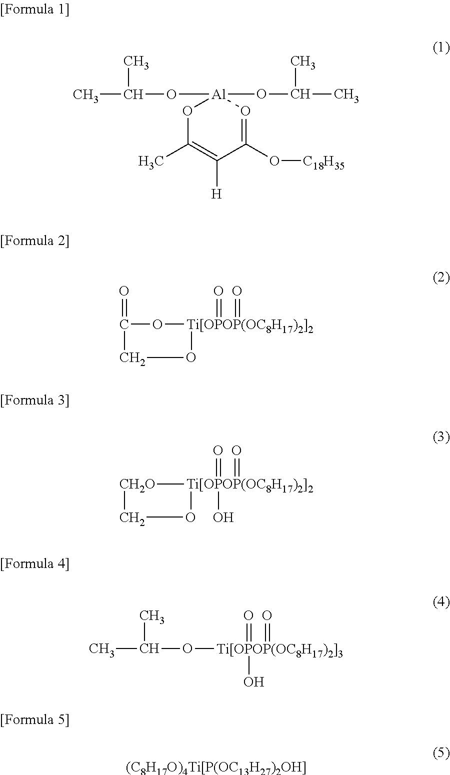

To form the transparent and conductive film 14 by using the composition for transparent and conductive film, firstly the composition for transparent and conductive film is applied by a wet coating method on the photoelectric conversion unit 13 to form a film having a thickness in the range between 0.03 and 0.5 μm, or preferably in the range between 0.05 and 0.3 μm after burning. Here, the thickness of the transparent and conductive film 14 is limited in the range between 0.03 and 0.5 μm, because, if the thickness is less than 0.03 μm or more than 0.5 μm, an incremental reflection effect cannot be obtained fully. Then, the transparent and conductive film 14 is formed by burning this laminate at 120 to 400° C. for 5 to 60 minutes in an air or under an atmosphere of an inert gas such as nitrogen and argon.

On the transparent and conductive film 14 is formed the back electrode layer 16. The back electrode layer 16 reflects a light that has transmitted through the photoelectric conversion unit without absorption, thereby playing a role to improve power generation efficiency by returning the light back to the photoelectric conversion unit again; and thus, the back electrode layer is required to have high diffusion reflectance. Accordingly, the back electrode layer 16 is preferably a metal having high reflectance. Example of the metal includes a metal such as silver, iron, chromium, tantalum, molybdenum, nickel, aluminum, cobalt, and titanium; a metal alloy of the foregoing metals; and a metal alloy such as nichrome and stainless steel. The back electrode layer 16 may be formed by a heretofore known method such as a thermal CVD method, a sputtering method, a vacuum deposition method, and a wet coating method, though the method is not particularly limited to these methods.

When the back electrode layer 16 is formed with a wet coating method, a composition for electrode having metal nanoparticles dispersed in a dispersing medium is used. The composition for electrode is prepared by dispersing metal nanoparticles into a dispersing medium. In the metal nanoparticles, content of silver is 75% or more by mass, or preferably 80% or more by mass, based on the total metal elements. Content of silver is made 75% or more by mass based on the total metal elements, because, if the content is less than 75% by mass, reflectance of the back electrode layer 16 that is formed by using the composition for electrode is decreased. The metal nanoparticles are chemically modified by a protecting agent having an organic molecular main chain with a carbon skeleton of 1 to 3 carbon atoms. The reason why the carbon number of a carbon skeleton in an organic molecular main chain of the protecting agent to chemically modify the metal nanoparticles is made 1 to 3 is because, when the carbon number is made 4 or more, decomposition or elimination (separation and burning) of the protecting agent by heating becomes difficult, so that much of organic residues may remain in the back electrode layer 16 thereby decreasing conductivity and reflectance of the back electrode layer 16 due to property change or deterioration.

The metal nanoparticles contain 70% or more by number-average, or preferably 75% or more by number-average, of metal nanoparticles having primary particle diameter in the range between 10 and 50 nm. When content of the metal nanoparticles having primary particle diameter in the range between 10 and 50 nm is less than 70% by mass relative to 100% by number-average of the total metal nanoparticles, specific surface area of the metal nanoparticles increases thereby leading to increase of the ratio of an organic substance. Therefore, even if an organic molecule that can be easily decomposed or eliminated (separation and burning) is used, much of organic residues remain in the back electrode layer 16 because the ratio of the organic molecule is so large. There is a fear that the residues may cause property change or deterioration thereby leading to decrease in conductivity and reflectance of the back electrode layer 16. In addition, particle size distribution of the metal nanoparticles becomes wider so that density of the back electrode layer 16 may be lowered easily thereby leading to decrease in conductivity and reflectance of the back electrode layer 16. Further in addition, in view of relationship between primary particle diameter and temporal stability (aging stability) of the metal nanoparticles, primary particle diameter of the metal nanoparticles is made in the range between 10 and 50 nm.

It is preferable that the composition for electrode that contains the metal nanoparticles further contain one, or two or more of an additive selected from the group consisting of an organic polymer, a metal oxide, a metal hydroxide, an organometallic compound, and a silicone oil. The additive of an organic polymer, a metal oxide, a metal hydroxide, an organometallic compound, or a silicone oil, contained in the composition for electrode, is used. With this, chemical bonding to a substrate or an anchor effect maybe increased, or wetting properties between a substrate and the metal nanoparticles during burning process by heating may be improved, so that adhesion thereof with a substrate can be improved without damaging conductivity. In addition, when the back electrode layer 16 is formed by using the composition for electrode, grain growth among metal nanoparticles by sintering can be controlled. In formation of the back electrode layer 16 by using the composition for electrode, a vacuum process is not necessary during film formation; and thus, process restrictions and running cost of manufacturing equipment can be decreased drastically.

Content of the additive is 0.1 to 20% by mass, or preferably 0.2 to 10% by mass, relative to silver nanoparticles that constitute the metal nanoparticles. If content of the additive is less than 0.1%, there is a fear that pores having a large average diameter may be formed or pore density may be increased. If content of the additive is more than 20%, conductivity of the back electrode layer 16 formed may be adversely affected thereby causing a problem of volume resistivity beyond 2×10⁻⁵ Ω·cm.

As the organic polymer to be used as the additive, one, or two or more of the organic polymer is selected from the group consisting of polyvinylpyrrolidone (hereinafter PVP), a PVP copolymer, and a water-soluble cellulose. Specific example of the PVP copolymer includes PVP-methacrylate copolymer, PVP-styrene copolymer, and PVP-vinyl acetate copolymer. Example of the water-soluble cellulose includes a cellulose ether such as hydroxypropyl methylcellulose, methylcellulose, and hydroxyethyl methylcellulose.

The metal oxide to be used as the additive is preferably an oxide or a composite oxide that contains at least one metal selected from the group consisting of aluminum, silicon, titanium, zirconium, chromium, manganese, iron, cobalt, nickel, silver, copper, zinc, molybdenum, tin, indium, and antimony. Specific example of the composite oxide includes ITO (Indium Tin Oxide: composite oxides of indium oxide-tin oxide), ATO (Antimony Tin Oxide: composite oxides of antimony oxide-tin oxide), IZO (Indium Zinc Oxide: composite oxides of indium oxide-zinc oxide), and AZO (Aluminum Zinc Oxide: composite oxides of aluminum oxide-zinc oxide).

The metal hydroxide to be used as the additive is preferably a hydroxide that contains at least one metal selected from the group consisting of aluminum, silicon, titanium, zirconium, chromium, manganese, iron, cobalt, nickel, silver, copper, zinc, molybdenum, tin, indium, and antimony.

The organometallic compound to be used as the additive is preferably a metal soap, a metal complex, or a metal alkoxide, wherein the organometallic compound contains at least one metal selected from the group consisting of silicon, titanium, zirconium, chromium, manganese, iron, cobalt, nickel, silver, copper, zinc, molybdenum, and tin. Example of the metal soap includes chromium acetate, manganese formate, iron citrate, cobalt formate, nickel acetate, silver citrate, copper acetate, copper citrate, tin acetate, zinc acetate, zinc oxalate, and molybdenum acetate. Example of the metal complex includes zinc acetylacetonato complex, chromium acetylacetonato complex, and nickel acetylacetonato complex. Example of the metal alkoxide includes titanium isopropoxide, methyl silicate, isoanatopropyl trimethoxy silane, and aminopropyl trimethoxy silane.

As the silicone oil to be used as the additive, a straight silicone oil as well as a modified silicone oil may be used. As the modified silicone oil, polysiloxane whose side chain is partly introduced with an organic group (side chain type), polysiloxane whose both terminals are introduced with an organic group (both terminal type), polysiloxane whose any one of both terminals is introduced with an organic group (one terminal type), and polysiloxane whose side chain partly as well as both terminals are introduced with an organic group (side chain-both terminal type) may be used. As to the modified silicone oil, there are a reactive silicone oil and a non-reactive silicone oil; both types may be used as the additive of the present invention. Meanwhile, the reactive silicone oil means a silicone oil modified with an amino group, an epoxy group, a carboxy group, a carbinol group, a mercapto group, and different functional groups (an epoxy group, an amino group, and a polyether group); the non-reactive silicone oil means a silicone oil modified with a polyether group, a methylstyryl group, an alkyl group, a higher fatty acid ester group, a fluorine atom, and a particular hydrophilic group.

On the other hand, among the metal nanoparticles that constitute the composition for electrode, it is preferable that metal nanoparticles other than silver nanoparticles further contain metal nanoparticles of one kind of metal particles selected from the group consisting of gold, platinum, palladium, ruthenium, nickel, copper, tin, indium, zinc, iron, chromium, and manganese, or metal particles of a mixture composition or a metal alloy composition containing two or more metals selected from the foregoing metal group. Content of the metal nanoparticles other than silver nanoparticles is preferably 0.02% or more by mass and less than 25% by mass, or more preferably 0.03 to 20% by mass, relative to 100% by mass of the total metal nanoparticles. This is because, when content of the metal nanoparticles other than silver nanoparticles is in the range of 0.02% or more by mass and less than 25% by mass, conductivity and reflectance of the back electrode layer 16 are not deteriorated after a weatherability test (the test is done in a chamber controlled at constant temperature of 100° C. and constant humidity of 50% for 1000 hours) as compared with before the weatherability test.

Content of the metal nanoparticles including silver nanoparticles contained in the composition for electrode is preferably 2.5 to 95.0% by mass, or more preferably 3.5 to 90% by mass, relative to 100% by mass of the composition for electrode comprised of metal nanoparticles and dispersing medium. This is because, when the content is more than 95.0% by mass relative to 100% by mass of the composition for electrode, necessary fluidity as an ink or a paste during a wet coating process of the composition for electrode is lost.

The dispersing medium that constitutes the composition for electrode to form the back electrode layer 16 contains water with its content being 1% or more by mass, or preferably 2% or more by mass, and a water-miscible solvent, for example, an alcohol, with its content being 2% or more by mass, or preferably 3% or more by mass, relative to 100% by mass of the total dispersing medium. For example, in the case that the dispersing medium is comprised of only water and an alcohol, if the medium contains 2% by mass of water, content of the alcohol is 98% by mass; while if the medium contains 2% by mass of the alcohol, content of water is 98% by mass. The dispersing medium, namely a protective molecule that chemically modifies surface of the metal nanoparticles, contains any one of a hydroxy (—OH) group and a carbonyl (—C═O) group or both. Content of water is made preferably 1% or more by mass relative to 100% by mass of the total dispersing medium. This is because, if content of water is less than 2% by mass, a film obtained by applying the composition for electrode with a wet coating method is difficult to be sintered at low temperature. In addition, conductivity and reflectance of the back electrode layer 16 are decreased after burning. Meanwhile, if a hydroxy (—OH) group is contained in the protecting agent that chemically modifies metal nanoparticles such as silver nanoparticles, dispersion stability of the composition for electrode becomes excellent and good effect can be obtained during low-temperature sintering of the coat film. If a carbonyl (—C═O) group is contained in the protecting agent that chemically modifies metal nanoparticles such as silver nanoparticles, dispersion stability of the composition for electrode becomes excellent and good effect can be obtained during low-temperature sintering of the coat film, similarly to the foregoing. The solvent miscible with water used in the dispersing medium is preferably an alcohol. Among alcohols, it is particularly preferable to use one, or two or more alcohols selected from the group consisting of methanol, ethanol, propanol, butanol, ethylene glycol, propylene glycol, diethylene glycol, glycerol, isobonyl hexanol, and erythritol.

The composition for electrode containing metal nanoparticles to form the back electrode layer 16 is prepared by the following methods.
(a) The case that the carbon number of a carbon skeleton in an organic molecular main chain of the protecting agent to chemically modify silver nanoparticles is 3:

Firstly, an aqueous metal salt solution is prepared by dissolving silver nitrate into water such as deionized water. On the other hand, sodium citrate is dissolved into water such as deionized water to obtain an aqueous sodium citrate solution with concentration of 10 to 40%, into which is directly added granular or powdered ferrous sulfate for dissolution under stream of an inert gas such as nitrogen, whereby an aqueous reductive solution containing a citrate ion and a ferrous ion with mole ratio of 3:2 is prepared. Into this reductive aqueous solution is gradually added the foregoing aqueous metal salt solution with stirring the reductive aqueous solution to mix both solutions under the forgoing inert gas stream. Here, addition amount of the aqueous metal salt solution is made 1/10 or less relative to the amount of the aqueous reductive solution by controlling concentration of each solution so that reaction temperature may be kept preferably at 30 to 60° C. even when the aqueous metal salt solution of room temperature is added gradually. The mixing ratio of both of the aqueous solutions is controlled so that equivalent of the ferrous ion added as a reducing agent may be three times of equivalent of the metal ion. Namely, control is made so as to satisfy the equation: (mole of metal ion in aqueous metal salt solution)×(valency of the metal ion)=3×(mole of ferrous ion in aqueous reductive solution). After completion of gradual addition of the aqueous metal salt solution, stirring of the mixture solution is continued for further 10 to 300 minutes to prepare a disperse solution comprised of metal colloid. The resulting disperse solution is allowed to stand at room temperature; and after the settled metal nanoparticle agglomerate is separated by decantation, centrifugal separation, or the like, water such as deionized water is added to this separated substance to obtain a disperse body, which is then desalted by ultrafiltration. Subsequently, washing by an alcohol for displacement is conducted to make content of the metal (silver) in the range between 2.5 and 50% by mass. Thereafter, large particles are separated out by using a centrifugal separator with controlling its centrifugal force so that silver nanoparticles that are controlled to have primary particle diameter in the range between 10 and 50 nm with the amount of nanoparticles thereof being 70% or more by number-average may be obtained.. Namely, control is made so that content of silver nanoparticles having primary particle diameter in the range between 10 and 50 nm may be 70% or more by number-average relative to 100% by number-average of the total silver nanoparticles. With this, the disperse body, wherein the carbon number of a carbon skeleton in an organic molecular main chain of the protecting agent to chemically modify silver nanoparticles is 3, is obtained.

Subsequently, the obtained disperse body is controlled so that final metal content (silver content) may be in the range between 2.5 and 95% by mass relative to 100% by mass of the disperse body. When an aqueous alcohol is used as the disperse medium, it is preferable that each content of water and an alcohol used as the solvent be controlled 1% or more and 2% or more, respectively. When, an additive is further included in the composition for electrode, one, or two or more additives selected from the group consisting of an organic polymer, a metal oxide, a metal hydroxide, an organometallic compound, and a silicone oil is added to the disperse body with an intended ratio. Content of the additive is controlled so that the content thereof may be in the range between 0.1 and 20% by mass relative to 100% by mass of the composition for electrode obtained. With this, the composition for electrode, wherein silver nanoparticles, chemically modified with a protecting agent whose organic molecular main chain has carbon skeleton of 3 carbon atoms, are dispersed into a disperse medium, can be obtained.
(b) The case that the carbon number of a carbon skeleton in an organic molecular main chain of the protecting agent to chemically modify silver nanoparticles is 2:

The disperse body is prepared in a manner similar to that for (a), except that sodium citrate used for preparation of the aqueous reductive solution is changed to sodium maleate. With this, the disperse body, wherein the carbon number of a carbon skeleton in an organic molecular main chain of the protecting agent to chemically modify silver nanoparticles is 2, is obtained.
(c) The case that the carbon number of a carbon skeleton in an organic molecular main chain of the protecting agent to chemically modify silver nanoparticles is 1:

The disperse body is prepared in a manner similar to that for (a), except that sodium citrate used for preparation of the aqueous reductive solution is changed to sodium glycolate. With this, the disperse body, wherein the carbon number of a carbon skeleton in an organic molecular main chain of the protecting agent to chemically modify silver nanoparticles is 1, is obtained.
(d) The case that the carbon number of a carbon skeleton in an organic molecular main chain of the protecting agent to chemically modify metal nanoparticles other than silver nanoparticles is 3:

As the metal that constitutes the metal nanoparticles other than silver nanoparticles, gold, platinum, palladium, ruthenium, nickel, copper, tin, indium, zinc, iron, chromium, and manganese can be mentioned. The disperse body is prepared in a manner similar to that for (a), except that silver nitrate used for preparation of the aqueous metal salt solution is changed to aurochloric acid, chloroplatinic acid, palladium nitrate, ruthenium trichloride, nickel chloride, cuprous nitrate, stannic chloride, indium nitrate, zinc chloride, iron sulfate, chromium sulfate, or manganese sulfate. With this, the disperse body, wherein the carbon number of a carbon skeleton in an organic molecular main chain of the protecting agent to chemically modify metal nanoparticles other than silver nanoparticles is 3, is obtained.

Meanwhile, in the case that the carbon number of a carbon skeleton in an organic molecular main chain of the protecting agent to chemically modify metal nanoparticles other than silver nanoparticles is 1 or 2, the disperse body is prepared in a manner similar to those of (b) or (c), except that silver nitrate used for preparation of the aqueous metal salt solution is changed to the metal salt as mentioned above. With this, the disperse body, wherein the carbon number of a carbon skeleton in an organic molecular main chain of the protecting agent to chemically modify metal nanoparticles other than silver nanoparticles is 1 or 2, is obtained.

In the case that metal nanoparticles other than silver nanoparticles, in addition to silver nanoparticles, are included as the metal nanoparticles, for example, a first disperse body that contains silver nanoparticles prepared by the foregoing method (a) is mixed with a second disperse body that contains metal nanoparticles other than silver nanoparticles prepared by the foregoing method (d) in such a manner that 75% or more by mass of the first disperse body and less than 25% by mass of the second disperse body may be mixed to give 100% by mass of the total amount of the first body and the second body. Meanwhile, the first disperse body of not only the disperse body that contains silver nanoparticles prepared by the foregoing method (a) but also the disperse body that contains silver nanoparticles prepared by the foregoing method (b) or the disperse body that contains silver nanoparticles prepared by the foregoing method (c) may be used.

To form the back electrode layer 16 by using the composition for electrode, firstly the composition for electrode is applied on the photoelectric conversion unit 13 with a wet coating method in such a manner that thickness of the coat layer for the electrode after burning by heating may become 0.05 to 2.0 μm, or preferably 0.1 to 1.5 μm. Then, burning is conducted with keeping the coat layer for the electrode in an air or under an atmosphere of an inert gas such as nitrogen and argon at temperature of 130 to 400° C., or preferably 150 to 350° C. and for the time of 5 minutes to one hour, or preferably 15 to 40 minutes. Here, thickness of the back electrode layer 16 after burning is limited in the range between 0.05 and 2.0 This is because, if the thickness is less than 0.05 μm, surface resistivity of the electrode required for a solar cell module is insufficient. The heating temperature of the coat layer for the electrode is made in the range between 130 and 400° C. This is because, if the temperature is lower than 130° C., sintering among the metal nanoparticles is insufficient, and in addition, elimination or decomposition (separation and burning) of the protecting agent by heating is difficult. Namely, much of organic residues remain in the back electrode layer 16 after burning thereby decreasing conductivity and reflectance of the back electrode layer 16 due to property change or deterioration. When the temperature is higher than 400° C., manufacturing merits of the low temperature process cannot be enjoyed. Namely, manufacturing cost is increased and productivity is decreased, and in particular, wavelength region of photoelectric conversion in a solar cell module of an amorphous silicon, a microcrystalline silicon, or a hybrid thereof is affected. Further, the heating time of the coat layer for the electrode is made in the range between five minutes and one hour. This is because, when the time is less than five minutes, sintering among metal nanoparticles is insufficient, and in addition, elimination or decomposition (separation and burning) of the protecting agent by heating is difficult so that much of organic residues may remain in the back electrode layer 16 thereby decreasing conductivity and reflectance of the back electrode layer 16 due to property change or deterioration.

Accordingly, with a wet coating method, the back electrode layer 16 can be formed by a simple process in a short time, and in addition, a vacuum process is not necessary during film formation so that process restrictions may be decreased thereby cutting the running cost of manufacturing equipment drastically. In the back electrode layer 16 obtained by this method, pores whose average diameter is 100 nm or less, average depth where the pores are is 100 nm or shallower, and density by number is 30 pieces/μcm² or lower are formed in the contact side of the photoelectric conversion unit 13. With regard to the pores formed in the contact side of the photoelectric conversion unit 13 of the back electrode layer 16, when the average diameter is made small, the average depth where the pores are is made shallow, and density by number is made small, the inflection point to start decrease of reflectance spectrum measured from the side of the photoelectric conversion unit 13 shifts toward a shorter wavelength upon formation of the back electrode layer 16 on the photoelectric conversion unit 13. In the back electrode layer 16, with regard to the pores formed in the contact side of the photoelectric conversion unit 13 of the back electrode layer 16, the average diameter was made 100 nm or less, the average depth where the pores were was made 100 nm or less, and the density by number was made 30/μcm² or lower. With this, when a transparent substrate having transmittance of 98% or higher is used, high diffusion reflectance of 80% or higher relative to the theoretical reflectance in the wavelength range between 500 and 1200 nm can be accomplished. The wavelength range between 500 and 1200 nm can cover almost entire variable wavelength of the case that polycrystalline silicon is used in the photoelectric conversion unit. In addition, the back electrode layer 16 can have specific resistance near the specific resistance of the metal itself that constitutes metal nanoparticles contained in the composition for electrode. Namely, low specific resistance with approximately the same level as the bulk that is usable as the electrode of a solar cell module is obtained. In addition, the back electrode layer 16 of the present invention is excellent in reflectance and adhesion of the film and has durable stability in specific resistance as compared with a film formed by a vacuum process such as a sputtering method. This is because the back electrode layer 16 of the present invention, which is formed under an air atmosphere, is not easily affected by oxidation and penetration of water as compared with a film formed under vacuum.

On the back electrode layer 16 is formed the back electrode reinforcing film 17 with a wet coating method. This back electrode reinforcing film 17 protects electromagnetic properties and corrosion resistance of the back electrode layer 16, and in addition, avoids delamination or drop off of each layer and film after formation of the separation groove by a laser scriber. To form the back electrode reinforcing film 17 with a wet coating method, firstly a composition for reinforcing film that is applied on the back electrode layer 16 with a wet coating method is prepared. The composition for reinforcing film contains any one of an organic-based or an inorganic-based material of a polymer type binder and an inorganic-based material of a non-polymer type binder or both, wherein the materials are curable by UV-irradiation, or by heating, or by heating after UV-irradiation. The organic-based material of a polymer type binder contains preferably one, or two or more polymers selected from the group consisting of an acryl type, an epoxy type, a urethane type, an acryl urethane type, an epoxy acryl type, a cellulose type, and a siloxane type. As the acryl type binder, an acryl polymer obtained by photo-polymerization of an acryl monomer, mixed with an added photo-polymerization initiator, by UV-irradiation can be used. Example of the acryl monomer includes one, or two or more mixed monomers selected from the group consisting of 1,6-hexanediol diacrylate, trimethylolpropane triacrylate, neopentylglycol diacrylate, tetramethylolmethane tetraacrylate, ditrimethylolpropane tetraacrylate, 1,9-nonanediol diacrylate, tripropyleneglycol diacrylate, ethoxylated isocyanuric acid triacrylate, and tetramethylolmethane tetraacrylate. It is preferable that to these monomers be added a solvent such as MIBK (methyl isobutyl ketone), PGME (1-methoxy-2-propanol), and PGMEA (propylene glycol monomethyl ether acetate). However, as far as the foregoing monomers can be dissolved, a general organic solvent such as ethanol, methanol, benzene, toluene, xylene, NMP (N-methyl pyrrolidone), acrylonitrile, acetonitrile, THF (tetrahydrofurane), ethyl acetate, MEK (methyl ethyl ketone), butyl carbitol, butyl carbitol acetate, butyl cellosolve, butyl cellosolve acetate, ethyl carbitol, ethyl carbitol acetate, IPA (isopropyl alcohol), acetone, DMF (dimethyl formamide), DMSO (dimethyl sulfoxide), piperidine, and phenol may be used. Example of the photo-polymerization initiator includes 1-hydroxy-cyclohexyl-phenyl-ketone, 2-hydroxy-2-methyl-1-phenyl-propane-1-one, 2-hydroxy-1-{4-[4-(2-hydroxy-2-methyl-propionyl)-benzyl ]-phenyl}-2-methyl-propane-1-one, and 1-[4-(2-hydroxyethoxy)-phenyl]-2-hydroxy-2-methyl-1-propane-1-one. An acryl monomer is diluted into an arbitrary solvent mentioned above, and the resulting solution can be used after viscosity thereof is controlled so as to be easily applicable. Amount of a photo-polymerization initiator to be added is 0.1 to 30% by mass relative to 100% by mass of an acryl monomer. This is because, when the amount of a photo-polymerization initiator to be added is less than 0.1% by mass relative to 100% by mass of an acryl monomer, cure is insufficient, and when the amount is more than 30% by mass, a cured film (back electrode reinforcing film) is discolored or causes poor adhesion due to residual stress. A mixture solution obtained by adding a solvent and a photo-polymerization initiator into an acryl monomer with stirring is used as a base solution of the composition for reinforcing film. Here, if the mixture solution obtained by adding a solvent and a photo-polymerization initiator into an acryl monomer with stirring does not become homogeneous, heating to about 40° C. may be allowed.

As the epoxy type binder, an epoxy polymer, obtained by heating a mixture solution that is obtained by the procedure wherein a solvent is added to an epoxy type resin with stirring, and into the resulting mixture solution is added a thermal curing agent with stirring, may be used. Example of the epoxy type resin includes a biphenyl epoxy resin, a cresol novolak epoxy resin, a bisphenol A epoxy resin, a bisphenol F epoxy resin, and a naphthalene epoxy resin. Example of the solvent includes BCA (butyl carbitol acetate), ECA (ethyl carbitol acetate), and BC (butyl carbitol). However, as far as the foregoing epoxy type resins can be dissolved, a general organic solvent such as ethanol, methanol, benzene, toluene, xylene, PGME (1-methoxy-2-propanol), PGMEA (propylene glycol monomethyl ether acetate), NMP (N-methyl pyrrolidone), MIBK (methyl isobutyl ketone), acrylonitrile, acetonitrile, THF (tetrahydrofurane), ethyl acetate, MEK (methyl ethyl ketone), butyl carbitol, butyl carbitol acetate, butyl cellosolve, butyl cellosolve acetate, ethyl carbitol, ethyl carbitol acetate, IPA (isopropyl alcohol), acetone, DMF (dimethyl formamide), DMSO (dimethyl sulfoxide), piperidine, and phenol may be used. Example of the thermal curing agent includes 2-ethyl-4-methylimidazole, boron fluoride-monoethanol amine, DICY (dicyan diamide), diethylaminopropyl amine, isophorone diamine, diaminodiphenyl methane, piperidine, 2,4,6-tris-(dimethylaminomethyl) phenol, 2-methylimidazole, hexahydrophthalic anhydride, and 7,11-octadecanediene-1,18-dicarbohydrazide. An epoxy type resin is diluted into an arbitrary solvent mentioned above, and the resulting solution can be used after viscosity thereof is controlled so as to be easily applicable. Amount of a thermal curing agent to be added is 0.5 to 20% by mass relative to 100% by mass of an epoxy type resin.. This is because, when the amount of a thermal curing agent to be added is less than 0.5% by mass relative to 100% by mass of an epoxy type resin, cure is insufficient, and when the amount is more than 20% by mass, a cured film (back electrode reinforcing film) causes poor adhesion due to large internal stress. A mixture solution obtained by adding a solvent and a thermal curing agent into an epoxy type resin with stirring is used as a base solution of the composition for reinforcing film. Here, if the mixture solution obtained by adding a solvent into an epoxy type resin with stirring does not become homogeneous, heating to about 40° C. may be allowed.

The cellulose type binder is obtained by heating a mixture solution that is obtained by the procedure wherein a solvent is added to a cellulose type polymer with stirring, and into the resulting mixture solution is added gelatin with stirring. Example of the cellulose type polymer includes a water-soluble cellulose derivative such as hydroxypropyl cellulose, hydroxypropyl methylcellulose, methylcellulose, and hydroxyethyl methylcellulose. Example of the solvent includes IPA (isopropyl alcohol), ethanol, methanol, PGME (propylene glycol monomethyl ether), PGMEA (propylene glycol monomethyl ether acetate), MIBK (methyl isobutyl ketone), and acetone. A cellulose type polymer is diluted into an arbitrary solvent mentioned above, and the resulting solution can be used after viscosity thereof is controlled so as to be easily applicable. Amount of gelatin to be added is 0.1 to 20% by mass relative to 100% by mass of a cellulose type polymer. This is because, when the amount of gelatin to be added is less than 0.1% by mass, or more than 20% by mass, relative to 100% by mass of a cellulose type polymer, viscosity suitable for application cannot be obtained. A mixture solution obtained by adding a solvent and gelatin into a cellulose type resin with stirring is used as a base solution of the composition for reinforcing film. Here, the mixture solution obtained by adding a solvent and gelatin into a cellulose type polymer becomes homogeneous by heating at about 30° C. with stirring.

The urethane type binder that uses a thermosetting urethane resin is prepared as following. Firstly, a polyol component represented by trimethylol propane, neopentyl glycol, or the like is reacted with excess amount of a polyisocyanate represented by tolylene diisocyanate (TDI), diphenylmethane isocyanate (MDI), or the like to obtain a urethane prepolymer having reactive isocyanate terminals. Then, this urethane prepolymer having reactive isocyanate terminals is reacted with a blocking agent such as a phenol type represented by methyl phenol, a lactam type represented by β-butyrolactam, and an oxime type represented by methyl ethyl ketone oxime. Solvent, such as a ketone, an alkylbenzene, a cellosolve, an ester, and an alcohol, may be used. Specific example of the ketone includes acetone and methyl ethyl ketone. Specific example of the alkylbenzene includes benzene and toluene. Specific example of the cellosolve includes methyl cellosolve and butyl cellosolve; specific example of the ester includes butyl cellosolve acetate and butyl acetate; and specific example of the alcohol includes isopropyl alcohol and butyl alcohol. On the other hand, a polyamine may be used as the thermal curing agent (reactant). Specific example of the polyamine includes N-octyl-N-aminopropyl-N′-aminopropyl propylene diamine, N-lauryl-N-aminopropyl-N′-aminopropyl propylene diamine, N-myristyl-N-aminopropyl-N′-aminopropyl propylene diamine, and N-octyl-N-aminopropyl-N′,N′-di(aminopropyl)propylene diamine. The urethane prepolymer having reactive isocyanate terminals obtained by reaction of the polyol component with the isocyanate compound is blocked by a blocking agent to obtain a blocked polyisocyanate. Equivalent ratio of an amino group of the polyamine to an isocyanate group of the blocked polyisocyanate is preferably nearly one (in the range between 0.7 and 1.1). This is because, when equivalent ratio of an amino group of the polyamine to an isocyanate group of the blocked polyisocyanate is less than 0.7, or more than 1.1, insufficient reaction takes place because either the blocked polyisocyanate or the polyamine is excessive so that cure may be insufficient. The urethane polymer is diluted into an arbitrary solvent mentioned above, and the resulting solution can be used after viscosity thereof is controlled so as to be easily applicable.

Example of the urethane type binder, containing a urethane acrylate oligomer, is an acryl urethane polymer such as Shiko UV-3310B or Shiko UV-6100B (manufactured by Nippon Synthetic Chemical Co., Ltd.), EBECRYL 4820 or EBECRYL 284 (manufactured by Daicel-Cytec Co., Ltd.), and U-4HA or UA-32P (manufactured by Shin-Nakamura Chemical Co., Ltd.), which are curable by UV-irradiation. Curing ability can be increased by adding, as appropriate, a photo-polymerization initiator (such as, for example, 1-hydroxy-cyclohexyl-phenyl-ketone, and 2-hydroxy-2-methyl-1-phenyl-propane-1-one) that is used in an acrylate. Solvent, such as a ketone, an alkylbenzene, a cellosolve, an ester, and an alcohol, may be used. Specific example of the ketone includes acetone and methyl ethyl ketone. Specific example of the alkylbenzene includes benzene and toluene. Specific example of the cellosolve includes methyl cellosolve and butyl cellosolve; specific example of the ester includes butyl cellosolve acetate and butyl acetate; and specific example of the alcohol includes isopropyl alcohol and butyl alcohol. A photo-polymerization initiator in the range between 0.1 and 30% by mass, relative to 100% by mass of the acryl urethane polymer, is added as appropriate. This is because, when added amount of a photo-polymerization initiator is less than 0.1% by mass, cure is insufficient, and when more than 30% by mass, poor adhesion is resulted due to large internal stress of the back electrode reinforcing film. An acryl urethane type monomer is diluted into an arbitrary solvent mentioned above, and the resulting solution can be used after viscosity thereof is controlled so as to be easily applicable.

As the epoxy acryl type binder, an epoxy acryl type polymer may be used. Example of the epoxy acryl type polymer includes bisphenol A epoxy acrylate (for example, NK Oligo EA-1020, manufactured by Shin-Nakamura Chemical Co., Ltd.) and 1,6-hexanediol diglycidyl ether diacrylate (for example, NK Oligo EA-5521, manufactured by Shin-Nakamura Chemical Co., Ltd.). In addition, Neopol 8318 and Neopol 8355 (manufactured by Japan U-PICA Co., Ltd.) may be used. Solvent, such as a ketone, an alkylbenzene, a cellosolve, an ester, and an alcohol, may be used. Specific example of the ketone includes acetone and methyl ethyl ketone. Specific example of the alkylbenzene includes benzene and toluene. Specific example of the cellosolve includes methyl cellosolve and butyl cellosolve; specific example of the ester includes butyl cellosolve acetate and butyl acetate; and specific example of the alcohol includes isopropyl alcohol and butyl alcohol. An epoxy acryl type polymer may be added with a thermal curing agent and a photo-polymerization initiator, as appropriate. Curing by a thermal curing agent and a photo-polymerization initiator is conducted by heating, or UV-irradiation, or by heating after UV-irradiation. An epoxy acryl type polymer is diluted into an arbitrary solvent mentioned above, and the resulting solution can be used after viscosity thereof is controlled so as to be easily applicable.

As the siloxane type binder, a siloxane type polymer may be used. Example of the siloxane type polymer includes polydimethyl siloxane, polymethyl hydrogen siloxane, and polymethyl phenyl siloxane. Both a straight silicone oil and a modified silicone oil may be used as the siloxane type polymer shown herein. As the modified silicone oil, polysiloxane whose side chain is partly introduced with an organic group (side chain type), polysiloxane whose both terminals are introduced with an organic group (both terminal type), polysiloxane whose any one of both terminals is introduced with an organic group (one terminal type), polysiloxane whose side chain partly as well as both terminals are introduced with an organic group (side chain-both terminal type), or the like may be used. As to the modified silicone oil, there are a reactive silicone oil and a non-reactive silicone oil; both types may be used. Meanwhile, the reactive silicone oil means a silicone oil modified with an amino group, an epoxy group, a carboxy group, a carbinol group, a mercapto group, or different functional groups (an epoxy group, an amino group, and a polyether group); the non-reactive silicone oil means a silicone oil modified with a polyether group, a methylstyryl group, an alkyl group, a higher fatty acid ester group, a fluorine atom, or a particular hydrophilic group. Solvent, such as a ketone, an alkylbenzene, a cellosolve, an ester, and an alcohol, may be used. Specific example of the ketone includes acetone and methyl ethyl ketone. Specific example of the alkylbenzene includes benzene and toluene. Specific example of the cellosolve includes methyl cellosolve and butyl cellosolve. Specific example of the ester includes butyl cellosolve acetate and butyl acetate. Specific example of the alcohol includes isopropyl alcohol and butyl alcohol. The siloxane type polymer may be added with a thermal curing agent and a photo-polymerization initiator, as appropriate; but, if the film can be cured without addition of a thermal curing agent, a thermal curing agent is not necessary. The siloxane type polymer is diluted into an arbitrary solvent mentioned above, and the resulting solution can be used after viscosity thereof is controlled so as to be easily applicable.

The inorganic-based material of the polymer type binder preferably contains one, or two or more kinds selected from the group consisting of a metal soap, a metal complex, and a hydrolysate of a metal alkoxide. These inorganic-based materials of the polymer type binder change to the inorganic-based material from an organic-based material by heating. Namely, a film having properties of the inorganic-based material can be formed by burning. The metal contained in the metal soap, the metal complex, or the hydrolysate of the metal alkoxide is preferably one, or two or more metals selected from the group consisting of aluminum, silicon, titanium, zirconium, and tin. Example of the metal soap includes chromium acetate, manganese formate, iron citrate, cobalt formate, nickel acetate, silver citrate, copper acetate, copper citrate, tin acetate, zinc acetate, zinc oxalate, and molybdenum acetate. Example of the metal complex includes zinc acetylacetonato complex, chromium acetylacetonato complex, and nickel acetylacetonato complex. Example of the metal alkoxide includes titanium isopropoxide, methyl silicate, isoanatopropyl trimethoxy silane, and aminopropyl trimethoxy silane.

On the other hand, as the inorganic-based material of the non-polymer type binder, a SiO₂ binder may be mentioned. The SiO₂ binder may be prepared as an example shown as following. Firstly, HCl is dissolved into pure water with stirring to obtain an aqueous HCl solution. Then, tetraethoxy silane and ethyl alcohol are mixed; into the resulting solution is added the aqueous HCl solution, and then the reaction is carried out by heating. With this, the SiO₂ binder is prepared. The non-polymer type binder preferably includes one, or two or more kinds selected from the group consisting of a metal soap, a metal complex, a hydrolysate of a metal alkoxide, a halosilane, a 2-alkoxy ethanol, a β-diketone, and an alkyl acetate. The hydrolysate of a metal alkoxide includes sol and gel. The metal contained in the metal soap, the metal complex, or the hydrolysate of the metal alkoxide is preferably one, or two or more metals selected from the group consisting of aluminum, silicon, titanium, zirconium, and tin. Example of the metal soap includes chromium acetate, manganese formate, iron citrate, cobalt formate, nickel acetate, silver citrate, copper acetate, copper citrate, tin acetate, zinc acetate, zinc oxalate, and molybdenum acetate. Example of the metal complex includes zinc acetylacetonato complex, chromium acetylacetonato complex, and nickel acetylacetonato complex. Example of the metal alkoxide includes titanium isopropoxide, methyl silicate, isoanatopropyl trimethoxy silane, and aminopropyl triethoxy silane. Example of the halosilane includes chlorosilane, bromosilane, and fluorosilane. Example of the 2-alkoxy ethanol includes 2-methoxy ethanol, 2-ethoxy ethanol, and 2-butoxy ethanol. Example of the β-diketone includes 2,4-pentanedione and 1,3-diphenyl-1,3-propanedione. Example of the alkyl acetate includes ethylene glycol monomethyl ether acetate and propylene glycol monomethyl ether acetate.

The composition for reinforcing film may contain one, or two or more coupling agents selected from the group consisting of a silane coupling agent, an aluminum-coupling agent, and a titanium-coupling agent. As to the silane coupling agent, the aluminum-coupling agent, and the titanium-coupling agent, the silane coupling agent, the aluminum-coupling agent, and the titanium-coupling agent added in the composition for transparent and conductive film may be used. When the composition for reinforcing film contains the silane coupling agent, the aluminum-coupling agent, or the like, adhesion of the back electrode reinforcing film 17 to the back electrode layer 16 can be improved further. Accordingly, even if laser output is increased during formation of the separation groove 18 by a laser scriber, the back electrode reinforcing film 17 is not delaminated from the back electrode layer 16.

The composition for reinforcing film may contain one, or two or more kinds of metal oxide microparticles or planular particles selected from the group consisting of colloidal silica, fumed silica particles, silica particles, mica particles, and smectite particles. The colloidal silica is colloid of SiO₂ or hydrate thereof, having average particle diameter of 1 to 100 nm, or preferably 5 to 50 nm, without having a certain structure. The fumed silica particles are formed by oxidation of a gasified silicon chloride under a gas phase condition with a high temperature flame, and have average particle diameter of 1 to 50 nm, or preferably 5 to 30 nm. The silica particles are particles having average particle diameter of 1 to 100 nm, or preferably 5 to 50 nm. The mica particles are manufactured synthetically, and are particles having average particle diameter of 10 to 50000 nm, or preferably planular particles having average diameter of 1 to 20 μm and average thickness of 10 to 100 nm. The smectite particles are one kind of a layered ion-exchangeable silicate salt having a crystal structure wherein layers formed by an ionic bond and the like are layered in parallel with a weak bonding force with each other, and are particles having average particle diameter of 10 to 100000 nm, or preferably planular particles having average diameter of 1 to 20 μm and average thickness of 10 to 100 nm. When the composition for reinforcing film contains colloidal silica, fumed silica particles, and the like, the back electrode reinforcing film 17 can be made further harder. Accordingly, after formation of the separation groove 18 by a laser scriber, even if flash or crud that remains in the separation groove 18 is removed by an air knife and the like, edge part of the separation groove 18 in the back electrode reinforcing film 17 is not dropped off because the back electrode reinforcing film 17 has excellent abrasion resistance and impact resistance. Adding amount of the particles thereof is preferably 0.1 to 30% by mass, or in particular 0.2 to 20% by mass. When the amount is less than 0.1% by mass, it is difficult to obtain the effect; while when the amount is more than 30% by mass, adhesion tends to become poorer. Here, the average particle diameter of each of particles or microparticles in the present invention means 50%-average particle diameter (D₅₀) calculated as the number, based on particle diameter measured by a particle size distribution-measuring instrument with a laser diffraction and scattering method (LA-950, manufactured by Horiba, Ltd.). The value of average particle diameter by number measured with this particle size distribution measuring instrument with a laser diffraction and scattering method almost coincides with the average particle diameter obtained by measuring particle diameter of arbitrary 50 particles in a picture obtained with a scanning electron microscope (S-4300SE and S-900, manufactured by Hitachi High-Technologies Corp.). Average diameter and average thickness of the planular particles as well as average diameter and average thickness of each planular microparticles as described later are the values measured in a manner similar to those described above.

Here, the reason why average particle diameter of the colloidal silica is limited in the range between 1 and 100 nm is because, when the diameter is less than 1 run, colloidal is unstable and easy to coagulate; and when more than 100 nm, the diameter is too large to form a disperse solution. The reason why the sizes of the fumed silica particles, the silica particles, the mica particles, and the smectite particles are limited to the foregoing range is because particles within these ranges may be easily available or the size ranges may not be too large as compared with thickness of the film thereunder.

The composition for reinforcing film can contain microparticles or planular microparticles containing one, or two or more metals, or metal oxides of a metal, selected from the group consisting of gold, platinum, palladium, ruthenium, nickel, copper, tin, indium, zinc, iron, chromium, manganese, and aluminum. Average particle diameters of these microparticles are made in the range between 1 and 50000 nm, or preferably 100 and 5000 nm. Average diameter of the planular microparticles is preferably 1 to 50000 nm, and average thickness of the planular microparticles is preferably 100 to 20000 nm. When the composition for reinforcing film contains microparticles or planular microparticles of gold, platinum, and the like, the back electrode reinforcing film 17 may be furnished with more flexibility. Because of this, even if a stress is generated in the back electrode reinforcing film 17 during formation of the separation groove 18 by a laser scriber, the stress may be absorbed by ductility and malleability of the back electrode reinforcing film 17. Here, the reason why the size of the metal microparticles is limited to the foregoing range is because of the size of the obtainable microparticles; and the reason why the size of planular metal microparticles is limited to the foregoing range is not to exceed thickness of the back electrode reinforcing film. Adding amount of these microparticles or planular microparticles is preferably 0.1 to 30% by mass, or in particular 0.2 to 20% by mass. This is because, when the amount is less than 0.1% by mass, it is difficult to obtain the effect; while when the amount is more than 30% by mass, adhesion tends to become poorer. In addition, content of the foregoing metal or metal oxide in the foregoing microparticles or planular microparticles is 70% or more by mass, or preferably in the range between 80 and 100% by mass. This is because, if the amount is less than 70% by mass, workability of the back electrode reinforcing film 17 is decreased.

Example of the method to add and disperse an additive such as necessary foregoing particles, microparticles, or planular microparticles into a base solution of the composition for reinforcing film includes dispersion by agitation with a blade such as a dispersal blade, shear dispersion such as planetary agitation and a three-roll mill, and dispersion by using beads such as a bead mill and a paint shaker. Alternatively, a method wherein a disperse body that is previously prepared with a method as mentioned above by dispersing the additive to a solvent component of the base solution is mixed may be used. In the case that the additive itself is already a disperse solution by dispersing into a suitable solvent, a liquid-mixing method such as an ultrasonic homogenizer and an ultrasonic vibration, in addition to the foregoing methods, may be used.

A method to form the back electrode reinforcing film 17 on the back electrode layer 16 by using the composition for reinforcing film that is prepared as mentioned above will be explained. Firstly, the composition for reinforcing film is applied on the back electrode layer 16 with a wet coating method to form an applied layer of the reinforcing film on the back electrode layer 16. The wet coating is preferably done any of a spray coating method, a dispenser coating method, a spin coating method, a knife coating method, a slit coating method, an inkjet coating method, a die coating method, a screen printing method, an offset printing method, and a gravure printing method. However, the wet coating method is not limited to the foregoing methods; and thus, any method can be used. In the spray coating method, a disperse body is applied onto a substrate in a mist form by a compressed air, or a disperse body is applied onto a substrate in a mist form by compressing the disperse body itself. In the dispenser coating method, for example, by pushing a piston of a syringe into which a disperse body is filled, the disperse body is applied onto a substrate by ejection through a fine nozzle at the syringe tip. In the spin coating method, a disperse body is dropped onto a rotating substrate and the dropped disperse body is extended toward the substrate's peripheral direction by its centrifugal force. In the knife coating method, a knife and a horizontally-movable substrate are arranged such that the knife's edge and the substrate may have a prescribed space therebetween; a disperse body is charged onto the substrate in the upstream side of the knife, and then the substrate is moved horizontally toward the downstream direction. In the slit coating method, stream of a disperse body is applied onto a substrate through a narrow slit. In the inkjet coating method, inkjet printing on a substrate is conducted with a disperse body filled in an ink cartridge of a commercially available inkjet printer. In the die coating method, a disperse body charged into a die is distributed by a manifold and extruded through a slit as a thin film thereby coating surface of a running substrate. In the die coating method, there are a slot coating method, a slide coating method, and a curtain coating method. In the screen-printing method, a disperse body is transferred to a substrate through an engraved image formed on a gauze used as a pattern indicant material. In the offset printing method, which utilizes a water repellent property of an ink, a disperse body attached on a plate is once transferred from the plate to a rubber sheet without being directly attached to a substrate, and then the disperse body is newly transferred to the substrate from the rubber sheet. In the gravure printing method, an ink attached on a cylinder surface, among the ink transferred onto a cylinder surface that has a concave portion, is removed by a doctor blade thereby transferring the ink only left in the concave portion for pattern printing, or an ink is printed on entire surface by solid printing. These wet coating methods can be also used for forming the front electrode layer 12, the transparent electrode layer 14, the back electrode layer 16, and a barrier film which will be described later, when they are formed by using a wet coating method.

Then, this coat layer for the reinforcing film is UV-irradiated; or the coat layer for the reinforcing film is heated at 120 to 400° C., or preferably 120 to 200° C.; or the coat layer for the reinforcing film is heated at 120 to 400° C., or preferably 120 to 200° C., after being UV-irradiated. With this, the back electrode reinforcing film 17 having thickness of 0.01 to 2.0 or preferably 0.03 to 1.0 μm, is formed on the back electrode layer 16. Namely, the back electrode reinforcing film 17 is formed with thickness of 0.2 to 1 fold, or preferably 0.2 to 0.8 fold, relative to thickness of the back electrode layer 16. Here, when heating temperature of the coat layer for the reinforcing film is lower than 120° C., curing is insufficient because curing inside the back electrode reinforcing film is hindered due to a residual component such as solvent; and when the temperature is higher than 400° C., manufacturing merits of the low temperature process cannot be enjoyed. In addition, wavelength region of photoelectric conversion in a solar cell module of an amorphous silicon, a microcrystalline silicon, or a hybrid silicon thereof (multi-junction) is affected. Even when thickness of the back electrode reinforcing film 17 is made thin in a range between 0.2 and 1 fold relative to thickness of the back electrode layer 16, the back electrode reinforcing film 17 becomes a hard and fine film, with the wet coating method and by UV-irradiation and by heating. Accordingly, the back electrode reinforcing film 17 can protect electromagnetic properties and corrosion resistance of the back electrode layer 16. In addition, even when the separation groove 18 that penetrates through each film and layer is formed by a laser scriber, delamination or drop off of each Layer and film after formation of the separation groove 18 can be avoided. Meanwhile, it is preferable that a UV beam be irradiated about 1 to about 20 passes with accumulated light amount being 100 mJ/cm² or more by using a high pressure mercury lamp or a metal halide lamp.

After the back electrode reinforcing film 17 is formed, the photoelectric conversion unit 13 formed on the front electrode layer 12, the transparent and conductive film 14, the back electrode layer 16, and the back electrode reinforcing film 17 are patterned in strips by a laser scriber. Namely, separation process is conducted to form the separation groove 18. The separation groove 18 is formed from surface of the back electrode reinforcing film 17 extended onto the front electrode layer 12, for example, by using a laser separation-groove processing equipment by irradiation of a laser beam having a prescribed energy density from the substrate's side under an air atmosphere.

With this, a plurality of the photovoltaic elements 15 are formed with a space therebetween (separation groove 18) on the substrate 11 via the front electrode layer 12, so that these photovoltaic elements 15 may be connected electrically in series. In the space (separation groove 18) is arranged the filler layer 19 as described later. The back electrode layers 16 and 16 of the neighboring photovoltaic elements 15 and 15 are electrically separated with each other by the separation groove 18; and the photoelectric conversion units 13 and 13 of the neighboring photovoltaic elements 15 and 15 are separated with each other by the separation groove 18. The back electrode layer 16 of one of the neighboring photovoltaic elements 15 and 15 is electrically connected with the front electrode layer 16 of the other photovoltaic element 15 via the transparent and conductive film 14 wherein the separation groove 23 is arranged with the photoelectric conversion unit 13. As seen above, by electrically connecting the neighboring photovoltaic elements 15 and 15 in series, an electric current flows to one direction.

On the back electrode reinforcing film 17 is laminated the back film 21 via the filler layer 19. The back film 21 is formed with a resin film of a resin such as PET, PEN, ETFE, PVDF, PCTFE, PVF, and PC. Here, the back film 21 may be of a structure of a metal foil sandwiched between resin films or the like, or a metal plate such as a SUS steel plate and a Galvalume steel plate. The back film 21 also has a function to prevent water penetration from outside as far as possible. The filler layer 19 is formed with a resin such as EVA, EEA, PVB, silicon, urethane, acryl, and epoxy. The filler layer 19 also has a function as an adhesive as well as a buffer between the back film 21 and the back electrode reinforcing film 17.

As mentioned above, by the method of producing a solar cell module according to the first embodiment of the present invention, a hard and fine back electrode reinforcing film capable to adhere strongly to the back electrode layer can be obtained easily in a relatively short time with a wet coating method. As a result, the back electrode reinforcing film can protect electromagnetic properties and corrosion resistance of the back electrode layer. In addition, even when the separation groove that penetrates from the photoelectric conversion unit to the back electrode reinforcing film through the transparent and conductive film and the back electrode layer is formed by a laser scriber, delamination or drop off of each layer and film after formation of the separation groove can be avoided. Accordingly, the back electrode reinforcing film can be formed by a convenient method without using expensive and complicated manufacturing equipment having many controlling items, such as in vacuum equipment. As a result, a running cost can be made small, and in addition, a solar cell module can be produced relatively easily even if the module is made larger.

### Second Embodiment

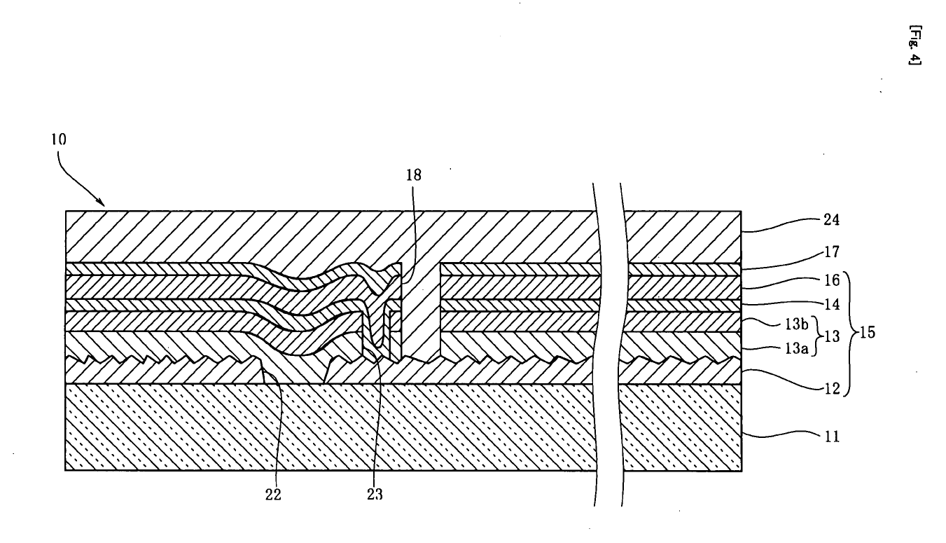

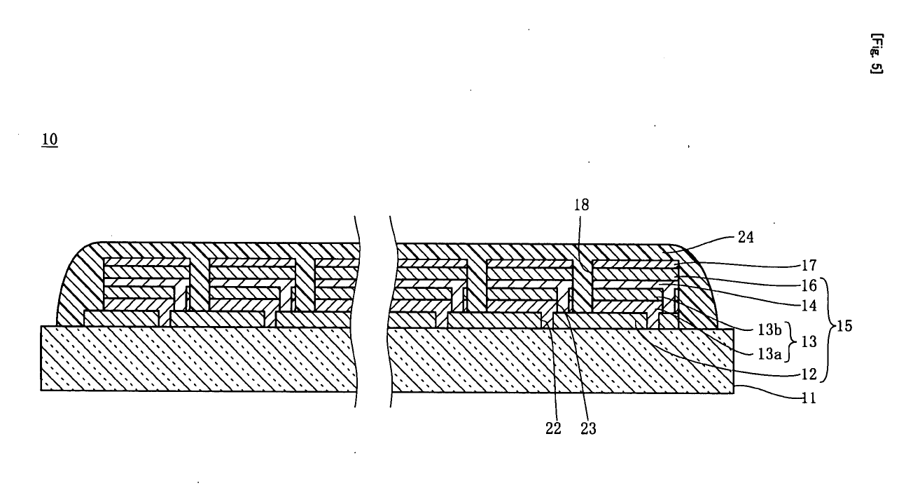

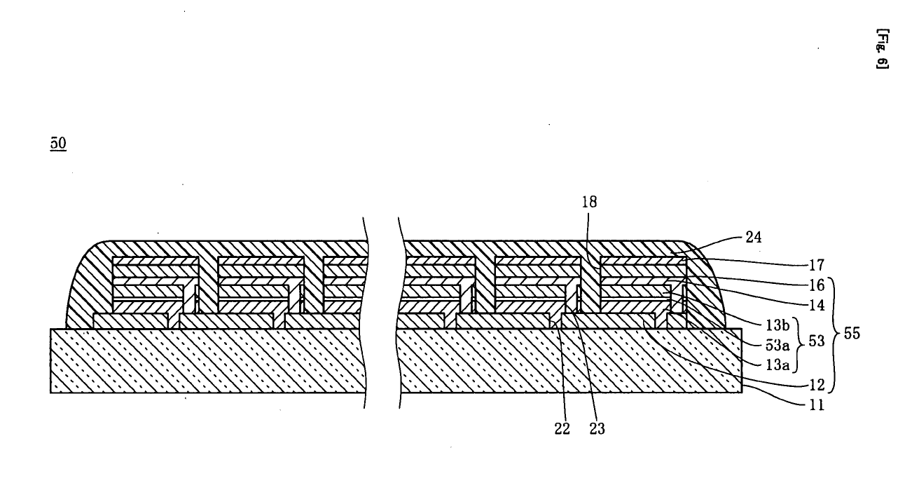

A second embodiment of the present invention is explained based on FIG. 4 to FIG. 6. In FIG. 4 to FIG. 6, the symbols identical to those in FIG. 1 to FIG. 3 show the same composition elements. As shown in FIG. 4 and FIG. 5, the thin film silicon solar cell module 10 is arranged with the substrate 11 having an insulative surface and the photovoltaic element 15 that is laminated on the substrate 11. The photovoltaic element 15 is formed on the substrate 11 by laminating the front electrode layer 12, the photoelectric conversion unit 13, the transparent and conductive film 14, and the back electrode layer 16, in this order. Further arranged is the back electrode reinforcing film 17 formed by UV-irradiation of, or by heating of, or by heating after UV-irradiation of a layer that is laminated on the photovoltaic element 15 by applying a composition for reinforcing film with a wet coating method; and further arranged is the structure wherein the barrier film 24 is formed by UV-irradiation of, or by heating of, or by heating after UV-irradiation of a layer that is obtained on the reinforcing film 17 by applying a composition for barrier film with a wet coating method. In this embodiment, on the backside opposite to the incident light side of the substrate 11 are arranged the photovoltaic element 15, the back electrode reinforcing film 17, and the barrier film 24, in this order. Meanwhile, in the second embodiment, compositions of the substrate 11, the front electrode layer 12, the photoelectric conversion unit 13, the transparent and conductive film 14, the back electrode layer 16, and the back electrode reinforcing film 17 are the same as those of the first embodiment; and thus, they are omitted.

After the back electrode reinforcing film 17 is formed, the photoelectric conversion unit 13 formed on the front electrode layer 12, the transparent and conductive film 14, the back electrode layer 16, and the back electrode reinforcing film 17 are patterned in strips by a laser scriber, thereby conducting separation process to form the separation groove 18; and thus, a plurality of the photovoltaic elements 15 are formed with a space therebetween (separation groove 18) on the substrate 11 via the front electrode layer 12, so that these photovoltaic elements 15 may be connected electrically in series. In the space (separation groove 18) is arranged the barrier film 24 as described later. The back electrode layers 16 and 16 of the neighboring photovoltaic elements 15 and 15 are electrically separated with each other by the separation groove 18; and the photoelectric conversion units 13 and 13 of the neighboring photovoltaic elements 15 and 15 are separated with each other by the separation groove 18. The back electrode layer 16 of one of the neighboring photovoltaic elements 15 and 15 is electrically connected with the front electrode layer 16 of the other photovoltaic element 15 via the transparent and conductive film 14 wherein the separation groove 23 is arranged with the photoelectric conversion unit 13. As seen above, by electrically connecting the neighboring photovoltaic elements 15 and 15 in series, an electric current flows to one direction.

To form the barrier film 24, firstly a composition for barrier film is applied on the reinforcing film 17 with a wet coating method. This is done by applying the composition for barrier layer in such a manner that the separation groove 18 formed by a laser scriber may be filled up with the composition. Then, the obtained layer is UV-irradiated, or heated, or heated after UV-irradiation to form the barrier film 24.

The composition for barrier film used to form the barrier film 24 contains any one of an organic-based or an inorganic-based material of a polymer type binder and an inorganic-based material of a non-polymer type binder or both, wherein the materials are curable by UV-irradiation, or by heating, or by heating after UV-irradiation. When these polymer type binders and non-polymer type binders are cured by UV-irradiation, or by heating, or by heating after UV-irradiation, the fine barrier layer 24 showing weatherability, water resistance, moisture resistance, heat resistance, and the like can be formed.

As to an organic-based or an inorganic-based material of a polymer type binder and an inorganic-based material of a non-polymer type binder, the foregoing materials exemplified in the composition for reinforcing film can be used.

It is preferable that a coupling agent is added in accordance with other components used in the composition for barrier film. The addition is made to improve adhesion with the underlayer film, the reinforcing film. Example of the coupling agent includes a silane coupling agent, an aluminum-coupling agent, and a titanium-coupling agent. As to the silane coupling agent, the aluminum-coupling agent, and the titanium-coupling agent to be used herein, the silane coupling agent, the aluminum-coupling agent, and the titanium-coupling agent, added in the composition for transparent and conductive film, can be used.

It is preferable that the composition for barrier film contains one, or two or more kinds of metal oxide microparticles or planular particles selected from the group consisting of colloidal silica, fumed silica particles, silica particles, mica particles, and smectite particles. When these metal oxide microparticles or planular particles are contained in the composition for barrier film, a baffle plate effect to prevent water penetration can be obtained so that water resistance and waterproof may be improved effectively, especially in the case that a binder of an organic-based material is used. As to the colloidal silica, the fumed silica particles, the silica particles, the mica particles, and the smectite particles, the foregoing particles exemplified in the composition for reinforcing film can be used.

It is preferable that the composition for barrier film contain microparticles or planular microparticles containing one, or two or more metals, or metal oxides of a metal, selected from the group consisting of gold, platinum, palladium, ruthenium, nickel, copper, tin, indium, zinc, iron, chromium, manganese, and aluminum. When these microparticles or planular microparticles are contained, a baffle plate effect to prevent water penetration can be obtained, similarly to the case of metal oxide microparticles or planular particles. Size and adding amount of these microparticles may be made the same as size and adding amount of the microparticles described in the foregoing composition for reinforcing film.

Meanwhile, as to the method to add and disperse an additive such as necessary foregoing particles, microparticles, or planular microparticles into a base solution of the composition for barrier film, methods similar to those described in the foregoing composition for reinforcing film may be used.

It is preferable that the barrier film 24 be formed by alternately layering one, or two or more inorganic barrier films, using a composition for barrier film that contains an inorganic-based material of a polymer type binder or an inorganic-based material of a non-polymer type binder, and one, or two or more organic barrier films, using a composition for barrier film that contains an organic-based material of a polymer type. It is particularly preferable that the inorganic barrier films and the organic barrier films be alternately layered to form a laminate of 3 to 5 plural layers. With this, the barrier film 24 having a plurality of laminated layers having different properties may be formed. An inorganic barrier film formed with a composition for barrier film that contains an inorganic-based material has high moisture resistance and heat resistance, so that excellent effect may be expected in view of obtaining a hard film, but a problem of forming a pore in the film may appear easily. On the other hand, an organic barrier film formed with a composition for barrier film that contains an organic-based material is excellent in water resistance and impact resistance, but poor in moisture resistance because of high permeability of water vapor. Accordingly, when the barrier film 24 is formed by lamination of a plurality of layers having different properties, each drawback can be redeemed so that the barrier film 24 may express its function with excellent properties such as fineness, water resistance, moisture resistance, weatherability, impact resistance, and heat resistance. The film having 6 or more layers is not preferable, because materials are wasted and manufacturing cost becomes high due to increased process steps, though there are no problems in properties.

To form the barrier film, single layer or a plurality of layers obtained as mentioned above by applying a composition for barrier film is UV-irradiated, or heated at 120 to 400° C., or preferably 120 to 200° C., or after being UV-irradiated, heated at 120 to 400° C., or preferably 120 to 200° C. When the heating temperature is lower than 120° C., cure is insufficient because cure of inside the back electrode reinforcing film is hindered due to a residual component such as solvent; and when the temperature is higher than 400° C., manufacturing merits of the low temperature process cannot be enjoyed. In other words, the manufacturing cost is increased and productivity is decreased; and in particular, wavelength region of photoelectric conversion in a solar cell module of an amorphous silicon, a microcrystalline silicon, or a hybrid silicon thereof (multi-junction) is affected. It is preferable that thickness of the formed barrier film 24 be in the range between 0.2 and 20 μm. When thickness of the barrier film 24 is less than 0.2 μm, it is difficult to keep adequate weatherability, water resistance, moisture resistance, and the like upon occurring of a defect: on the other hand, when the thickness is more than 20 μm, materials are wasted, though there is no problem in particular. In the foregoing range, thickness of the barrier film 24 is particularly preferable in the range between 0.2 to 10 μm.

As mentioned above, according to the method of producing a solar cell module in the second embodiment of the present invention, because the barrier film is formed by a wet coating method, materials having different properties can be laminated in layers intentionally. As a result, a solar cell having excellent reliability on such properties as weatherability, water resistance, and moisture resistance can be produced. In addition, a solar cell can be produced more cheaply by using a wet coating method with avoiding a vacuum process such as a vacuum vapor deposition method and a sputtering method as far as possible. Further in addition, because a solar cell module obtained by the method of the second embodiment of the present invention has the barrier film formed with a wet coating method, deterioration of power generation efficiency is small even under a humid environment, so that stable performance can be expressed for a long period of time.

### Third Embodiment

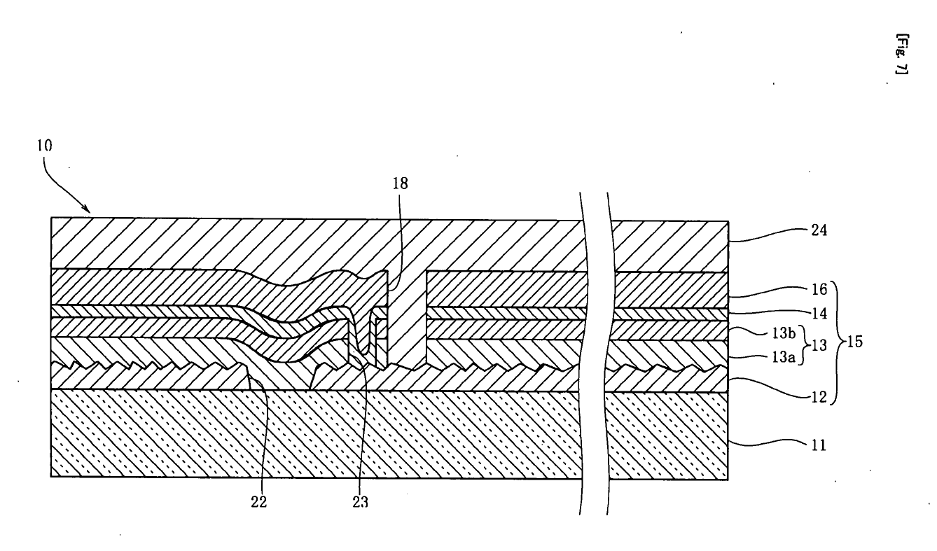

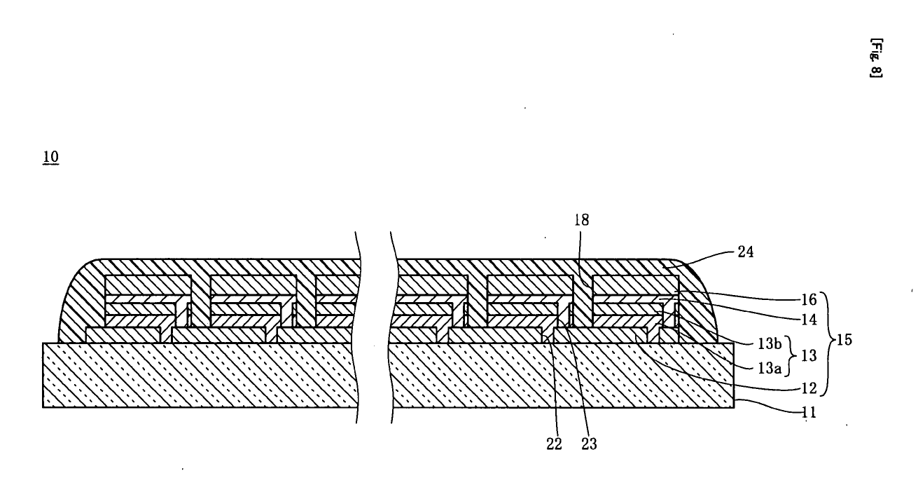

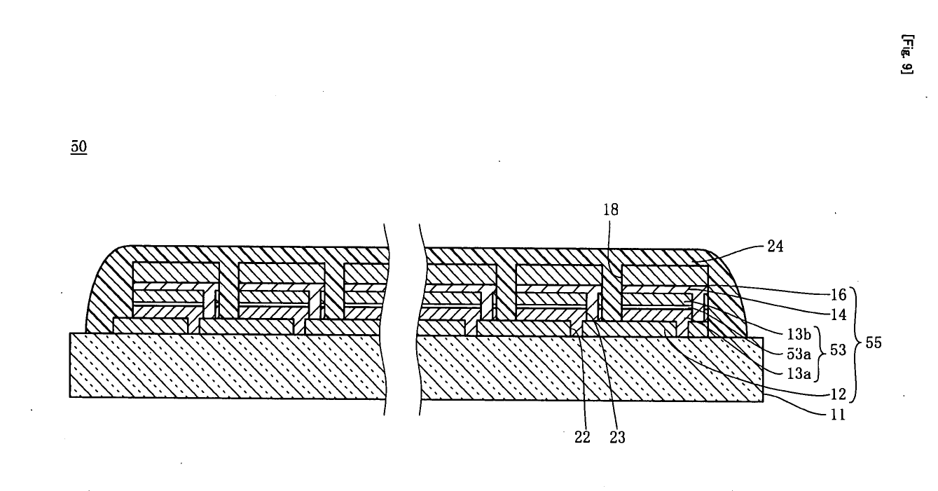

A third embodiment of the present invention is explained based on FIG. 7 to FIG. 9. In FIG. 7 to FIG. 9, the symbols identical to those in FIG. 1 to FIG. 3 show the same composition elements. As shown in FIG. 7 and FIG. 8, the thin film silicon solar cell module 10 is arranged with the substrate 11 having an insulative surface and the photovoltaic element 15 that is laminated on the substrate 11. The photovoltaic element 15 is formed on the substrate 11 by laminating the front electrode layer 12, the photoelectric conversion unit 13, the transparent and conductive film 14, and the back electrode layer 16, in this order. Further arranged is the barrier film 24 formed by UV-irradiation of, or by heating of, or by heating after UV-irradiation of a layer that is obtained on the back electrode layer 16 of the photovoltaic element 15 by applying a composition for barrier film with a wet coating method. In this embodiment, on the backside opposite to the incident light side of the substrate 11 are arranged the photovoltaic element 15 and the barrier film 24, in this order. Meanwhile, in the third embodiment, compositions of the substrate 11, the front electrode layer 12, the photoelectric conversion unit 13, the transparent and conductive film 14, and the back electrode layer 16 are the same as those of the first embodiment; and composition of the barrier film 24 is the same as that of the second embodiment; and thus, they are omitted. Alternatively, as shown in FIG. 4 and FIG. 5, the structure that the back electrode reinforcing film 17 is laminated on the photovoltaic element 15, and on this reinforcing film 17 is arranged the barrier film 24 formed by UV-irradiation of, or by heating of, or by heating after UV-irradiation of a layer that is obtained by applying the composition for barrier film with a wet coating method may also be allowed. In this case, the back electrode reinforcing film 17 is formed by a method other than the wet coating methods in the foregoing second embodiment, for example, by a sputtering and the like. The preferred is a sputtered film that contains highly corrosive-resistant Ti and is formed under atmosphere of reduced pressure at the temperature of about 150° C. It is preferable that the back electrode reinforcing film 17 by a sputtering method be formed with the thickness in the range between 0.1 and 2.0 μm. In this embodiment, on the backside opposite to the incident light side of the substrate 11 are arranged the photovoltaic element 15, the back electrode reinforcing film 17, and the barrier film 24, in this order.

As mentioned above, according to the method of producing a solar cell module in the third embodiment of the present invention, because the barrier film is formed by a wet coating method, a laminated film which is obtained by laminating materials having different properties laminated in layers intentionally. As a result, a solar cell having excellent reliability on such properties as weatherability, water resistance, and moisture resistance can be produced. In addition, a solar cell can be produced more cheaply by using a wet coating method with avoiding a vacuum process such as a vacuum vapor deposition method and a sputtering method as far as possible. Further in addition, because a solar cell module obtained by the method of the third embodiment of the present invention has a barrier film formed with a wet coating method, deterioration of power generation efficiency is small even under a humid environment, so that stable performance can be expressed for a long period of time.

### EXAMPLES

Hereinbelow, Examples of the present invention, along with Comparative Examples, will be explained in detail.

At first, back electrode layers No. 1 to No. 17, showing each composition for electrode that constitutes the respective back electrode layers formed by the following Examples 58 to 80 and Examples 104 to 126, and methods to form the respective back electrode layers by using each of the compositions thereof, are shown in the following Table 1.

TABLE 1

| | | | | | Conditions for | |
|---|---|---|---|---|---|---|
| Back | Composition for electrode | | | | heat treatment | |
| Electrode | Metal | | | Application | | Time, |
| Layer | nanoparticles | Additive 1 | Additive 2 | method | Temperature | atmosphere |
| No. 1 | Ag: 94% | PVP: 5% | Ni | Spin | 200° C. | 20 |
| | by mass | by mass | acetate: | | | minutes, |
| | | | 1% by mass | | | air |
| No. 2 | Ag: 96% | PVP: 3% | Cu | Spin | 200° C. | 20 |
| | by mass | by mass | acetate: | | | minutes, |
| | | | 1% by mass | | | air |
| No. 3 | Ag: 94% | Hydoroxy | Sn | Spin | 200° C. | 20 |
| | by mass | propyl | acetate: | | | minutes, |
| | Ru: 2% | methyl | 1% by mass | | | air |
| | by mass | cellulose: | | | | |
| | | 3% by | | | | |
| | | mass | | | | |
| No. 4 | Ag: 92% | PVP: 3% | Sn | Dispenser | 130° C. | 20 |
| | by mass | by mass | acetate: | | | minutes, |
| | Cu: 4% | | 1% by mass | | | air |
| | by mass | | | | | |
| No. 5 | Ag: | PVP: 3% | Zn | Offset | 320° C. | 20 |
| | 95.8% | by mass | acetate: | | | minutes, |
| | by mass | | 1% by mass | | | air |
| | Fe: 0.2% | | | | | |
| | by mass | | | | | |
| No. 6 | Ag: 95% | PVP: 4% | TiO₂: 1% by | Spin | 150° C. | 20 |
| | by mass | by mass | mass | | | minutes, |
| | | | | | | air |
| No. 7 | Ag: 95% | PVP: 4% | Cr₂O₃: 1% by | Spin | 150° C. | 20 |
| | by mass | by mass | mass | | | minutes, |
| | | | | | | air |
| No. 8 | Ag: 95% | PVP: 4% | MnO₂: 1% by | Spin | 150° C. | 20 |
| | by mass | by mass | mass | | | minutes, |
| | | | | | | air |
| No. 9 | Ag: 95% | PVP: 4% | Ag₂O: 1% by | Spin | 150° C. | 20 |
| | by mass | by mass | mass | | | minutes, |
| | | | | | | air |
| No. | Ag: 95% | PVP: 4% | MnO₂: 1% by | Spin | 150° C. | 20 |
| 10 | by mass | by mass | mass | | | minutes, |
| | | | | | | air |
| No. | Ag: 95% | PVP: 4% | SnO₂: 1% by | Spin | 150° C. | 20 |
| 11 | by mass | by mass | mass | | | minutes, |
| | | | | | | air |
| No. | Ag: 95% | PVP: 4% | Methyl | Spin | 150° C. | 20 |
| 12 | by mass | by mass | silicate: | | | minutes, |
| | | | 1% by mass | | | air |
| No. | Ag: 95% | PVP: 4% | Ti | Spin | 150° C. | 20 |
| 13 | by mass | by mass | isopropoxide: | | | minutes, |
| | | | 1% by mass | | | air |
| No. | Ag: | PVP: 4% | Mn | Spin | 150° C. | 20 |
| 14 | 95.9% | by mass | formate: | | | minutes, |
| | by mass | | 1% by mass | | | air |
| No. | Ag: | PVP: 4% | Co | Spin | 200° C. | 20 |
| 15 | 95.9% | by mass | formate: | | | minutes, |
| | by mass | | 0.01% | | | air |
| | | | by mass | | | |
| No. | Ag: 95% | Cu | — | Spin | 150° C. | 20 |
| 16 | by mass | acetate: | | | | minutes, |
| | | 5% by | | | | air |
| | | mass | | | | |
| No. | Ag: 95% | Sn | — | Die | 150° C. | 20 |
| 17 | by mass | acetate: | | | | minutes, |
| | | 5% by | | | | air |
| | | mass | | | | |

Then, each base solution classified into 1 to 12 Groups, which is a component of the composition for reinforcing film to be used for forming a back electrode reinforcing film and the composition for barrier film to be used for forming a barrier film was prepared as following.

### Base Solution of Group 1:

At first, 1,6-hexanediol diacryalte and trimethylol propane triacrylate were mixed with mass ratio of 1:1 to obtain a monomer mixture. The obtained monomer mixture was mixed with solvent MIBK (methyl isobutyl ketone) with mass ratio of 3:7. Then, to this acryl monomer mixture was added 5% by mass (relative to 100% by mass of the acryl monomer mixture) of 1-hydroxy-cyclohexyl-phenyl-ketone as photo-polymerization initiator with agitation, which was continued until a homogeneous solution was resulted. When a homogeneous solution was not resulted, the mixture was agitated with increasing the temperature till about 40° C. This base solution is curable by UV-irradiation.

Base solution of Group 2:

At first, neopentyl glycol diacrylate and tetramethylol methane tetraacrylate were mixed with mass ratio of 1:1 to obtain a monomer mixture. The obtained monomer mixture was mixed with solvent PGM (1-methoxy-2-propanol) with mass ratio of 1:1. Then, to this acryl monomer mixture was added 4% by mass (relative to 100% by mass of the acryl monomer mixture) of 2-hydroxy-2-methyl-1-phenyl-propane-1-one as photo-polymerization initiator with agitation, which was continued until a homogeneous solution was resulted. When a homogeneous solution was not resulted, the mixture was agitated with increasing the temperature till about 40° C. This base solution is curable by UV-irradiation.

### Base Solution of Group 3:

At first, 1,6-hexanediol diacrylate and ditrimethylol propane tetraacrylate were mixed with mass ratio of 4:6 to obtain a monomer mixture. The obtained monomer mixture was mixed with solvent PGMEA (propyleneglycol monomethyl ether acetate) with mass ratio of 4:6. Then, to this acryl monomer mixture was added 5% by mass (relative to 100% by mass of the acryl monomer mixture) of 1-hydroxy-cyclohexyl-phenyl-ketone as photo-polymerization initiator with agitation, which was continued until a homogeneous solution was resulted. When a homogeneous solution was not resulted, the mixture was agitated with increasing the temperature till about 40° C. This base solution is curable by UV-irradiation.

### Base Solution of Group 4:

At first, solvent BCA (butyl carbitol acetate) and a biphenyl type epoxy resin (YX4000; manufactured by Japan Epoxy Resin Co., Ltd.) were mixed with mass ratio of 7:3. Here, when a homogeneous solution was not resulted, the mixture was agitated with increasing the temperature till about 40° C. Then, to this mixture was added an appropriate amount of 2-ethyl-4-methylimidazole as a thermal curing agent. This base solution is curable by heating.

### Base Solution of Group 5:

At first, solvent ECA (ethyl carbitol acetate) and a cresol novolak type epoxy resin (EPICLON-665-EXP-S; manufactured by DIC Corp.) were mixed with mass ratio of 8:2. Here, when a homogeneous solution was not resulted, the mixture was agitated with increasing the temperature till about 40° C. Then, to this mixture was added an appropriate amount of boron fluoride.monoethanol amine as a thermal curing agent. This base solution is curable by heating.

### Base Solution of Group 6:

At first, solvent BC (butyl carbitol) and a biphenyl type epoxy resin (NC3000; manufactured by Nippon Kayaku Co., Ltd.) were mixed with mass ratio of 8:2. Here, when a homogeneous solution was not resulted, the mixture was agitated with increasing the temperature till about 40° C. Then, to this mixture was added an appropriate amount of DICY (dicyan diamide) as a thermal curing agent. This base solution is curable by heating.

### Base Solution of Group 7:

At first, solvent IPA (isopropyl alcohol) and water were mixed with mass ratio of 1:1 to prepare a solvent. To 94% by mass of this solvent mixture were added 1% by mass of hydroxypropyl cellulose (water-soluble cellulose derivative) and 5% by mass of gelatin; and then, the resulting mixture was mixed by increasing the temperature to about 30° C. This base solution is curable by heating.

### Base Solution of Group 8:

At first, 6% by mass of ATO particles (composite oxides of antimony oxide-tin oxide) having average particle diameter of 0.025 μm as the conductive oxide microparticles (Additive 2), 9% by mass of a titanium-coupling agent having a dialkyl pyrophosphite group (Additive 1) as the coupling agent, and 85% by mass of solvent mixture of ethanol and butanol (mass ratio of 98:2) as the disperser medium were mixed; and the resulting mixture was agitated with the rotation speed of 800 rpm at room temperature for one hour. Then, 60 g of this mixture was taken into a 100-mL glass bottle and dispersed in a paint shaker by using 100 g of zirconia beads having diameter of 0.3 mm (Microhica; manufactured by Showa Shell Sekiyu K. K.) for 6 hours to prepare a disperse solution of ATO particles. Meanwhile, the titanium-coupling agent having a dialkyl pyrophosphite group (Additive 1) is shown by the formula (3) described in the foregoing embodiment. Separately, 10% by mass of a SiO₂ binder as the binder and 90% by mass of the foregoing solvent mixture of ethanol and butanol (mass ratio of 98:2) were mixed to prepare a disperse solution of a SiO₂ binder. Here, the foregoing SiO₂ binder was prepared as following. At first, 1.0 g of 12N-HCl was dissolved into 25 g of pure water with stirring. Then, 140 g of tetraethoxy silane and 240 g of ethanol were taken into a 500-mL four-neck glass flask, and then the foregoing aqueous HCl solution was added into the flask all at once. Then, the reaction was carried out at 80° C. for 6 hours to obtain the SiO₂ binder. Thereafter, the disperse solution of ATO particles and the disperse solution of the SiO₂ binder were mixed to obtain a base solution. This base solution is curable by heating.

### Base Solution of Group 9:

At first, 8% by mass of ITO particles (composite oxides of indium oxide-tin oxide) having average particle diameter of 0.025 μm as the conductive oxide microparticles (Additive 2), 2% by mass of a titanium-coupling agent having a dialkyl pyrophosphite group (Additive 1) as the coupling agent, and 90% by mass of solvent mixture of ethanol and butanol (mass ratio of 98:2) as the disperser medium were mixed; and the resulting mixture was agitated with the rotation speed of 800 rpm at room temperature for one hour. Then, 60 g of this mixture was taken into a 100-mL glass bottle and dispersed in a paint shaker by using 100 g of zirconia beads having diameter of 0.3 mm (Microhica; manufactured by Showa Shell Sekiyu K. K.) for 6 hours to prepare a disperse solution of ITO particles (composite oxides of indium oxide-tin oxide). Meanwhile, the titanium-coupling agent having a dialkyl pyrophosphite group (Additive 1) is shown by the formula (2) described in the foregoing embodiment. A disperse solution of the SiO₂ binder was prepared in a manner similar to that for the disperse solution of the SiO₂ binder of Group 8. Then, the disperse solution of ITO particles and the disperse solution of the SiO₂ binder were mixed to obtain a base solution. This base solution is curable by heating.

### Base Solution of Group 10:

At first, 10% by mass of AZO particles (composite oxides of aluminum oxide-zinc oxide) having average particle diameter of 0.025 μm as the conductive oxide microparticles (Additive 2), 1.6% by mass of a titanium-coupling agent having a dialkyl pyrophosphite group (Additive 1) as the coupling agent, and 90% by mass of solvent mixture of methanol and ethanol (mass ratio of 4:1) as the disperser medium were mixed; and the resulting mixture was agitated with the rotation speed of 800 rpm at room temperature for one hour. Then, 60 g of this mixture was taken into a 100-mL glass bottle and dispersed in a paint shaker by using 100 g of zirconia beads having diameter of 0.3 mm (Microhica; manufactured by Showa Shell Sekiyu K. K.) for 6 hours to prepare a disperse solution of AZO particles. Meanwhile, the titanium-coupling agent having a dialkyl pyrophosphite group (Additive 1) is shown by the formula (4) described in the foregoing embodiment. A disperse solution of the SiO₂ binder was prepared in a manner similar to that for the disperse solution of the SiO₂ binder of Group 8. Then, the disperse solution of AZO particles and the disperse solution of the SiO₂ binder were mixed to obtain a base solution. This base solution is curable by heating.

### Base Solution of Group 11:

At first, solvent IPA (isopropyl alcohol) and methanol were mixed with mass ratio of 4:1 to prepare a solvent mixture. Then, the SiO₂ binder prepared in a manner similar to that in Group 8 was mixed with the foregoing solvent mixture to obtain a base solution containing 10% by mass of the binder. This base solution is curable by heating.

### Base Solution of Group 12:

At first, 1,6-hexanediol diacryalte and trimethylol propane triacrylate were mixed with mass ratio of 1:1 to obtain a monomer mixture. Then, 10% by mass of perhydropolysilazane was mixed with 90% by mass of xylene to prepare a perhydropolysilazane mixture solution. The monomer mixture previously prepared and the perhydropolysilazane mixture solution were mixed with the mass ratio of 3:97 to obtain a base solution. This base solution is curable by heating.

Then, Reinforcing Films No. 1 to No. 17, showing compositions for reinforcing film that constitutes the back electrode reinforcing film formed by the following Examples 35 to 80, and methods to form the back electrode reinforcing film by using the compositions thereof, are shown in the following Table 2.

### Reinforcing Film No. 1:

At first, 85% by mass of IPA (isopropyl alcohol) and 15% by mass of colloidal silica having average particle diameter of about 20 nm were mixed to prepare a colloidal silica disperse solution of Additive 1. Then, the acryl type base solution of Group 1 and the foregoing colloidal silica disperse solution were mixed and agitated with a disperser having an agitation blade at rotation speed of about 500 rpm for 5 minutes, whereby a coating solution of a composition for reinforcing film was obtained. Then, this coating solution (composition for reinforcing film) was applied with a spray coating instrument on the back electrode layer (silver electrode layer) of the laminated body that was laminated on the substrate with the front electrode layer, the photoelectric conversion unit, the transparent and conductive film, and the back electrode layer (silver electrode layer) in this order, in such a manner that a coat layer for the reinforcing film having film thickness of 500 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film.

### Reinforcing Film No. 2:

At first, 85% by mass of the acryl type base solution of Group 1 and 15% by mass of mica particles having average diameter of 5 μm and average thickness of about 20 nm (Micromica; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the mica particles into the base solution, whereby a coating solution of the composition for reinforcing film was obtained. Thereafter, this coating solution (composition for reinforcing film) was applied with a spray coating instrument on the back electrode layer (silver electrode layer) of the laminated body that was laminated on the substrate with the front electrode layer, the photoelectric conversion unit, the transparent and conductive film, and the back electrode layer (silver electrode layer) in this order, in such a manner that a coat layer for the reinforcing film having film thickness of 200 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film.

### Reinforcing Film No. 3:

At first, 95% by mass of the acryl type base solution of Group 2 and 5% by mass of planular Al particles having average diameter of 35 μm and average thickness of about 100 nm (Alpaste; manufactured by Toyo Aluminium K. K.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the Al particles into the base solution, whereby a coating solution of the composition for reinforcing film was obtained. Thereafter, this coating solution (composition for reinforcing film) was applied with a spin coating instrument on the back electrode layer (silver electrode layer) of the laminated body that was laminated on the substrate with the front electrode layer, the photoelectric conversion unit, the transparent and conductive film, and the back electrode layer (silver electrode layer) in this order, in such a manner that a coat layer for the reinforcing film having film thickness of 400 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film.

### Reinforcing Film No. 4:

At first, 90% by mass of the acryl type base solution of Group 2 and 10% by mass of silica particles having average particle diameter of about 20 nm (Silica; manufactured by Fuso Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the silica particles into the base solution, whereby a coating solution of the composition for reinforcing film was obtained. Thereafter, this coating solution (composition for reinforcing film) was applied with a spin coating instrument on the back electrode layer (silver electrode layer) of the laminated body that was laminated on the substrate with the front electrode layer, the photoelectric conversion unit, the transparent and conductive film, and the back electrode layer (silver electrode layer) in this order, in such a manner that a coat layer for the reinforcing film having film thickness of 300 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film.

### Reinforcing Film No. 5:

At first, 95% by mass of the acryl type base solution of Group 3 and 5% by mass of planular smectite particles having average diameter of 140 nm and average thickness of about 50 nm (Synthetic Smectite; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the smectite particles into the base solution, whereby a coating solution of the composition for reinforcing film was obtained. Thereafter, this coating solution (composition for reinforcing film) was applied with a spin coating instrument on the back electrode layer (silver electrode layer) of the laminated body that was laminated on the substrate with the front electrode layer, the photoelectric conversion unit, the transparent and conductive film, and the back electrode layer (silver electrode layer) in this order, in such a manner that a coat layer for the reinforcing film having film thickness of 150 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film.

### Reinforcing Film No. 6:

At first, 93% by mass of the epoxy type base solution of Group 4 and 7% by mass of planular Al particles having average diameter of 27 μm and average thickness of about 100 nm (Alpaste; manufactured by Toyo Aluminium K. K.) as Additive 1 were mixed and agitated with a rotor at rotation speed of about 300 rpm for one hour at room temperature to adapt the mixture thoroughly. Then, the mixture was agitated with a disperser blade capable of high-speed rotation till 2000 rpm to disperse the Al particles into the base solution, whereby a coating solution of the composition for reinforcing film was obtained. Thereafter, this coating solution (composition for reinforcing film) was applied with a spray coating instrument on the back electrode layer (silver electrode layer) of the laminated body that was laminated on the substrate with the front electrode layer, the photoelectric conversion unit, the transparent and conductive film, and the back electrode layer (silver electrode layer) in this order, in such a manner that a coat layer for the reinforcing film having film thickness of 400 nm after curing might be formed. Then, after drying at room temperature for 20 minutes or longer, a solar cell module was kept in a hot air drying oven at 150° C. for 20 minutes to thermally cure the coat layer for the reinforcing film to obtain the back electrode reinforcing film.

### Reinforcing Film No. 7:

At first, 80% by mass of the epoxy type base solution of Group 4 and 20% by mass of mica particles having average diameter of 1 μm and average thickness of about 20 nm (Micromica; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the mica particles into the base solution, whereby a coating solution of the composition for reinforcing film was obtained. During this operation, shape of the blade and rotation speed were carefully controlled so that temperature of the coating solution might not become 70° C. or higher. Thereafter, this coating solution (composition for reinforcing film) was applied with a spin coating instrument on the back electrode layer (silver electrode layer) that was laminated on the substrate with the front electrode layer, the photoelectric conversion unit, the transparent and conductive film, and the back electrode layer (silver electrode layer) in this order, in such a manner that a coat layer for the reinforcing film having film thickness of 200 nm after curing might be formed. Then, after drying at room temperature for 20 minutes or longer, a solar cell module was kept in a hot air drying oven at 200° C. for 20 minutes to thermally cure the coat layer for the reinforcing film to obtain the back electrode reinforcing film.

### Reinforcing Film No. 8:

At first, 97% by mass of the epoxy type base solution of Group 5 and 3% by mass of a fumed silica disperse solution (Aerosil; manufactured by Nippon Aerosil Co., Ltd.) as Additive 1 were mixed and dispersed with an ultrasonic vibration instrument for 10 minutes at room temperature to adapt the mixture thoroughly, whereby a coating solution of the composition for reinforcing film was obtained. Thereafter, this coating solution (composition for reinforcing film) was applied with a die coating instrument on the back electrode layer (silver electrode layer) that was laminated on the substrate with the front electrode layer, the photoelectric conversion unit, the transparent and conductive film, and the back electrode layer (silver electrode layer) in this order, in such a manner that a coat layer for the reinforcing film having film thickness of 150 nm after curing might be formed. Then, after drying at room temperature for 20 minutes or longer, a solar cell module was kept in a hot air drying oven at 180° C. for 30 minutes to thermally cure the coat layer for the reinforcing film to obtain the back electrode reinforcing film. Meanwhile, the fumed silica disperse solution was prepared as following. Firstly, 10% by mass of fumed silica particles and 90% by mass of a mixed solvent of IPA (isopropyl alcohol) and ethanol (mass ratio of 2:1) were mixed and then agitated at rotation speed of 800 rpm at room temperature for one hour to prepare a mixture. Then, 60 g of this mixture was taken into a 100-mL glass bottle and dispersed in a paint shaker by using 100 g of zirconia beads having diameter of 0.3 mm (Microhica; manufactured by Showa Shell Sekiyu K. K.) for 6 hours to prepare the disperse solution of fumed silica of the conductive oxide microparticles.

### Reinforcing Film No. 9:

At first, 95% by mass of the epoxy type base solution of Group 6 and 5% by mass of planular smectite particles having average diameter of 180 nm and average thickness of about 30 nm (Synthetic Smectite; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the smectite particles into the base solution, whereby a coating solution of the composition for reinforcing film was obtained. During this operation, shape of the blade and rotation speed were carefully controlled so that temperature of the coating solution might not become 70° C. or higher. Thereafter, this coating solution (composition for reinforcing film) was applied with a slit coating instrument on the back electrode layer (silver electrode layer) that was laminated on the substrate with the front electrode layer, the photoelectric conversion unit, the transparent and conductive film, and the back electrode layer (silver electrode layer) in this order, in such a manner that a coat layer for the reinforcing film having film thickness of 400 nm after curing might be formed. Then, after drying at room temperature for 20 minutes or longer, a solar cell module was kept in a hot air drying oven at 200° C. for 20 minutes to thermally cure the coat layer for the reinforcing film to obtain the back electrode reinforcing film.

### Reinforcing Film No. 10:

At first, 87% by mass of the epoxy type base solution of Group 6 and 13% by mass of the colloidal silica disperse solution as Additive 1 were mixed with a planetary agitating instrument at room temperature for 10 minutes to adapt the mixture, whereby a coating solution of a composition for reinforcing film was obtained. Then, this coating solution (composition for reinforcing film) was applied with a screen printing instrument on the back electrode layer (silver electrode layer) that was laminated on the substrate with the front electrode layer, the photoelectric conversion unit, the transparent and conductive film, and the back electrode layer (silver electrode layer) in this order, in such a manner that a coat layer for the reinforcing film having film thickness of 900 nm after curing might be formed. Then, after drying at room temperature for 20 minutes or longer, a solar cell module was kept in a hot air drying oven at 200° C. for 20 minutes to thermally cure the coat layer for the reinforcing film to obtain the back electrode reinforcing film. Here, the colloidal silica disperse solution was prepared in a manner similar to that for the fumed silica disperse solution of Reinforcing Film No. 8.

### Reinforcing Film No. 11:

At first, 90% by mass of the cellulose type base solution of Group 7 and 10% by mass of silica particles having average particle diameter of about 30 nm (Silica; manufactured by Fuso Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the silica particles into the base solution, whereby a coating solution of the composition for reinforcing film was obtained. Thereafter, this coating solution (composition for reinforcing film) was applied with a spin coating instrument on the back electrode layer (silver electrode layer) that was laminated on the substrate with the front electrode layer, the photoelectric conversion unit, the transparent and conductive film, and the back electrode layer (silver electrode layer) in this order, in such a manner that a coat layer for the reinforcing film having film thickness of 400 nm after curing might be formed. Then, after drying at room temperature for 20 minutes or longer, a solar cell module was kept in a hot air drying oven at 180° C. for 20 minutes to thermally cure the coat layer for the reinforcing film to obtain the back electrode reinforcing film.

### Reinforcing Film No. 12:

At first, 85% by mass of IPA (isopropyl alcohol) and 15% by mass of colloidal silica having average particle diameter of about 20 run were mixed to prepare a colloidal silica disperse solution (Snowtex 20; manufactured by Nissan Chemical Industries, Ltd.) of Additive 3. Then, 75% by mass of the SiO₂ binder type base solution of Group 8 and 25% by mass of the colloidal silica disperse solution were mixed and dispersed with an ultrasonic vibration instrument for 10 minutes at room temperature to adapt the mixture thoroughly, whereby a coating solution of the composition for reinforcing film was obtained. Then, this coating solution (composition for reinforcing film) was applied with a spin coating instrument on the back electrode layer (silver electrode layer) of the laminated body that was laminated on the substrate with the front electrode layer, the photoelectric conversion unit, the transparent and conductive film, and the back electrode layer (silver electrode layer) in this order, in such a manner that a coat layer for the reinforcing film having film thickness of 200 nm after curing might be formed. Then, after the solvent was removed from the coat layer for the reinforcing film by drying under vacuum, a solar cell module was kept in a hot air drying oven at 200° C. for 30 minutes to thermally cure the coat layer for the reinforcing film to obtain the back electrode reinforcing film. Meanwhile, in Table 2, titanium-coupling agent 1 of Additive 1 and ATO (composite oxides of antimony oxide-tin oxide) particles of Additive 2 were already included in the base solution, and thus added amounts of these additives were shown by the rates (values in brackets) relative to 100% of the total coating solution (composition for reinforcing film).

### Reinforcing Film No. 13:

At first, 98% by mass of the SiO₂ binder type base solution of Group 8 and 2% by mass of the fumed silica disperse solution as Additive 3 were mixed and dispersed with an ultrasonic vibration instrument for 10 minutes at room temperature to adapt the mixture thoroughly, whereby a coating solution of the composition for reinforcing film was obtained. Then, this coating solution (composition for reinforcing film) was applied with a spray coating instrument on the back electrode layer (silver electrode layer) that was laminated on the substrate with the front electrode layer, the photoelectric conversion unit, the transparent and conductive film, and the back electrode layer (silver electrode layer) in this order, in such a manner that a coat layer for the reinforcing film having film thickness of 150 nm after curing might be formed. Then, after the solvent was removed from the coat layer for the reinforcing film by drying under vacuum, a solar cell module was kept in a hot air drying oven at 150° C. for 20 minutes to thermally cure the coat layer for the reinforcing film to obtain the back electrode reinforcing film. Meanwhile, in Table 2, titanium-coupling agent 1 of Additive 1 and ATO (composite oxides of antimony oxide-tin oxide) particles of Additive 2 were already included in the base solution, and thus added amounts of these additives were shown by the rates (values in brackets) relative to 100% of the total coating solution (composition for reinforcing film). The fumed silica disperse solution was prepared in a manner similar to that for the fumed silica disperse solution of Reinforcing Film No. 8.

### Reinforcing Film No. 14:

At first, 95% by mass of the SiO₂ binder type base solution of Group 9 and 5% by mass of the fumed silica disperse solution as Additive 3 were mixed and dispersed with an ultrasonic vibration instrument for 10 minutes at room temperature, to adapt the mixture thoroughly, whereby a coating solution of the composition for reinforcing film was obtained. Then, this coating solution (composition for reinforcing film) was applied with a die coating instrument on the back electrode layer (silver electrode layer) that was laminated on the substrate with the front electrode layer, the photoelectric conversion unit, the transparent and conductive film, and the back electrode layer (silver electrode layer) in this order, in such a manner that a coat layer for the reinforcing film having film thickness of 350 nm after curing might be formed. Then, after the solvent was removed from the coat layer for the reinforcing film by drying under vacuum, a solar cell module was kept in a hot air drying oven at 180° C. for 20 minutes to thermally cure the coat layer for the reinforcing film to obtain the back electrode reinforcing film. Meanwhile, in Table 2, titanium-coupling agent 2 of Additive 1 and ITO (composite oxides of indium oxide-tin oxide) particles of Additive 2 were already included in the base solution, and thus added amounts of these additives were shown by the rates (values in brackets) relative to 100% of the total coating solution (composition for reinforcing film). The fumed silica disperse solution was prepared in a manner similar to that for the fumed silica disperse solution of Reinforcing Film No. 8.

### Reinforcing Film No. 15:

At first, 90% by mass of the SiO₂ binder type base solution of Group 9 and 10% by mass of mica particles having average diameter of 5 μm and average thickness of about 20 nm (Micromica; manufactured by Co-op Chemical Co., Ltd.) as Additive 3 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the mica particles into the base solution, whereby a coating solution of the composition for reinforcing film was obtained. During this operation, shape of the blade and rotation speed were carefully controlled so that temperature of the coating solution might not become 70° C. or higher. Thereafter, this coating solution (composition for reinforcing film) was applied with a spin coating instrument on the back electrode layer (silver electrode layer) that was laminated on the substrate with the front electrode layer, the photoelectric conversion unit, the transparent and conductive film, and the back electrode layer (silver electrode layer) in this order, in such a manner that a coat layer for the reinforcing film having film thickness of 200 nm after curing might be formed. Then, after drying at room temperature for 20 minutes or longer, a solar cell module was kept in a hot air drying oven at 200° C. for 30 minutes to thermally cure the coat layer for the reinforcing film to obtain the back electrode reinforcing film. Meanwhile, in Table 2, titanium-coupling agent 2 of Additive 1 and ITO (composite oxides of indium oxide-tin oxide) particles of Additive 2 were already included in the base solution, and thus added amounts of these additives were shown by the rates (values in brackets) relative to 100% by mass of the total coating solution (composition for reinforcing film).

### Reinforcing Film No. 16:

At first, 96% by mass of the acryl type base solution of Group 1 and 4% by mass of Al particles having average diameter of 27 μm and average thickness of about 100 nm (Alpaste; manufactured by Toyo Aluminium K. K.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the Al particles into the base solution, whereby a coating solution of the composition for reinforcing film was obtained. Thereafter, this coating solution (composition for reinforcing film) was applied with a die coating instrument on the back electrode layer (silver electrode layer) that was laminated on the substrate with the front electrode layer, the photoelectric conversion unit, the transparent and conductive film, and the back electrode layer (silver electrode layer) in this order, in such a manner that a coat layer for the reinforcing film having film thickness of 250 nm after curing might be formed. Then, the solvent was removed from the coat layer for the reinforcing film by drying under vacuum; and after the coat layer for the reinforcing film was irradiated with UV-beam with a UV-beam irradiation instrument to cure the coat layer for the reinforcing film with UV-beam, a solar cell module was kept in a hot air drying oven at 70° C. for 3 hours to thermally cure the coat layer for the reinforcing film to obtain the back electrode reinforcing film that was thoroughly cured.

### Reinforcing Film No. 17:

At first, 85% by mass of IPA (isopropyl alcohol) and 15% by mass of colloidal silica having average particle diameter of about 20 nm were mixed to prepare a colloidal silica disperse solution (IPA-ST-UP; manufactured by Nissan Chemical Industries, Ltd.) of Additive 1. Then, 93% by mass of the acryl type base solution of Group 1 and 7% by mass of the colloidal silica disperse solution were mixed and dispersed with an ultrasonic vibration instrument for 10 minutes at room temperature to adapt the mixture thoroughly, whereby a coating solution of the composition for reinforcing film was obtained. Then, this coating solution (composition for reinforcing film) was applied with a spin coating instrument on the back electrode layer (silver electrode layer) that was laminated on the substrate with the front electrode layer, the photoelectric conversion unit, the transparent and conductive film, and the back electrode layer (silver electrode layer) in this order, in such a manner that a coat layer for the reinforcing film having film thickness of 400 nm after curing might be formed. Then, the solvent was removed from the coat layer for the reinforcing film by drying under vacuum; and after the coat layer for the reinforcing film was irradiated with UV-beam with a UV-beam irradiation instrument to cure the coat layer for the reinforcing film with UV-beam, a solar cell module was kept in a hot air drying oven at 70° C. for 3 hours to thermally cure the coat layer for the reinforcing film to obtain the back electrode reinforcing film that was thoroughly cured.

TABLE 2

| | Composition for reinforcing film | | | | | | | | | | |
|---|---|---|---|---|---|---|---|---|---|---|---|
| | | Base solution | | Additive 1 | | Additive 2 | | Additive 3 | | | |
| Rein- | | | Content | | Content | | Content | | Content | Film | |
| forcing | Curing | | (% by | | (% by | | (% by | | (% by | thickness | Coating |
| Film | method | Group | mass) | Kind | mass) | Kind | mass) | Kind | mass) | (nm) | method |
| No. 1 | UV | 1 | 90 | Colloidal silica | 10 | — | — | — | — | 500 | Spray |
| | | | | disperse solution | | | | | | | |
| No. 2 | UV | 1 | 85 | Mica particles | 15 | — | — | — | — | 200 | Spray |
| No. 3 | UV | 2 | 95 | Al particles | 5 | — | — | — | — | 400 | Spin |
| No. 4 | UV | 2 | 90 | Silica particles | 10 | — | — | — | — | 300 | Spin |
| No. 5 | UV | 3 | 95 | Smectite particles | 5 | — | — | — | — | 150 | Spin |
| No. 6 | Heat | 4 | 93 | Al particles | 7 | — | — | — | — | 400 | Spray |
| No. 7 | Heat | 4 | 80 | Mica particles | 20 | — | — | — | — | 200 | Spin |
| No. 8 | Heat | 5 | 97 | Fumed silica | 3 | — | — | — | — | 150 | Die |
| | | | | disperse solution | | | | | | | |
| No. 9 | Heat | 6 | 95 | Smectite particles | 5 | — | — | — | — | 400 | Slit |
| No. 10 | Heat | 6 | 87 | Colloidal silica | 13 | — | — | — | — | 900 | Screen |
| | | | | disperse solution | | | | | | | |
| No. 11 | Heat | 7 | 90 | Silica particles | 10 | — | — | — | — | 400 | Spin |
| No. 12 | Heat | 8 | 75 | Titanium-coupling | (7) | ATO | (5) | Colloidal | 25 | 200 | Spin |
| | | | | agent 1 | | particles | | silica | | | |
| | | | | | | | | disperse | | | |
| | | | | | | | | solution | | | |
| No. 13 | Heat | 8 | 98 | Titanium-coupling | (9) | ATO | (6) | Fumed | 2 | 150 | Spray |
| | | | | agent 1 | | particles | | silica | | | |
| | | | | | | | | disperse | | | |
| | | | | | | | | solution | | | |
| No. 14 | Heat | 9 | 95 | Titanium-coupling | (2) | ITO | (8) | Fumed | 5 | 350 | Die |
| | | | | agent 2 | | particles | | silica | | | |
| | | | | | | | | disperse | | | |
| | | | | | | | | solution | | | |
| No. 15 | Heat | 9 | 90 | Titanium-coupling | (2) | ITO | (7) | Mica | 10 | 200 | Spin |
| | | | | agent 2 | | particles | | particles | | | |
| No. 16 | UV + Heat | 1 | 96 | Al particles | 4 | — | — | — | — | 250 | Die |
| No. 17 | UV + Heat | 1 | 93 | Colloidal silica | 7 | — | — | — | — | 400 | Spin |
| | | | | disperse solution | | | | | | | |

Then, Barrier Films No. 1 to No. 24, showing compositions for barrier film that constitutes the barrier film formed by the following Examples 35 to 126, and methods to form the barrier film by using the compositions thereof, are shown in the following Tables 3 and 4.

### Barrier Film No. 1:

At first, 85% by mass of IPA (isopropyl alcohol) and 15% by mass of colloidal silica having average particle diameter of about 20 nm were mixed to prepare a colloidal silica disperse solution of Additive 1. Then, the acryl type base solution of Group 1 and the foregoing colloidal silica disperse solution were mixed and agitated with a disperser having an agitation blade at rotation speed of about 500 rpm for 5 minutes, whereby a coating solution of a composition for barrier film was obtained. Then, this coating solution (composition for barrier film) was applied with a spray coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 800 nm after curing might be formed. Then, after the solvent was removed from the coat layer by drying under vacuum, the coat layer was irradiated with UV beam by using a UV irradiation instrument to cure the coat layer with UV beam to obtain the barrier film.

### Barrier Film No. 2:

At first, 85% by mass of the acryl type base solution of Group 1 and 15% by mass of mica particles having average diameter of 5 μm and average thickness of about 20 nm (Micromica; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the mica particles into the base solution, whereby a coating solution of the composition for barrier film was obtained. Thereafter, this coating solution (composition for barrier film) was applied with a spray coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 600 nm after curing might be formed. Then, after the solvent was removed from the coat layer by drying under vacuum, the coat layer was irradiated with UV beam by using a UV irradiation instrument to cure the coat layer with UV beam to obtain the barrier film.

### Barrier Film No. 3:

At first, 95% by mass of the acryl type base solution of Group 2 and 5% by mass of Al particles having average diameter of 35 μm and average thickness of about 100 nm (Alpaste; manufactured by Toyo Aluminium K. K.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the Al particles into the base solution, whereby a coating solution of the composition for barrier film was obtained. Thereafter, this coating solution (composition for barrier film) was applied with a spin coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 400 nm after curing might be formed. Then, after the solvent was removed from the coat layer by drying under vacuum, the coat layer was irradiated with UV beam by using a UV irradiation instrument to cure the coat layer with UV beam to obtain the barrier film.

### Barrier Film No. 4:

At first, 90% by mass of the acryl type base solution of Group 2 and 10% by mass of silica particles having average particle diameter of about 20 nm (Silica; manufactured by Fuso Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the silica particles into the base solution, whereby a coating solution of the composition for barrier film was obtained. Thereafter, this coating solution (composition for barrier film) was applied with a spin coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 750 nm after curing might be formed. Then, after the solvent was removed from the coat layer by drying under vacuum, the coat layer was irradiated with UV beam by using a UV irradiation instrument to cure the coat layer with UV beam to obtain the barrier film.

### Barrier Film No. 5:

At first, 95% by mass of the acryl type base solution of Group 3 and 5% by mass of smectite particles having average diameter of 140 nm and average thickness of about 50 nm (Synthetic Smectite; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the smectite particles into the base solution, whereby a coating solution of the composition for barrier film was obtained. Thereafter, this coating solution (composition for barrier film) was applied with a spin coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 1000 nm after curing might be formed. Then, after the solvent was removed from the coat layer by drying under vacuum, the coat layer was irradiated with UV beam by using a UV irradiation instrument to cure the coat layer with UV beam to obtain the barrier film.

### Barrier Film No. 6:

At first, 93% by mass of the epoxy type base solution of Group 4 and 7% by mass of Al particles having average diameter of 27 μm and average thickness of about 1.00 nm (Alpaste; manufactured by Toyo Aluminium K. K.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the Al particles into the base solution, whereby a coating solution of the composition for barrier film was obtained. Thereafter, this coating solution (composition for barrier film) was applied with a spray coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 1200 nm after curing might be formed. Then, after drying at room temperature for 20 minutes or longer, a solar cell module was kept in a hot air drying oven at 150° C. for 20 minutes to thermally cure the coat layer to obtain the barrier film.

### Barrier Film No. 7:

At first, 80% by mass of the epoxy type base solution of Group 4 and 20% by mass of mica particles having average diameter of 1 μm and average thickness of about 20 nm (Micromica; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the mica particles into the base solution, whereby a coating solution of the composition for barrier film was obtained. During this operation, shape of the blade and rotation speed were carefully controlled so that temperature of the coating solution might not become 70° C. or higher. Thereafter, this coating solution (composition for barrier film) was applied with a spin coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 900 nm after curing might be formed. Then, after drying at room temperature for 20 minutes or longer, a solar cell module was kept in a hot air drying oven at 200° C. for 20 minutes to thermally cure the coat layer to obtain the barrier film.

### Barrier Film No. 8:

At first, 97% by mass of the epoxy type base solution of Group 5 and 3% by mass of a fumed silica disperse solution (Aerosil; manufactured by Nippon Aerosil Co., Ltd.) as Additive 1 were mixed and dispersed with an ultrasonic vibration instrument for 10 minutes at room temperature to adapt the mixture thoroughly, whereby a coating solution of the composition for barrier film was obtained. Thereafter, this coating solution (composition for barrier film) was applied with a die coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 150 nm after curing might be formed. Then, after drying at room temperature for 20 minutes or longer, a solar cell module was kept in a hot air drying oven at 180° C. for 30 minutes to thermally cure the coat layer to obtain the barrier film. Meanwhile, the fumed silica disperse solution was prepared as following. Firstly, 10% by mass of fumed silica particles and 90% by mass of a mixed solvent of IPA (isopropyl alcohol) and ethanol (mass ratio of 2:1) were mixed and then agitated at rotation speed of 800 rpm at room temperature for one hour to prepare a mixture. Then, 60 g of this mixture was taken into a 100-mL glass bottle and dispersed in a paint shaker by using 100 g of zirconia beads having diameter of 0.3 mm (Microhica; manufactured by Showa Shell Sekiyu K. K.) for 6 hours to prepare the disperse solution of fumed silica of the conductive oxide microparticles.

### Barrier Film No. 9:

At first, 95% by mass of the epoxy type base solution of Group 6 and 5% by mass of planular smectite particles having average diameter of 180 nm and average thickness of about 30 nm (Synthetic Smectite; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the smectite particles into the base solution, whereby a coating solution of the composition for barrier film was obtained. During this operation, shape of the blade and rotation speed were carefully controlled so that temperature of the coating solution might not become 70° C. or higher. Thereafter, this coating solution (composition for barrier film) was applied with a slit coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 400 nm after curing might be formed. Then, after drying at room temperature for 20 minutes or longer, a solar cell module was kept in a hot air drying oven at 200° C. for 20 minutes to thermally cure the coat layer to obtain the barrier film.

### Barrier Film No. 10:

At first, 87% by mass of the epoxy type base solution of Group 6 and 13% by mass of the colloidal silica disperse solution as Additive 1 were mixed with a planetary agitating instrument at room temperature for 10 minutes to adapt the mixture thoroughly, whereby a coating solution of a composition for barrier film was obtained. Then, this coating solution (composition for barrier film) was applied with a screen printing instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 900 nm after curing might be formed. Then, after drying at room temperature for 20 minutes or longer, a solar cell module was kept in a hot air drying oven at 200° C. for 30 minutes to thermally cure the coat layer to obtain the barrier film. Here, the colloidal silica disperse solution was prepared in a manner similar to that for the fumed silica disperse solution of Barrier Film No. 8.

### Barrier Film No. 11:

At first, 90% by mass of the cellulose type base solution of Group 7 and 10% by mass of silica particles having average particle diameter of about 30 nm (Silica; manufactured by Fuso Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the silica particles into the base solution, whereby a coating solution of the composition for barrier film was obtained. Then, this coating solution (composition for barrier film) was applied with a spin coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 700 nm after curing might be formed. Then, after drying at room temperature for 20 minutes or longer, a solar cell module was kept in a hot air drying oven at 180° C. for 20 minutes to thermally cure the coat layer to obtain the barrier film.

### Barrier Film No. 12:

At first, 85% by mass of IPA (isopropyl alcohol) and 15% by mass of colloidal silica having average particle diameter of about 20 nm were mixed to prepare a colloidal silica disperse solution (Snowtex 20; manufactured by Nissan Chemical Industries, Ltd.) of Additive 3. Then, 75% by mass of the SiO₂ binder type base solution of Group 8 and 25% by mass of the colloidal silica disperse solution were mixed and dispersed with an ultrasonic vibration instrument for 10 minutes at room temperature to adapt the mixture thoroughly, whereby a coating solution of the composition for barrier film was obtained. Then, this coating solution (composition for barrier film) was applied with a spin coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of200 nm after curing might be formed. Then, after the solvent was removed from the coat layer by drying under vacuum, a solar cell module was kept in a hot air drying oven at 200° C. for 30 minutes to thermally cure the coat layer to obtain the barrier film. Meanwhile, in Table 3, titanium-coupling agent 1 of Additive 1 and ATO (antimony-doped tin oxide) particles of Additive 2 were already included in the base solution, and thus added amounts of these additives were shown by the rates (values in brackets) relative to 100% of the total coating solution (composition for barrier film).

### Barrier Film No. 13:

At first, 98% by mass of the SiO₂ binder type base solution of Group 8 and 2% by mass of the fumed silica disperse solution as Additive 3 were mixed and dispersed with an ultrasonic vibration instrument for 10 minutes at room temperature to adapt the mixture thoroughly, whereby a coating solution of the composition for barrier film was obtained. Then, this coating solution (composition for barrier film) was applied with a spray coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 150 nm after curing might be formed. Then, after the solvent was removed from the coat layer by drying under vacuum, a solar cell module was kept in a hot air drying oven at 150° C. for 20 minutes to thermally cure the coat layer to obtain the barrier film. Meanwhile, in Table 3, titanium-coupling agent 1 of Additive 1 and ATO (antimony-doped tin oxide) particles of Additive 2 were already included in the base solution, and thus added amounts of these additives were shown by the rates (values in brackets) relative to 100% by mass of the total coating solution (composition for barrier film). The fumed silica disperse solution was prepared in a manner similar to that for the fumed silica disperse solution of Barrier Film No. 8.

### Barrier Film No. 14:

At first, 95% by mass of the SiO₂ binder type base solution of Group 9 and 5% by mass of the fumed silica disperse solution as Additive 3 were mixed and dispersed with an ultrasonic vibration instrument for 10 minutes at room temperature to adapt the mixture thoroughly, whereby a coating solution of the composition for barrier film was obtained. Then, this coating solution (composition for barrier film) was applied with a die coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 350 nm after curing might be formed. Then, after the solvent was removed from the coat layer by drying under vacuum, a solar cell module was kept in a hot air drying oven at 180° C. for 20 minutes to thermally cure the coat layer to obtain the barrier film. Meanwhile, in Table 3, titanium-coupling agent 2 of Additive 1 and ITO (indium tin oxide) particles of Additive 2 were already included in the base solution, and thus added amounts of these additives were shown by the rates (values in brackets) relative to 100% by mass of the total coating solution (composition for barrier film). The fumed silica disperse solution was prepared in a manner similar to that for the fumed silica disperse solution of Barrier Film No. 8.

### Barrier Film No. 15:

At first, 90% by mass of the SiO₂ binder type base solution of Group 9 and 10% by mass of mica particles having average diameter of 5 μm and average thickness of about 20 nm (Micromica; manufactured by Co-op Chemical Co., Ltd.) as Additive 3 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the mica particles into the base solution, whereby a coating solution of the composition for barrier film was obtained. During this operation, shape of the blade and rotation speed were carefully controlled so that temperature of the coating solution might not become 70° C. or higher. Thereafter, this coating solution (composition for barrier film) was applied with a spin coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 200 nm after curing might be formed. Then, after drying at room temperature for 20 minutes or longer, a solar cell module was kept in a hot air drying oven at 200° C. for 30 minutes to thermally cure the coat layer to obtain the barrier film. Meanwhile, in Table 3, titanium-coupling agent 2 of Additive 1 and ITO (indium tin oxide) particles of Additive 2 were already included in the base solution, and thus added amounts of these additives were shown by the rates (values in brackets) relative to 100% by mass of the total coating solution (composition for barrier film).

### Barrier Film No. 16:

At first, 30% by mass of the SiO₂ binder type base solution of Group 10 and 70% by mass of the fumed silica disperse solution as Additive 3 were mixed and dispersed with an ultrasonic vibration instrument for 10 minutes at room temperature to adapt the mixture thoroughly, whereby a coating solution of the composition for barrier film was obtained. Then, this coating solution (composition for barrier film) was applied with a spin coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 300 nm after curing might be formed. Then, after drying at room temperature for 20 minutes or longer, a solar cell module was kept in a hot air drying oven at 150° C. for 30 minutes to thermally cure the coat layer to obtain the barrier film. Meanwhile, in Table 3, titanium-coupling agent 3 of Additive 1 and AZO (antimony-doped tin oxide) particles of Additive 2 were already included in the base solution, and thus added amounts of these additives were shown by the rates (values in brackets) relative to 100% by mass of the total coating solution (composition for barrier film). The fumed silica disperse solution was prepared in a manner similar to that for the fumed silica disperse solution of Barrier Film No. 8.

### Barrier Film No. 17:

At first, 50% by mass of the SiO₂ binder type base solution of Group 10 and 50% by mass of the colloidal silica disperse solution were mixed and dispersed with an ultrasonic vibration instrument for 10 minutes at room temperature to adapt the mixture thoroughly, whereby a coating solution of the composition for barrier film was obtained. Then, this coating solution (composition for barrier film) was applied with a spray coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 250 nm after curing might be formed. Then, after drying at room temperature for 20 minutes or longer, a solar cell module was kept in a hot air drying oven at 150° C. for 30 minutes to thermally cure the coat layer to obtain the barrier film. Meanwhile, the colloidal silica disperse solution was prepared as following. Firstly, 10% by mass of colloidal silica particles and 90% by mass of a mixed solvent of methanol-modified alcohol and IPA (isopropyl alcohol) (mass ratio of 4:1) were mixed and then agitated at rotation speed of 800 rpm at room temperature for one hour to prepare a mixture. Then, 60 g of this mixture was taken into a 100-mL glass bottle and dispersed in a paint shaker by using 100 g of zirconia beads having diameter of 0.3 mm (Microhica; manufactured by Showa Shell Sekiyu K. K.) for 6 hours to prepare the colloidal silica disperse solution. Here, in Table 4, titanium-coupling agent 3 of Additive 1 and ATO (antimony-doped tin oxide) particles of Additive 2 were already included in the base solution, and thus added amounts of these additives were shown by the rates (values in brackets) relative to 100% by mass of the total coating solution (composition for barrier film).

### Barrier Film No. 18:

At first, 30% by mass of the SiO₂ binder type base solution of Group 11 and 70% by mass of a fumed silica disperse solution (Aerosil; manufactured by Nippon Aerosil Co., Ltd.) as Additive 1 were mixed and dispersed with an ultrasonic vibration instrument for 10 minutes at room temperature to adapt the mixture thoroughly, whereby a coating solution of the composition for barrier film was obtained. Thereafter, this coating solution (composition for barrier film) was applied with a spin coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 400 nm after curing might be formed. Then, after drying at room temperature for 20 minutes or longer, a solar cell module was kept in a hot air drying oven at 200° C. for 30 minutes to thermally cure the coat layer to obtain the barrier film. The fumed silica disperse solution was prepared in a manner similar to that for the fumed silica disperse solution of Barrier Film No. 8.

### Barrier Film No. 19:

At first, 50% by mass of the SiO₂ binder type base solution of Group 11 and 50% by mass of a disperse solution that contains mica particles having average diameter of 1 μm and average thickness of about 20 nm (Micromica; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm, whereby a coating solution of the composition for barrier film was obtained. Thereafter, this coating solution (composition for barrier film) was applied with a spin coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 600 nm after curing might be formed. Then, after drying at room temperature for 20 minutes or longer, a solar cell module was kept in a hot air drying oven at 200° C. for 30 minutes to thermally cure the coat layer to obtain the barrier film. Meanwhile, the mica disperse solution was prepared as following. Firstly, 10% by mass of the mica particles and 80% by mass of solvent mixture of IPA (isopropyl alcohol) and ethanol (mass ratio of 2:1) were mixed and then agitated at rotation speed of 300 rpm at room temperature for one hour to adapt the material thoroughly, and then the mixture was further agitated with a disperser blade capable of high-speed rotation till about 5000 rpm.

### Barrier Film No. 20:

At first, 85% by mass of IPA (isopropyl alcohol) and 15% by mass of colloidal silica having average particle diameter of about 20 nm were mixed to prepare a colloidal silica disperse solution (IPA-ST; manufactured by Nissan Chemical Industries, Ltd.) of Additive 1. Then, 40% by mass of the acryl type base solution of Group 11 and 60% by mass of the colloidal silica disperse solution were mixed and dispersed with an ultrasonic vibration instrument for 10 minutes at room temperature to adapt the mixture thoroughly, whereby a coating solution of the composition for barrier film was obtained. Thereafter, this coating solution (composition for barrier film) was applied with a spray coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 300 nm after curing might be formed. Then, after drying at room temperature for 20 minutes or longer, a solar cell module was kept in a hot air drying oven at 180° C. for 30 minutes to thermally cure the coat layer to obtain the thoroughly cured barrier film.

### Barrier Film No. 21:

At first, 90% by mass of the SiO₂ binder type base solution of Group 12 and 10% by mass of mica particles having average diameter of 5 μm and average thickness of about 20 nm (Micromica; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the mica particles into the base solution, whereby a coating solution of the composition for barrier film was obtained. Thereafter, this coating solution (composition for barrier film) was applied with a spin coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 400 nm after curing might be formed. Then, after drying at room temperature for 20 minutes or longer, a solar cell module was kept in a hot air drying oven at 200° C. for 30 minutes to thermally cure the coat layer to obtain the barrier film.

### Barrier Film No. 22:

At first, 95% by mass of the SiO₂ binder type base solution of Group 12 and 5% by mass of Al particles having average diameter of 35 μm and average thickness of about 100 nm (Alpaste; manufactured by Toyo Aluminium K. K.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the Al particles into the base solution, whereby a coating solution of the composition for barrier film was obtained. Thereafter, this coating solution (composition for barrier film) was applied with a spray coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 500 nm after curing might be formed. Then, after drying at room temperature for 20 minutes or longer, a solar cell module was kept in a hot air drying oven at 200° C. for 30 minutes to thermally cure the coat layer to obtain the barrier film.

### Barrier Film No. 23:

At first, 96% by mass of the acryl type base solution of Group 1 and 4% by mass of Al particles having average diameter of 27 μm and average thickness of about 100 nm (Alpaste; manufactured by Toyo Aluminium K. K.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the Al particles into the base solution, whereby a coating solution of the composition for barrier film was obtained. Thereafter, this coating solution (composition for barrier film) was applied with a die coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 1100 nm after curing might be formed. Then, after the solvent was removed from the coat layer by drying under vacuum, the coat layer was irradiated with UV beam by using a UV irradiation instrument to cure the coat layer with UV beam; thereafter, a solar cell module was kept in a hot air drying oven at 70° C. for 3 hours to thermally cure the coat layer to obtain the thoroughly cured barrier film.

### Barrier Film No. 24:

At first, 85% by mass of IPA (isopropyl alcohol) and 15% by mass of colloidal silica having average particle diameter of about 20 nm were mixed to prepare a colloidal silica disperse solution (IPA-ST-UP; manufactured by Nissan Chemical Industries, Ltd.) of Additive 1. Then, 93% by mass of the acryl type base solution of Group 1 and 7% by mass of the colloidal silica disperse solution were mixed and dispersed with an ultrasonic vibration instrument for 10 minutes at room temperature to adapt the mixture thoroughly, whereby a coating solution of the composition for barrier film was obtained. Thereafter, this coating solution (composition for barrier film) was applied with a spin coating instrument on the back electrode reinforcing film of the laminated body that was laminated on the substrate with the front electrode layer, the photoelectric conversion unit, the transparent and conductive film, the back electrode layer, and the back electrode reinforcing film in this order, in such a manner that a coat layer having film thickness of 800 nm after curing might be formed. Then, after the solvent was removed from the coat layer by drying under vacuum, the coat layer was irradiated with UV beam by using a UV irradiation instrument to cure the coat layer with UV beam; thereafter, a solar cell module was kept in a hot air drying oven at 70° C. for 3 hours to thermally cure the coat layer to obtain the thoroughly cured barrier film.

TABLE 3

| | Composition for barrier film | | | | | | | | | | |
|---|---|---|---|---|---|---|---|---|---|---|---|
| | | Base solution | | Additive 1 | | Additive 2 | | Additive 3 | | | |
| | | | Content | | Content | | Content | | Content | Film | |
| Barrier | Curing | | (% by | | (% by | | (% by | | (% by | thickness | Coating |
| Film | method | Group | mass) | Kind | mass) | Kind | mass) | Kind | mass) | (nm) | method |
| No. 1 | UV | 1 | 90 | Colloidal silica | 10 | — | — | — | — | 800 | Spray |
| | | | | disperse solution | | | | | | | |
| No. 2 | UV | 1 | 85 | Mica particles | 15 | — | — | — | — | 600 | Spray |
| No. 3 | UV | 2 | 95 | Al particles | 5 | — | — | — | — | 400 | Spin |
| No. 4 | UV | 2 | 90 | Silica particles | 10 | — | — | — | — | 750 | Spin |
| No. 5 | UV | 3 | 95 | Smectite particles | 5 | — | — | — | — | 1000 | Spin |
| No. 6 | Heat | 4 | 93 | Al particles | 7 | — | — | — | — | 1200 | Spray |
| No. 7 | Heat | 4 | 80 | Mica particles | 20 | — | — | — | — | 900 | Spin |
| No. 8 | Heat | 5 | 97 | Fumed silica | 3 | — | — | — | — | 150 | Die |
| | | | | disperse solution | | | | | | | |
| No. 9 | Heat | 6 | 95 | Smectite particles | 5 | — | — | — | — | 400 | Slit |
| No. 10 | Heat | 6 | 87 | Colloidal silica | 13 | — | — | — | — | 900 | Screen |
| | | | | disperse solution | | | | | | | |
| No. 11 | Heat | 7 | 90 | Silica particles | 10 | — | — | — | — | 700 | Spin |
| No. 12 | Heat | 8 | 75 | Titanium-coupling | (7) | ATO | (5) | Colloidal | 25 | 200 | Spin |
| | | | | agent 1 | | particles | | silica | | | |
| | | | | | | | | disperse | | | |
| | | | | | | | | solution | | | |
| No. 13 | Heat | 8 | 98 | Titanium-coupling | (9) | ATO | (6) | Fumed | 2 | 150 | Spray |
| | | | | agent 1 | | particles | | silica | | | |
| | | | | | | | | disperse | | | |
| | | | | | | | | solution | | | |
| No. 14 | Heat | 9 | 95 | Titanium-coupling | (2) | ITO | (8) | Fumed | 5 | 350 | Die |
| | | | | agent 2 | | particles | | silica | | | |
| | | | | | | | | disperse | | | |
| | | | | | | | | solution | | | |
| No. 15 | Heat | 9 | 90 | Titanium-coupling | (2) | ITO | (7) | Mica | 10 | 200 | Spin |
| | | | | agent 2 | | particles | | particles | | | |
| No. 16 | Heat | 10 | 30 | Titanium-coupling | (0.1) | AZO | (0.6) | Fumed | 70 | 300 | Spin |
| | | | | agent 3 | | particles | | silica | | | |
| | | | | | | | | disperse | | | |
| | | | | | | | | solution | | | |

TABLE 4

| | Composition for barrier film | | | | | | | | | | |
|---|---|---|---|---|---|---|---|---|---|---|---|
| | | Base solution | | Additive 1 | | Additive 2 | | Additive 3 | | | |
| | | | Content | | Content | | Content | | Content | Film | |
| Barrier | Curing | | (% by | | (% by | | (% by | | (% by | thickness | Coating |
| Film | method | Group | mass) | Kind | mass) | Kind | mass) | Kind | mass) | (nm) | method |
| No. 17 | Heat | 10 | 50 | Titanium-coupling | (0.2) | AZO | (1) | Colloidal | 50 | 250 | Spray |
| | | | | agent 3 | | particles | | silica | | | |
| | | | | | | | | disperse | | | |
| | | | | | | | | solution | | | |
| No. 18 | Heat | 11 | 30 | Fumed silica | 70 | — | — | — | — | 400 | Spin |
| | | | | disperse solution | | | | | | | |
| No. 19 | Heat | 11 | 50 | Mica disperse | 50 | — | — | — | — | 600 | Spin |
| | | | | solution | | | | | | | |
| No. 20 | Heat | 11 | 40 | Colloidal silica | 60 | — | — | — | — | 300 | Spray |
| | | | | disperse solution | | | | | | | |
| No. 21 | Heat | 12 | 90 | Mica particles | 10 | — | — | — | — | 400 | Spin |
| No. 22 | Heat | 12 | 95 | Al particles | 5 | — | — | — | — | 500 | Spray |
| No. 23 | UV + Heat | 1 | 96 | Al particles | 4 | — | — | — | — | 1100 | Die |
| No. 24 | UV + Heat | 1 | 93 | Colloidal silica | 7 | — | — | — | — | 800 | Spin |
| | | | | disperse solution | | | | | | | |

### Example 1

At first, 65% by mass of IPA (isopropyl alcohol) and 15% by mass of colloidal silica having average particle diameter of about 20 nm were mixed to prepare a colloidal silica disperse solution of Additive 1. Then, the acryl type base solution of Group 1 and the foregoing colloidal silica disperse solution were mixed and agitated with a disperser having an agitation blade at rotation speed of about 500 rpm for 5 minutes, whereby a coating solution of a composition for reinforcing film was obtained. Then, this coating solution (composition for reinforcing film) was applied with a spray coating instrument on the back electrode layer (silver electrode layer) of the solar cell module that had already been processed in lamination, in such a manner that a coat layer for the reinforcing film having film thickness of 500 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film.

Meanwhile, “the solar cell module that has already been processed in lamination” means the following state. At first, as shown in FIG. 1, a glass plate formed with a SiO₂ layer having thickness of 50 nm (not shown in the figure) on its one main surface is prepared as the substrate 11. Then, on surface of the SiO₂ layer was formed with a sputtering method the front electrode layer 12 (SnO₂ film) with thickness of 800 nm having surface of a concave-convex texture and doped with F (fluorine). The front electrode layer 12 is patterned with a laser processing method. Namely, separation process in strips was conducted by forming the separation groove 22. Here, the separation process (formation of the separation groove 22) by using a laser processing method was conducted by using a Nd:YAG laser with wavelength of about 1.06 μm, energy density of 13 J/cm³, and pulse frequency of 3 kHz. Then, on the front electrode layer 12 was formed the photoelectric conversion unit 13 with a plasma CVD method. In this Example, the photoelectric conversion unit 13 was made to have a tandem type structure comprised of two layers; an amorphous silicon layer laminated, in order, from the substrate 11 side, with a p-type a-Si (amorphous silicon), an i-type a-Si, and an n-type a-Si, and a microcrystalline silicon layer further laminated, on this amorphous silicon layer, with a p-type μc-Si (microcrystalline silicon), an i-type μc-Si, and an n-type μc-Si. Specifically, the amorphous silicon layer was formed with a plasma CVD method by laminating: a p-type a-Si having film thickness of 10 nm formed with a gas mixture of SiH₄, CH₄, H₂, and B₂H₆, an i-type a-Si having film thickness of 300 nm formed with a gas mixture of SiH₄ and H₂, and an n-type a-Si having film thickness of 20 nm formed with a gas mixture of SiH₄, H₂, and PH₃, in this order. The microcrystalline silicon layer was formed with a plasma CVD method by laminating: a p-type having film thickness of 10 nm formed with a gas mixture of SiH₄, H₂, and B₂H₆, an i-type μc-Si having film thickness of 2000 nm formed with a gas mixture of SiH₄ and H₂, and an n-type having film thickness of 20 nm formed with a gas mixture of SiH₄, H₂, and PH₃, in this order. Detailed conditions of the foregoing plasma CVD method are shown in the following Table 5. The foregoing photoelectric conversion unit 13 was patterned into strips with a laser processing method. Namely, separation process was conducted to form the separation groove 23. The separation groove 23 was formed at 50 μm laterally apart from the patterned position of the front electrode layer 12. Then, on the photoelectric conversion unit 13 were formed the transparent and conductive film 14 (ZnO layer) having thickness of 80 nm and the back electrode layer 16 (silver electrode layer) having thickness of 200 nm by using a magnetron in-line sputtering instrument. Here, the separation process (formation of the separation groove 23) by using a laser processing method was conducted by using a Nd:YAG laser with energy density of 0.7 J/cm³ and pulse frequency of 3 kHz.

TABLE 5

| | Amorphous silicon | | | Microcrystalline | | |
|---|---|---|---|---|---|---|
| | layer | | | layer | | |
| | p-Type | i-Type | n-Type | p-Type | i-Type | n-Type |
| Temperature | 180 | 200 | 180 | 180 | 200 | 200 |
| of substrate | | | | | | |
| (° C.) | | | | | | |
| Gas flow | SiH₄: | SiH₄: | SiH₄: | SiH₄: | SiH₄: | SiH₄: |
| amount | 300 | 300 | 300 | 10 | 100 | 10 |
| (sccm) | CH₄: | H₂: | H₂: | H₂: | H₂: | H₂: |
| | 300 | 2000 | 2000 | 2000 | 2000 | 2000 |
| | H₂: | | PH₃: 5 | B₂H₆: 3 | | PH₃: 5 |
| | 2000 | | | | | |
| | B₂H₆: 3 | | | | | |
| Reaction | 106 | 106 | 133 | 106 | 133 | 133 |
| Pressure | | | | | | |
| (Pa) | | | | | | |
| RF power (W) | 10 | 20 | 20 | 10 | 20 | 20 |
| Film | 10 | 300 | 20 | 10 | 2000 | 20 |
| thickness | | | | | | |
| (nm) | | | | | | |

Then, after the back electrode layer 16 was formed on the transparent and conductive film 14 and before the back electrode reinforcing film 17 was formed on the back electrode layer 16, the back electrode layer 16, the transparent and conductive film 14, and the photoelectric conversion unit 13 were patterned in strips from the backside with a laser processing method. Namely, separation process was conducted to form the separation groove 18. The separation groove 18 was formed at 50 μm laterally apart (separation groove 23) from the pattered position of the photoelectric conversion unit 13. Here, the separation process (formation of the separation groove 18) by using a laser processing method was conducted by using a Nd:YAG laser with energy density of 0.7 J/cm³ and pulse frequency of 4 kHz. After separation processing of the back electrode layer 16 and so on, dry etching with CF₄ was carried out for several tens of seconds. Alternatively, wet etching or the like might be carried out. On the back electrode reinforcing film 17 were laminated the filler layer 19 comprised of ethylene-vinyl acetate copolymer (EVA) and the back film 21 comprised of polyethylene terephthalate (PET) in this order; and then heat treatment was conducted at 150° C. for 30 minutes by using a lamination instrument to cross link the filler layer 19 for stabilization and vacuum adhesion. Then, after a terminal box was attached and taken out, an electrode was connected to obtain a solar cell module 10.

### Example 2

At first, 85% by mass of the acryl type base solution of Group 1 and 15% by mass of mica particles having average diameter of 5 μm and average thickness of about 20 nm (Micromica; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the mica particles into the base solution, whereby a coating solution of the composition for reinforcing film was obtained. Thereafter, this coating solution (composition for reinforcing film) was applied with a spray coating instrument on the back electrode layer (silver electrode layer) of the solar cell module that had already been processed in lamination in such a manner that a coat layer for the reinforcing film having film thickness of 200 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film. A solar cell module was fabricated in a manner similar to those in Example 1 except for the procedures described above.

### Example 3

At first, 95% by mass of the acryl type base solution of Group 2 and 5% by mass of planular Al particles having average diameter of 35 μm and average thickness of about 100 nm (Alpaste; manufactured by Toyo Aluminium K. K.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the Al particles into the base solution, whereby a coating solution of the composition for reinforcing film was obtained. Thereafter, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 400 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film. A solar cell module was fabricated in a manner similar to those in Example 1 except for the procedures described above.

### Example 4

At first, 90% by mass of the acryl type base solution of Group 2 and 10% by mass of silica particles having average particle diameter of about 20 nm (Silica; manufactured by Fuso Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the silica particles into the base solution, whereby a coating solution of the composition for reinforcing film was obtained. Thereafter, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 300 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film. A solar cell module was fabricated in a manner similar to those in Example 1 except for the procedures described above.

### Example 5

At first, 95% by mass of the acryl type base solution of Group 3 and 5% by mass of planular smectite particles having average diameter of 140 nm and average thickness of about 50 nm (Synthetic Smectite; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the smectite particles into the base solution, whereby a coating solution of the composition for reinforcing film was obtained. Thereafter, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 150 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film. A solar cell module was fabricated in a manner similar to those in Example 1 except for the procedures described above.

### Example 6

At first, 93% by mass of the epoxy type base solution of Group 4 and planular Al particles having average diameter of 27 μm and average thickness of about 100 nm (Alpaste; manufactured by Toyo Aluminium K. K.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the Al particles into the base solution, whereby a coating solution of the composition for reinforcing film was obtained. Thereafter, this coating solution (composition for reinforcing film) was applied with a spray coating instrument on the back electrode layer (silver electrode layer) of the solar cell module that had already been processed in lamination, in such a manner that a coat layer for the reinforcing film having film thickness of 400 nm after curing might be formed. Then, after drying at room temperature for 20 minutes or longer, a solar cell module was kept in a hot air drying oven at 150° C. for 20 minutes to thermally cure the coat layer for the reinforcing film to obtain the back electrode reinforcing film. A solar cell module was fabricated in a manner similar to those in Example 1 except for the procedures described above.

### Example 7

At first, 80% by mass of the epoxy type base solution of Group 4 and 20% by mass of mica particles having average diameter of 1 μm and average thickness of about 20 nm (Micromica; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the mica particles into the base solution, whereby a coating solution of the composition for reinforcing film was obtained. During this operation, shape of the blade and rotation speed were carefully controlled so that temperature of the coating solution might not become 70° C. or higher. Thereafter, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 200 nm after curing might be formed. Then, after drying at room temperature for 20 minutes or longer, a solar cell module was kept in a hot air drying oven at 200° C. for 20 minutes to thermally cure the coat layer for the reinforcing film to obtain the back electrode reinforcing film. A solar cell module was fabricated in a manner similar to those in Example 1 except for the procedures described above.

### Example 8

At first, 97% by mass of the epoxy type base solution of Group 5 and 3% by mass of a fumed silica disperse solution (Aerosil; manufactured by Nippon Aerosil Co., Ltd.) as Additive 1 were mixed and dispersed with an ultrasonic vibration instrument for 10 minutes at room temperature to adapt the mixture thoroughly, whereby a coating solution of the composition for reinforcing film was obtained. Thereafter, this coating solution (composition for reinforcing film) was applied with a die coating instrument on the back electrode layer (silver electrode layer) of the solar cell module that had already been processed in lamination, in such a manner that a coat layer for the reinforcing film having film thickness of 150 nm after curing might be formed. Then, after drying at room temperature for 20 minutes or longer, a solar cell module was kept in a hot air drying oven at 180° C. for 30 minutes to thermally cure the coat layer for the reinforcing film to obtain the back electrode reinforcing film. Meanwhile, the fumed silica disperse solution was prepared as following. Firstly, 10% by mass of fumed silica particles and 90% by mass of a mixed solvent of IPA (isopropyl alcohol) and ethanol (mass ratio of 2:1) were mixed and then agitated at rotation speed of 800 rpm at room temperature for one hour to prepare a mixture. Then, 60 g of this mixture was taken into a 100-mL glass bottle and dispersed in a paint shaker by using 100 g of zirconia beads having diameter of 0.3 mm (Microhica; manufactured by Showa Shell Sekiyu K. K.) for 6 hours to prepare the disperse solution of fumed silica of the conductive oxide microparticles. A solar cell module was fabricated in a manner similar to those in Example 1 except for the procedures described above.

### Example 9

At first, 95% by mass of the epoxy type base solution of Group 6 and 5% by mass df planular smectite particles having average diameter of 180 nm and average thickness of about 30 nm (Synthetic Smectite; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse Ti particles into the base solution, whereby a coating solution of the composition for reinforcing film was obtained. During this operation, shape of the blade and rotation speed were carefully controlled so that temperature of the coating solution might not become higher than 70° C. Thereafter, this coating solution (composition for reinforcing film) was applied with a slit coating instrument on the back electrode layer (silver electrode layer) of the solar cell module that had already been processed in lamination, in such a manner that a coat layer for the reinforcing film having film thickness of 400 nm after curing might be formed. Then, after drying at room temperature for 20 minutes or longer, a solar cell module was kept in a hot air drying oven at 200° C. for 20 minutes to thermally cure the coat layer for the reinforcing film to obtain the back electrode reinforcing film. A solar cell module was fabricated in a manner similar to those in Example 1 except for the procedures described above.

### Example 10

At first, 87% by mass of the epoxy type base solution of Group 6 and 13% by mass of the colloidal silica disperse solution as Additive 1 were mixed with a planetary agitating instrument at room temperature for 10 minutes to adapt the mixture thoroughly, whereby a coating solution of a composition for reinforcing film was obtained. Then, this coating solution (composition for reinforcing film) was applied with a screen printing instrument on the back electrode layer (silver electrode layer) of the solar cell module that had already been processed in lamination, in such a manner that a coat layer for the reinforcing film having film thickness of 900 nm after curing might be formed. Then, after drying at room temperature for 20 minutes or longer, a solar cell module was kept in a hot air drying oven at 200° C. for 20 minutes to thermally cure the coat layer for the reinforcing film to obtain the back electrode reinforcing film. Here, the colloidal silica disperse solution was prepared in a manner similar to that for the fumed silica disperse solution of Example 8. A solar cell module was fabricated in a manner similar to those in Example 1 except for the procedures described above.

### Example 11

At first, 90% by mass of the cellulose type base solution of Group 7 and 10% by mass of silica particles having average particle diameter of about 30 nm (Silica; manufactured by Fuso Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the silica particles into the base solution, whereby a coating solution of the composition for reinforcing film was obtained. Thereafter, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 400 run after curing might be formed. Then, after drying at room temperature for 20 minutes or longer, a solar cell module was kept in a hot air drying oven at 180° C. for 20 minutes to thermally cure the coat layer for the reinforcing film to obtain the back electrode reinforcing film. A solar cell module was fabricated in a manner similar to those in Example 1 except for the procedures described above.

### Example 12

At first, 85% by mass of IPA (isopropyl alcohol) and 15% by mass of colloidal silica having average particle diameter of about 20 nm were mixed to prepare a colloidal silica disperse solution (Snowtex 20; manufactured by Nissan Chemical Industries, Ltd.) of Additive 3. Then, 75% by mass of the SiO₂ binder type base solution of Group 8 and 25% by mass of the colloidal silica disperse solution were mixed and dispersed with an ultrasonic vibration instrument for 10 minutes at room temperature to adapt the mixture thoroughly, whereby a coating solution of the composition for reinforcing film was obtained. Then, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 200 nm after curing might be formed. Then, after the solvent was removed from the coat layer for the reinforcing film by drying under vacuum, a solar cell module was kept in a hot air drying oven at 200° C. for 30 minutes to thermally cure the coat layer for the reinforcing film to obtain the back electrode reinforcing film. Meanwhile, in Table 6, titanium-coupling agent 1 of Additive 1 and ATO (composite oxides of antimony oxide-tin oxide) particles of Additive 2 were already included in the base solution, and thus added amounts of these additives were shown by the rates (values in brackets) relative to 100% by mass of the total coating solution (composition for reinforcing film). A solar cell module was fabricated in a manner similar to those in Example 1 except for the procedures described above.

### Example 13

At first, 98% by mass of the SiO₂ binder type base solution of Group 8 and 2% by mass of the fumed silica disperse solution as Additive 3 were mixed and dispersed with an ultrasonic vibration instrument for 10 minutes at room temperature to adapt the mixture thoroughly, whereby a coating solution of the composition for reinforcing film was obtained. Then, this coating solution (composition for reinforcing film) was applied with a spray coating instrument on the back electrode layer (silver electrode layer) of the solar cell module that had already been processed in lamination, in such a manner that a coat layer for the reinforcing film having film thickness of 150 nm after curing might be formed. Then, after the solvent was removed from the coat layer for the reinforcing film by drying under vacuum, a solar cell module was kept in a hot air drying oven at 150° C. for 20 minutes to thermally cure the coat layer for the reinforcing film to obtain the back electrode reinforcing film. Meanwhile, in Table 6, titanium-coupling agent 1 of Additive 1 and ATO (composite oxides of antimony oxide-tin oxide) particles of Additive 2 were already included in the base solution, and thus added amounts of these additives were shown by the rates (values in brackets) relative to 100% by mass of the total coating solution (composition for reinforcing film). The fumed silica disperse solution was prepared in a manner similar to that for the fumed silica disperse solution of Example 8. A solar cell module was fabricated in a manner similar to those in Example 1 except for the procedures described above.

### Example 14

At first, 95% by mass of the SiO₂ binder type base solution of Group 9 and 5% by mass of the ,fumed silica disperse solution as Additive 3 were mixed and dispersed with an ultrasonic vibration instrument for 10 minutes at room temperature to adapt the mixture thoroughly, whereby a coating solution of the composition for reinforcing film was obtained. Then, this coating solution (composition for reinforcing film) was applied with a die coating instrument on the back electrode layer (silver electrode layer) of the solar cell module that had already been processed in lamination, in such a manner that a coat layer for the reinforcing film having film thickness of 350 nm after curing might be formed. Then, after the solvent was removed from the coat layer for the reinforcing film by drying under vacuum, a solar cell module was kept in a hot air drying oven at 180° C. for 20 minutes to thermally cure the coat layer for the reinforcing film to obtain the back electrode reinforcing film. Meanwhile, in Table 6, titanium-coupling agent 2 of Additive 1 and ITO (composite oxides of indium oxide-tin oxide) particles of Additive 2 were already included in the base solution, and thus added amounts of these additives were shown by the rates (values in brackets) relative to 100% by mass of the total coating solution (composition for reinforcing film). The fumed silica disperse solution was prepared in a manner similar to that for the fumed silica disperse solution of Example 8. A solar cell module was fabricated in a manner similar to those in Example 1 except for the procedures described above.

### Example 15

At first, 90% by mass of the SiO₂ binder type base solution of Group 9 and 10% by mass of mica particles having average diameter of 5 μm and average thickness of about 20 run (Micromica; manufactured by Co-op Chemical Co., Ltd.) as Additive 3 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the mica particles into the base solution, whereby a coating solution of the composition for reinforcing film was obtained. During this operation, shape of the blade and rotation speed were carefully controlled so that temperature of the coating solution might not become 70° C. or higher. Thereafter, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 200 μm after curing might be formed. Then, after drying at room temperature for 20 minutes or longer, a solar cell module was kept in a hot air drying oven at 200° C. for 30 minutes to thermally cure the coat layer for the reinforcing film to obtain the back electrode reinforcing film. Meanwhile, in Table 6, titanium-coupling agent 2 of Additive 1 and ITO (composite oxides of indium oxide-tin oxide) particles of Additive 2 were already included in the base solution, and thus added amounts of these additives were shown by the rates (values in brackets) relative to 100% by mass of the total coating solution (composition for reinforcing film). A solar cell module was fabricated in a manner similar to those in Example 1 except for the procedures described above.

### Example 16

At first, 96% by mass of the acryl type base solution of Group 1 and 4% by mass of Al particles having average diameter of 35 μm and average thickness of about 100 nm (Alpaste; manufactured by Toyo Aluminium K. K.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the Al particles into the base solution, whereby a coating solution of the composition for reinforcing film was obtained. Thereafter, this coating solution (composition for reinforcing film) was applied with a die coating instrument on the back electrode layer (silver electrode layer) of the solar cell module that had already been processed in lamination, in such a manner that a coat layer for the reinforcing film having film thickness of 250 nm after curing might be formed. Then, the solvent was removed from the coat layer for the reinforcing film by drying under vacuum; and after the coat layer for the reinforcing film was irradiated with UV-beam with a UV-beam irradiation instrument to cure the coat layer for the reinforcing film with UV-beam, a solar cell module was kept in a hot air drying oven at 70° C. for 3 hours to thermally cure the coat layer for the reinforcing film to obtain the back electrode reinforcing film that was thoroughly cured. In this Example, the electric generator layer of the photoelectric conversion unit was made to be comprised of an amorphous silicon monolayer that was laminated, from the substrate side, with a p-type a-Si (amorphous silicon), an i-type a-Si, and an n-type a-Si, in this order. A solar cell module was fabricated in a manner similar to those in Example 1 except for the procedures described above.

### Example 17

At first, 85% by mass of IPA (isopropyl alcohol) and 15% by mass of colloidal silica having average particle diameter of about 20 nm were mixed to prepare a colloidal silica disperse solution (IPA-ST; manufactured by Nissan Chemical Industries, Ltd.) of Additive 1. Then, 93% by mass of the acryl type base solution of Group 1 and 7% by mass of the colloidal silica disperse solution were mixed and dispersed with an ultrasonic vibration instrument for 10 minutes at room temperature to adapt the mixture thoroughly, whereby a coating solution of the composition for reinforcing film was obtained. Then, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 400 nm after curing might be formed. Then, the solvent was removed from the coat layer for the reinforcing film by drying under vacuum; and after the coat layer for the reinforcing film was irradiated with UV-beam with a UV-beam irradiation instrument to cure the coat layer for the reinforcing film with UV-beam, a solar cell module was kept in a hot air drying oven at 70° C. for 3 hours to thermally cure the coat layer for the reinforcing film to obtain the back electrode reinforcing film that was thoroughly cured. In this Example, the electric generator layer of the photoelectric conversion unit was made to be comprised of a microcrystalline silicon monolayer that was laminated, from the substrate side, with a p-type μc-Si (microcrystalline silicon), an i-type μc-Si, and an n-type μc-Si, in this order. A solar cell module was fabricated in a manner similar to those in Example 1 except for the procedures described above.

### Comparative Example 1

The back electrode reinforcing film was not formed on the back electrode layer (silver electrode layer) of the solar cell module that had already been processed in lamination. Comparative Example 1 relates to this solar cell module.

### Comparative Example 2

The back electrode reinforcing film (Ti layer) having thickness of 15 nm was formed, by vapor-deposition of Ti (titanium) with a sputtering method, on the back electrode layer (silver electrode layer) of the solar cell module that had already been processed in lamination. Comparative Example 2 relates to this solar cell module.

### Comparative Example 3

The back electrode reinforcing film (Al layer) having thickness of 200 nm was formed, by vapor-deposition of Al (aluminum) with a sputtering method, on the back electrode layer (silver electrode layer) of the solar cell module that had already been processed in lamination. Comparative Example 3 relates to this solar cell module.

Comparative tests 1 and Evaluations:

Flash formation, adhesion, and relative output characteristics of the solar cell modules of Examples 1 to 17 and Comparative Examples 1 to 3 were evaluated. As to evaluation of flash formation, degree of flash formation into the inner side of a separation groove (worked surface) and irregularity in width of the separation groove, during the time of working the solar cell module by a laser scriber of a laser processing method, were classified into four groups: Excellent, Good, Fair, and Unacceptable. The separation groove having stable and beautiful worked lines was classified as “Excellent”. The separation groove partly showing a heave and the like but not showing large concavities and convexities or bumps was classified as “Good”. As a whole, the separation groove having unstable line width and constantly showing irregular concavities and convexities in worked lines, but always having a space between the lines thereby not having a short-circuit part was classified as “Fair”. The separation groove having exceedingly large concavities and convexities in worked lines thereby having unbroken space between the lines so that there might possibly occur short-circuit, or having cutting scraps that were larger than the groove width and were attached strongly on the lines was classified as “Unacceptable”.

As to evaluation of adhesion, according to the tape test (JIS K-5600), degree of delamination or peel-off of the back electrode reinforcing film and so on observed, when an adhesive tape was attached to and removed from a worked part of the solar cell module, was classified into four groups: Excellent, Good, Fair, and Unacceptable. The solar cell module whose worked part was not attached to the adhesive tape was classified as “Excellent. The solar cell module whose work scraps were partly attached to the adhesive tape but worked lines themselves did not float up was classified as “Good”. The solar cell module whose work scraps were formed and worked lines were partly peeled off in their shape, but line part itself was not changed in its shape was classified as “Fair”. The solar cell module whose work scraps as well as the reinforcing film itself near the lines were attached to the adhesive tape thereby changing shapes of the lines themselves was classified as “Unacceptable”.

Relative output characteristics were evaluated as following. Firstly, lead wiring was made on the substrate after the solar cell module was worked out to make lines; and the measured value of output characteristics (FF (fill factor) is shown by [maximum output]/([open voltage]×[short-circuit current])) upon confirmation of an I-V (current-voltage) characteristic curve was taken as the initial value. After about one week, the value of output characteristics (fill factor FF), upon confirmation whether or not there was any change of Ag itself of the back electrode layer by corrosion, was measured; and the measured value thereby obtained was expressed by the rate (%) relative to the initial value as 100%. These results, together with kind of binders and thickness of the back electrode reinforcing film, are shown in Table 7. Meanwhile, curing method of the coating solution (composition for reinforcing film), group number and mixing ratio of the base solution, kind and mixing ratio of Additives 1 to 3, coating method of the coating solution (composition for reinforcing film), and thickness of the back electrode reinforcing film, in Examples 1 to 17 and Comparative Examples 1 to 3, are shown in Table 6.

TABLE 6

Coating solution for reinforcing film (composition for reinforcing film)

| | | Base | | | | | | | | | Thickness of |
|---|---|---|---|---|---|---|---|---|---|---|---|
| | Curing | solution | | Additive 1 | | Additive 2 | | Additive 3 | | Coating | reinforcing |
| | method | Group | % | Kind | % | Kind | % | Kind | % | method | film (nm) |
| Examples | UV | 1 | 90 | Colloidal silica | 10 | — | — | — | — | Spray | 500 |
| 1/18 | | | | disperse solution | | | | | | | |
| Examples | UV | 1 | 85 | Mica particles | 15 | — | — | — | — | Spray | 200 |
| 2/19 | | | | | | | | | | | |
| Examples | UV | 2 | 95 | Al particles | 5 | — | — | — | — | Spin | 400 |
| 3/20 | | | | | | | | | | | |
| Examples | UV | 2 | 90 | Silica particles | 10 | — | — | — | — | Spin | 300 |
| 4/21 | | | | | | | | | | | |
| Examples | UV | 3 | 95 | Smectite particles | 5 | — | — | — | — | Spin | 150 |
| 5/22 | | | | | | | | | | | |
| Examples | Heat | 4 | 93 | Al particles | 7 | — | — | — | — | Spray | 400 |
| 6/23 | | | | | | | | | | | |
| Examples | Heat | 4 | 80 | Mica particles | 20 | — | — | — | — | Spin | 200 |
| 7/24 | | | | | | | | | | | |
| Examples | Heat | 5 | 97 | Fumed silica | 3 | — | — | — | — | Die | 150 |
| 8/25 | | | | disperse solution | | | | | | | |
| Examples | Heat | 6 | 95 | Smectite particles | 5 | — | — | — | — | Slit | 400 |
| 9/26 | | | | | | | | | | | |
| Examples | Heat | 6 | 87 | Colloidal silica | 13 | — | — | — | — | Screen | 900 |
| 10/27 | | | | disperse solution | | | | | | | |
| Examples | Heat | 7 | 90 | Silica particles | 10 | — | — | — | — | Spin | 400 |
| 11/28 | | | | | | | | | | | |
| Examples | Heat | 8 | 75 | Titanium-coupling | (7) | ATO | (5) | Colloidal | 25 | Spin | 200 |
| 12/29 | | | | agent 1 | | particles | | silica | | | |
| | | | | | | | | disperse | | | |
| | | | | | | | | solution | | | |
| Examples | Heat | 8 | 98 | Titanium-coupling | (9) | ATO | (6) | Fumed silica | 2 | Spray | 150 |
| 13/30 | | | | agent 1 | | particles | | disperse | | | |
| | | | | | | | | solution | | | |
| Examples | Heat | 9 | 95 | Titanium-coupling | (2) | ITO | (8) | Fumed silica | 5 | Die | 350 |
| 14/31 | | | | agent 2 | | particles | | disperse | | | |
| | | | | | | | | solution | | | |
| Examples | Heat | 9 | 90 | Titanium-coupling | (2) | ITO | (7) | Mica | 10 | Spin | 200 |
| 15/32 | | | | agent 2 | | particles | | particles | | | |
| Examples | UV + Heat | 1 | 96 | Al particles | 4 | — | — | — | — | Die | 250 |
| 16/33 | | | | | | | | | | | |
| Examples | UV + Heat | 1 | 93 | Colloidal silica | 7 | — | — | — | — | Spin | 400 |
| 17/34 | | | | disperse solution | | | | | | | |

TABLE 7

| | Back electrode reinforcing film | | | | Relative output |
|---|---|---|---|---|---|
| | Binder | Thickness (nm) | Flash formation | Adhesion | characteristics (%) |
| Example 1 | Acryl type | 500 | Excellent | Excellent | 97 or more |
| Example 2 | Acryl type | 200 | Excellent | Good | 97 |
| Example 3 | Acryl type | 400 | Good | Excellent | 97 |
| Example 4 | Acryl type | 300 | Excellent | Excellent | 95 |
| Example 5 | Acryl type | 150 | Good | Good | 95 |
| Example 6 | Epoxy type | 400 | Good | Good | 97 |
| Example 7 | Epoxy type | 200 | Excellent | Excellent | 96 |
| Example 8 | Epoxy type | 150 | Excellent | Excellent | 96 |
| Example 9 | Epoxy type | 400 | Excellent | Excellent | 95 |
| Example 10 | Epoxy type | 900 | Excellent | Good | 97 |
| Example 11 | Cellulose type | 400 | Good | Good | 95 |
| Example 12 | SiO₂ binder type | 200 | Excellent | Excellent | 97 |
| Example 13 | SiO₂ binder type | 150 | Excellent | Excellent | 97 |
| Example 14 | SiO₂ binder type | 350 | Excellent | Fair | 95 |
| Example 15 | SiO₂ binder type | 200 | Excellent | Excellent | 96 |
| Example 16 | Acryl type | 250 | Good | Excellent | 97 |
| Example 17 | Acryl type | 400 | Excellent | Excellent | 96 |

| | | | | |
|---|---|---|---|---|
| Comparative Example 1 | Without reinforcing film | Unacceptable | Unacceptable | 60 |
| Comparative Example 2 | Ti layer with 15 nm thickness | Fair | Fair | 95 |
| Comparative Example 3 | Al layer with 200 nm thickness | Fair | Unacceptable | 95 |

As can be seen in the column “Flash formation” of Table 7, in Comparative Example 1 in which the reinforcing film was not formed, the separation groove had exceedingly large concavities and convexities in worked lines with unbroken space therebetween; and in addition, cutting scraps that were larger than the line width had remained on the lines by attaching thereon strongly. In Comparative Examples 2 and 3, in which the reinforcing film of Ti or Al was used, no short-circuit sites were seen because there was always a space between the lines; but in the entire separation groove, the line width was not stable and irregular concavities and convexities were seen in the worked lines. On the other hand, in Examples 1 to 17, in which the reinforcing film was formed by curing the binder having dispersed silica particles, mica particles, or the like, worked lines of the separation groove were stable and beautiful; and in addition, there were no large concavities and convexities or bumps, though there was a heave in part of the separation groove. As can be seen in the column of “Adhesion” of Table 7, in Comparative Example 1 not having the reinforcing film and in Comparative Example 3 having the reinforcing film of aluminum, work scraps of the solar cell module as well as the reinforcing film itself near the lines were attached to the adhesive tape, indicating that shapes of the lines themselves were changed. On the other hand, in Examples 1 to 17, in which the reinforcing film was formed by curing the binder having dispersed silica particles, mica particles, or the like, worked lines themselves did not float up; and thus, there was no significant change in shape of the lines themselves. As can be seen in the column of “Relative output characteristics” of Table 7, in Comparative Examples 2 and 3, in which the reinforcing film of Ti or Al was used, the relative output characteristics were high in both Comparative Examples 2 and 3 (95%), while in Comparative Example 1 not having the reinforcing film, the relative output characteristics was decreased to as low as 60%; on the other hand, in Examples 1 to 17, in which the reinforcing film was formed by curing the binder having dispersed silica particles, mica particles, or the like, the relative output characteristics were high (95% or higher).

As described above, it can be seen the following. When the separation groove is formed with a laser scriber in the solar cell module, the back electrode reinforcing film plays a key role in processing. The back electrode layer (silver electrode layer) is a soft material, and is used as a reflection film as well; and thus, the shape thereof is easily changeable so that the processing of it is difficult. Accordingly, formation of flashes and poor adhesion such as peel-off during formation of the separation groove take place mostly in the back electrode layer. As a result, it was found that, when the back electrode layer was covered with a hard and brittle back electrode reinforcing film, breaking properties were improved to realize excellent workability so that poor adhesion and formation of flashes during formation of the separation groove could be avoided in the back electrode layer. In addition, the back electrode layer (silver electrode layer) was easily deteriorated and discolored upon contacting with an oxidative or a sulfidizing atmosphere. As a result, there had been such problems as decreased conductivity and poor output due to lack of necessary reflectance. However, it was found that, when the back electrode layer was covered with the back electrode reinforcing film, deterioration of the back electrode layer could be avoided; and as a result, relative output characteristics were hardly decreased even if the solar cell module of the Examples having the back electrode layer covered with the back electrode reinforcing film was allowed to stand in an air for about one week.

### Example 18

At first, 85% by mass of IPA (isopropyl alcohol) and 15% by mass of colloidal silica having average particle diameter of about 20 nm were mixed to prepare a colloidal silica disperse solution of Additive 1. Then, the acryl type base solution of Group 1 and the foregoing colloidal silica disperse solution were mixed and agitated with a disperser having an agitation blade at rotation speed of about 500 rpm for 5 minutes, whereby a coating solution of a composition for reinforcing film was obtained. Then, this coating solution (composition for reinforcing film) was applied with a spray coating instrument on the back electrode layer (silver electrode layer) of the solar cell module that had already been processed in lamination, in such a manner that a coat layer for the reinforcing film having film thickness of 500 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film.

Meanwhile, “the solar cell module that has already been processed in lamination” means the following state. At first, as shown in FIG. 1, a glass plate formed with a SiO₂ layer having thickness of 50 nm (not shown in the figure) on its one main surface is prepared as the substrate 11. Then, on surface of the SiO₂ layer was formed with a sputtering method the front electrode layer 12 (SnO₂ film) with thickness of 800 nm having surface of a concave-convex texture and doped with F (fluorine). The front electrode layer 12 is patterned with a laser processing method. Namely, separation process in strips was conducted by forming the separation groove 22. Here, the separation process (formation of the separation groove 22) by using a laser processing method was conducted by using a Nd:YAG laser with wavelength of about 1.06 μm, energy density of 13 J/cm³, and pulse frequency of 3 kHz. Then, on the front electrode layer 12 was formed the photoelectric conversion unit 13 with a plasma CVD method. In this Example, the photoelectric conversion unit 13 was made to have a tandem type structure comprised of two layers; an amorphous silicon layer laminated, in order, from the side of the substrate 11, with a p-type a-Si (amorphous silicon), an i-type a-Si, and an n-type a-Si, and a microcrystalline silicon layer further laminated, on this amorphous silicon layer, with a p-type μc-Si (microcrystalline silicon), an i-type μc-Si, and an n-type. Specifically, the amorphous silicon layer was formed with a plasma CVD method by laminating: a p-type a-Si having film thickness of 10 nm formed with a gas mixture of SiH₄, CH₄, H₂, and B₂H₆; an i-type a-Si having film thickness of 300 nm formed with a gas mixture of SiH₄ and H₂; and an n-type a-Si having film thickness of 20 nm formed with a gas mixture of SiH₄, H₂, and PH₃, in this order. The microcrystalline silicon layer was formed with a plasma CVD method by laminating: a p-type μc-Si having film thickness of 10 nm formed with a gas mixture of SiH₄, H₂, and B₂H₆; an i-type having film thickness of 2000 nm formed with a gas mixture of SiH₄ and H₂; and an n-type μc-Si having film thickness of 20 nm formed with a gas mixture of SiH₄, H₂, and PH₃, in this order. Detailed conditions of the foregoing plasma CVD method are shown in the above Table 5. The foregoing photoelectric conversion unit 13 was patterned into strips with a laser processing method. Namely, separation process was conducted to form the separation groove 23. The separation groove 23 was formed at 50 μm laterally apart from the patterned position of the front electrode layer 12. Then, on the photoelectric conversion unit 13 were formed the transparent and conductive film 14 (ZnO layer) having thickness of 80 nm by using a magnetron in-line sputtering instrument. Here, the separation process (formation of the separation groove 23) by using a laser processing method was conducted by using a Nd: YAG laser with energy density of 0.7 J/cm³ and pulse frequency of 3 kHz.

On this transparent and conductive film 14 was formed the back electrode layer 16 by the method as following. Firstly, silver nitrate was dissolved into deionized water to prepare an aqueous metal salt solution. Separately, sodium citrate was dissolved into deionized water to prepare an aqueous sodium citrate solution with concentration of 26% by weight. Into this aqueous sodium citrate was directly added granular ferrous sulfate for dissolution under nitrogen stream at 35° C. to obtain an aqueous reductive solution with mole ratio of citrate ion to ferrous ion being 3:2. Then, a rotation chip of magnetic stirrer was put in the aqueous reductive solution with keeping the nitrogen gas stream at 35° C.; and then, the aqueous metal salt solution was added gradually into the aqueous reductive solution while the rotation chip was rotated for mixing at the rotation speed of 100 rpm to stir the aqueous reductive solution. Here, adding amount of the aqueous metal salt solution into the aqueous reductive solution was made 1/10 or less relative to amount of the aqueous reductive solution; and the concentration of each solution was controlled so that the reaction temperature might be kept at 40° C. even if the aqueous metal salt solution having temperature of room temperature was gradually added. In addition, mixing ratio of the aqueous reductive solution to the aqueous metal salt solution was controlled so that equivalent of the ferrous ion added as a reducing agent might be three times of equivalent of the metal ion. After completion of the gradual addition of the aqueous meal salt solution into the aqueous reductive solution, stirring of the mixture solution was continued for further 15 minutes, whereby metal particles were formed in the mixture solution to obtain a metal particle disperse solution in which the metal particles were dispersed. The metal particle disperse solution had pH of 5.5, and the stoichiometric amount of the metal particles to be produced in the disperse solution was 5 g/L. The obtained disperse solution was allowed to stand at room temperature to settle the metal particles in the disperse solution; and agglomerates of the settled metal particles were separated by decantation. To the separated metal agglomerates was added deionized water to form a disperse body, which was then desalted by ultrafiltration and rinsed with methanol for displacement of the medium so that content of the metal (silver) might become 50% by weight. Thereafter, by using a centrifugal separator with controlling centrifugal force of the centrifugal separator, relatively large silver particles having particle diameter of more than 100 nm were separated, whereby control was made so that the content of the silver nanoparticles having primary particle diameter in the range between 10 and 50 nm might become 71% by number-average. Namely, control was made so that ratio of the silver nanoparticles having primary diameter in the range between 10 and 50 nm might become 71% by number-average relative to 100% by number-average of total silver nanoparticles. The obtained silver nanoparticles were chemically modified with a protecting agent whose organic molecular main chain has carbon skeleton of 3 carbon atoms.

Then, 10 parts by weight of the obtained metal nanoparticles was mixed with 90 parts by weight of a solvent mixture containing water, ethanol, and methanol to obtain a disperse solution, into which were added the additives shown in Table 8 with the ratio shown in Table 8 thereby obtaining respective coating solutions for back electrode (composition for back electrode). Here, metal nanoparticles that constitute the coating solution for back electrode (composition for back electrode) contain 75% or more by weight of the silver nanoparticles. Meanwhile, when metal nanoparticles other than silver nanoparticles, in addition to the silver nanoparticles, were contained as the metal nanoparticles, the silver nanoparticle disperse solution which was obtained by the above-mentioned method was used as a first disperse solution, while a metal salt that forms metal nanoparticles (shown in the following Table 8) other than silver nanoparticles was used in place of silver nitrate. Except for this, a disperse solution of metal nanoparticles other than silver nanoparticles was prepared in a manner similar to those of formation of the silver nanoparticles; and this metal nanoparticle disperse solution was used as a second disperse solution. Then, before an additive was added, the first disperse solution and the second disperse solution were mixed with the ratio shown in the following Table 8 to obtain a coating solution for back electrode (composition for back electrode). The obtained coating solution for back electrode (composition for back electrode) was applied on the transparent and conductive film 14 with various coating methods shown in the following Table 8 in such a manner that film thickness after burning might become 10² to 2×10³ nm; and then, heating for burning was conducted to form the back electrode layer 16 on the transparent and conductive film 14 with the heat treatment conditions shown in the following Table 8. Meanwhile, weight-average molecular weight of polyvinylpyrrolidone in Table 8 was 360,000.

Meanwhile, after the back electrode layer 16 was formed on the transparent and conductive film 14 and before the back electrode reinforcing film 17 was formed on the back electrode layer 16, the back electrode layer 16, the transparent and conductive film 14, and the photoelectric conversion unit 13 were patterned in strips from the backside with a laser processing method at 50 μm laterally apart from the pattered position (separation groove 23) of the photoelectric conversion unit 13; namely, separation process was conducted to form the separation groove 18. Here, the separation process (formation of the separation groove 18) by using a laser processing method was conducted by using a Nd:YAG laser with energy density of 0.7 J/cm³ and pulse frequency of 4 kHz. After separation processing of the back electrode layer 16 and so on, dry etching with CF₄ was carried out for several tens of seconds. Alternatively, wet etching or the like might be carried out. On the back electrode reinforcing film 17 were laminated the filler layer 19 comprised of ethylene-vinyl acetate copolymer (EVA) and the back film 21 comprised of polyethylene terephthalate (PET), in this order; and then heat treatment was conducted at 150° C. for 30 minutes by using a lamination instrument to crosslink the filler layer 19 for stabilization and vacuum adhesion. Then, after a terminal box was attached and taken out, an electrode was connected to obtain a solar cell module 10.

### Example 19

At first, 85% by mass of the acryl type base solution of Group 1 and 15% by mass of mica particles having average diameter of 5 μm and average thickness of about 20 nm (Micromica; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the mica particles into the base solution, whereby a coating solution of the composition for reinforcing film was obtained. Thereafter, this coating solution (composition for reinforcing film) was applied with a spray coating instrument on the back electrode layer (silver electrode layer) of the solar cell module that had already been processed in lamination in such a manner that a coat layer for the reinforcing film having film thickness of 200 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film. A solar cell module was fabricated in a manner similar to those in Example 18 except for the procedures described above.

### Example 20

At first, 95% by mass of the acryl type base solution of Group 2 and 5% by mass of planular Al particles having average diameter of 35 μm and average thickness of about 100 nm (Alpaste; manufactured by Toyo Aluminium K. K.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the Al particles into the base solution, whereby a coating solution of the composition for reinforcing film was obtained. Thereafter, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 400 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film. A solar cell module was fabricated in a manner similar to those in Example 18 except for the procedures described above.

### Example 21

At first, 90% by mass of the acryl type base solution of Group 2 and 10% by mass of silica particles having average particle diameter of about 20 nm (Silica; manufactured by Fuso Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the silica particles into the base solution, whereby a coating solution of the composition for reinforcing film was obtained. Thereafter, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 300 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film. A solar cell module was fabricated in a manner similar to those in Example 18 except for the procedures described above.

### Example 22

At first, 95% by mass of the acryl type base solution of Group 3 and 5% by mass of planular smectite particles having average diameter of 140 nm and average thickness of about 50 nm (Synthetic Smectite; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the smectite particles into the base solution, whereby a coating solution of the composition for reinforcing film was obtained. Thereafter, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 150 nm after curing might be formed. Then, after the solvent was removed from the coat layer for the reinforcing film by drying under vacuum, the coat layer for the reinforcing film was irradiated with UV beam by using a UV irradiation instrument to cure the coat layer for the reinforcing film with UV beam to obtain the back electrode reinforcing film. A solar cell module was fabricated in a manner similar to those in Example 18 except for the procedures described above.

### Example 23

At first, 93% by mass of the epoxy type base solution of Group 4 and planular Al particles having average diameter of 27 μm and average thickness of about 100 nm (Alpaste; manufactured by Toyo Aluminium K. K.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the Al particles into the base solution, whereby a coating solution of the composition for reinforcing film was obtained. Thereafter, this coating solution (composition for reinforcing film) was applied with a spray coating instrument on the back electrode layer (silver electrode layer) of the solar cell module that had already been processed in lamination, in such a manner that a coat layer for the reinforcing film having film thickness of 400 nm after curing might be formed. Then, after drying at room temperature for 20 minutes or longer, a solar cell module was kept in a hot air drying oven at 150° C. for 20 minutes to thermally cure the coat layer for the reinforcing film to obtain the back electrode reinforcing film. A solar cell module was fabricated in a manner similar to those in Example 18 except for the procedures described above.

### Example 24

At first, 80% by mass of the epoxy type base solution of Group 4 and 20% by mass of mica particles having average diameter of 1 μm and average thickness of about 20 nm (Micromica; manufactured by Co-op Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the mica particles into the base solution, whereby a coating solution of the composition for reinforcing film was obtained. During this operation, shape of the blade and rotation speed were carefully controlled so that temperature of the coating solution might not become 70° C. or higher. Thereafter, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 200 nm after curing might be formed. Then, after drying at room temperature for 20 minutes or longer, a solar cell module was kept in a hot air drying oven at 200° C. for 20 minutes to thermally cure the coat layer for the reinforcing film to obtain the back electrode reinforcing film. A solar cell module was fabricated in a manner similar to those in Example 18 except for the procedures described above.

### Example 25

At first, 97% by mass of the epoxy type base solution of Group 5 and 3% by mass of a fumed silica disperse solution (Aerosil; manufactured by Nippon Aerosil Co., Ltd.) as Additive 1 were mixed and dispersed with an ultrasonic vibration instrument for 10 minutes at room temperature to adapt the mixture thoroughly, whereby a coating solution of the composition for reinforcing film was obtained. Thereafter, this coating solution (composition for reinforcing film) was applied with a die coating instrument on the back electrode layer (silver electrode layer) of the solar cell module that had already been processed in lamination, in such a manner that a coat layer for the reinforcing film having film thickness of 150 nm after curing might be formed. Then, after drying at room temperature for 20 minutes or longer, a solar cell module was kept in a hot air drying oven at 180° C. for 30 minutes to thermally cure the coat layer for the reinforcing film to obtain the back electrode reinforcing film. Meanwhile, the fumed silica disperse solution was prepared as following. Firstly, 10% by mass of fumed silica particles and 90% by mass of a mixed solvent of IPA (isopropyl alcohol) and ethanol (mass ratio of 2:1) were mixed and then agitated at rotation speed of 800 rpm at room temperature for one hour to prepare a mixture. Then, 60 g of this mixture was taken into a 100-mL glass bottle and dispersed in a paint shaker by using 100 g of zirconia beads having diameter of 0.3 mm (Microhica; manufactured by Showa Shell Sekiyu K. K.) for 6 hours to prepare the disperse solution of fumed silica of the conductive oxide microparticles. A solar cell module was fabricated in a manner similar to those in Example 18 except for the procedures described above.

### Example 26

At first, 95% by mass of the epoxy type base solution of Group 6 and 5% by mass of planular smectite particles having average diameter of 180 nm and average thickness of about 30 run (Synthetic Smectite; manufactured by Co-op Chemical. Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse Ti particles into the base solution, whereby a coating solution of the composition for reinforcing film was obtained. During this operation, shape of the blade and rotation speed were carefully controlled so that temperature of the coating solution might not become 70° C. or higher. Thereafter, this coating solution (composition for reinforcing film) was applied with a slit coating instrument on the back electrode layer (silver electrode layer) of the solar cell module that had already been processed in lamination, in such a manner that a coat layer for the reinforcing film having film thickness of 400 nm after curing might be formed. Then, after drying at room temperature for 20 minutes or longer, a solar cell module was kept in a hot air drying oven at 200° C. for 20 minutes to thermally cure the coat layer for the reinforcing film to obtain the back electrode reinforcing film. A solar cell module was fabricated in a manner similar to those in Example 18 except for the procedures described above.

### Example 27

At first, 87% by mass of the epoxy type base solution of Group 6 and 13% by mass of the colloidal silica disperse solution as Additive 1 were mixed with a planetary agitating instrument at room temperature for 10 minutes to adapt the mixture thoroughly, whereby a coating solution of a composition for reinforcing film was obtained. Then, this coating solution (composition for reinforcing film) was applied with a screen printing instrument on the back electrode layer (silver electrode layer) of the solar cell module that had already been processed in lamination, in such a manner that a coat layer for the reinforcing film having film thickness of 900 nm after curing might be formed. Then, after drying at room temperature for 20 minutes or longer, a solar cell module was kept in a hot air drying oven at 200° C. for 30 minutes to thermally cure the coat layer for the reinforcing film to obtain the back electrode reinforcing film. Here, the colloidal silica disperse solution was prepared in a manner similar to that for the fumed silica disperse solution of Example 25. A solar cell module was fabricated in a manner similar to those in Example 18 except for the procedures described above.

### Example 28

At first, 90% by mass of the cellulose type base solution of Group 7 and 10% by mass of silica particles having average particle diameter of about 30 nm (Silica; manufactured by Fuso Chemical Co., Ltd.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the silica particles into the base solution, whereby a coating solution of the composition for reinforcing film was obtained. Thereafter, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 400 nm after curing might be formed. Then, after drying at room temperature for 20 minutes or longer, a solar cell module was kept in a hot air drying oven at 180° C. for 20 minutes to thermally cure the coat layer for the reinforcing film to obtain the back electrode reinforcing film. A solar cell module was fabricated in a manner similar to those in Example 18 except for the procedures described above.

### Example 29

At first, 85% by mass of IPA (isopropyl alcohol) and 15% by mass of colloidal silica having average particle diameter of about 20 nm were mixed to prepare a colloidal silica disperse solution (Snowtex 20; manufactured by Nissan Chemical Industries, Ltd.) of Additive 3. Then, 75% by mass of the SiO₂ binder type base solution of Group 8 and 25% by mass of the colloidal silica disperse solution were mixed and dispersed with an ultrasonic vibration instrument for 10 minutes at room temperature to adapt the mixture thoroughly, whereby a coating solution of the composition for reinforcing film was obtained. Then, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 200 nm after curing might be formed. Then, after the solvent was removed from the coat layer for the reinforcing film by drying under vacuum, a solar cell module was kept in a hot air drying oven at 200° C. for 30 minutes to thermally cure the coat layer for the reinforcing film to obtain the back electrode reinforcing film. Meanwhile, in Table 6, titanium-coupling agent 1 of Additive 1 and ATO (composite oxides of antimony oxide-tin oxide) particles of Additive 2 were already included in the base solution, and thus added amounts of these additives were shown by the rates (values in brackets) relative to 100% by mass of the total coating solution (composition for reinforcing film). A solar cell module was fabricated in a manner similar to those in Example 18 except for the procedures described above.

### Example 30

At first, 98% by mass of the SiO₂ binder type base solution of Group 8 and 2% by mass of the fumed silica disperse solution as Additive 3 were mixed and dispersed with an ultrasonic vibration instrument for 10 minutes at room temperature to adapt the mixture thoroughly, whereby a coating solution of the composition for reinforcing film was obtained. Then, this coating solution (composition for reinforcing film) was applied with a spray coating instrument on the back electrode layer (silver electrode layer) of the solar cell module that had already been processed in lamination, in such a manner that a coat layer for the reinforcing film having film thickness of 150 nm after curing might be formed. Then, after the solvent was removed from the coat layer for the reinforcing film by drying under vacuum, a solar cell module was kept in a hot air drying oven at 150° C. for 20 minutes to thermally cure the coat layer for the reinforcing film to obtain the back electrode reinforcing film. Meanwhile, in Table 6, titanium-coupling agent 1 of Additive 1 and ATO (composite oxides of antimony oxide-tin oxide) particles of Additive 2 were already included in the base solution, and thus added amounts of these additives were shown by the rates (values in brackets) relative to 100% by mass of the total coating solution (composition for reinforcing film). The fumed silica disperse solution was prepared in a manner similar to that for the fumed silica disperse solution of Example 25. A solar cell module was fabricated in a manner similar to those in Example 18 except for the procedures described above.

### Example 31

At first, 95% by mass of the SiO₂ binder type base solution of Group 9 and 5% by mass of the fumed silica disperse solution as Additive 3 were mixed and dispersed with an ultrasonic vibration instrument for 10 minutes at room temperature to adapt the mixture thoroughly, whereby a coating solution of the composition for reinforcing film was obtained. Then, this coating solution (composition for reinforcing film) was applied with a die coating instrument on the back electrode layer (silver electrode layer) of the solar cell module that had already been processed in lamination, in such a manner that a coat layer for the reinforcing film having film thickness of 350 nm after curing might be formed. Then, after the solvent was removed from the coat layer for the reinforcing film by drying under vacuum, a solar cell module was kept in a hot air drying oven at 180° C. for 20 minutes to thermally cure the coat layer for the reinforcing film to obtain the back electrode reinforcing film. Meanwhile, in Table 6, titanium-coupling agent 2 of Additive 1 and ITO (composite oxides of indium oxide-tin oxide) particles of Additive 2 were already included in the base solution, and thus added amounts of these additives were shown by the rates (values in brackets) relative to 100% by mass of the total coating solution (composition for reinforcing film). The fumed silica disperse solution was prepared in a manner similar to that for the fumed silica disperse solution of Example 25. A solar cell module was fabricated in a manner similar to those in Example 18 except for the procedures described above.

### Example 32

At first, 90% by mass of the SiO₂ binder type base solution of Group 9 and 10% by mass of mica particles having average diameter of 5 μm and average thickness of about 20 nm (Micromica; manufactured by Co-op Chemical Co., Ltd.) as Additive 3 were mixed and agitated with a rotor at rotation speed of about 300 rpm for one hour at room temperature to adapt the mixture thoroughly. Then, the mixture was agitated with a disperser blade capable of high-speed rotation till about 5000 rpm to disperse the mica particles into the base solution, whereby a coating solution of the composition for reinforcing film was obtained. During this operation, shape of the blade and rotation speed were carefully controlled so that temperature of the coating solution might not become 70° C. or higher. Thereafter, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 200 nm after curing might be formed. Then, after drying at room temperature for 20 minutes or longer, a solar cell module was kept in a hot air drying oven at 200° C. for 30 minutes to thermally cure the coat layer for the reinforcing film to obtain the back electrode reinforcing film. Meanwhile, in Table 6, titanium-coupling agent 2 of Additive 1 and ITO (composite oxides of indium oxide-tin oxide) particles of Additive 2 were already included in the base solution, and thus added amounts of these additives were shown by the rates (values in brackets) relative to 100% by mass of the total coating solution (composition for reinforcing film). A solar cell module was fabricated in a manner similar to those in Example 18 except for the procedures described above.

### Example 33

At first, 96% by mass of the acryl type base solution of Group 1 and 4% by mass of Al particles having average diameter of 35 μm and average thickness of about 100 nm (Alpaste; manufactured by Toyo Aluminium K. K.) as Additive 1 were mixed and agitated with a rotor at rotation speed of about 300 rpm for one hour at room temperature to adapt the mixture thoroughly. Then, the mixture was agitated with a disperser blade capable of high-speed rotation till about 2000 rpm to disperse the Al particles into the base solution, whereby a coating solution of the composition for reinforcing film was obtained. Thereafter, this coating solution (composition for reinforcing film) was applied with a die coating instrument on the back electrode layer (silver electrode layer) of the solar cell module that had already been processed in lamination, in such a manner that a coat layer for the reinforcing film having film thickness of 250 nm after curing might be formed. Then, the solvent was removed from the coat layer for the reinforcing film by drying under vacuum; and after the coat layer for the reinforcing film was irradiated with UV-beam with a UV-beam irradiation instrument to cure the coat layer for the reinforcing film with UV-beam, a solar cell module was kept in a hot air drying oven at 70° C. for 3 hours to thermally cure the coat layer for the reinforcing film to obtain the back electrode reinforcing film that was thoroughly cured. In this Example, the electric generator layer was made of the photoelectric conversion unit to be comprised of an amorphous silicon monolayer that was laminated, from the side of the substrate, with a p-type a-Si (amorphous silicon), an i-type a-Si, and an n-type a-Si, in this order. A solar cell module was fabricated in a manner similar to those in Example 18 except for the procedures described above.

### Example 34

At first, 85% by mass of IPA (isopropyl alcohol) and 15% by mass of colloidal silica having average particle diameter of about 20 nm were mixed to prepare a colloidal silica disperse solution (IPA-ST; manufactured by Nissan Chemical Industries, Ltd.) of Additive 1. Then, 93% by mass of the acryl type base solution of Group 1 and 7% by mass of the colloidal silica disperse solution were mixed and dispersed with an ultrasonic vibration instrument for 10 minutes at room temperature to adapt the mixture thoroughly, whereby a coating solution of the composition for reinforcing film was obtained. Then, this coating solution (composition for reinforcing film) was applied with a spin coating instrument on the back electrode layer (silver electrode layer) of the solar cell module that had already been processed in lamination, in such a manner that a coat layer for the reinforcing film having film thickness of 400 nm after curing might be formed. Then, the solvent was removed from the coat layer for the reinforcing film by drying under vacuum; and after the coat layer for the reinforcing film was irradiated with UV-beam with a UV-beam irradiation instrument to cure the coat layer for the reinforcing film with UV-beam, a solar cell module was kept in a hot air drying oven at 70° C. for 3 hours to thermally cure the coat layer for the reinforcing film to obtain the back electrode reinforcing film that was thoroughly cured. In this Example, the electric generator layer of the photoelectric conversion unit 13 was made to be comprised of a microcrystalline silicon monolayer laminated, from the side of the substrate, with a p-type μc-Si (microcrystalline silicon), an i-type μc-Si, and an n-type μc-Si, in this order. A solar cell module was fabricated in a manner similar to those in Example 18 except for the procedures described above.

### Comparative Example 4

The back electrode reinforcing film was not formed, on the solar cell module that had already been processed in lamination, namely on the solar cell module that had already formed the transparent and conductive film and the back electrode layer with a wet coating method on the photoelectric conversion unit. Comparative Example 4 relates to this solar cell module.

### Comparative Example 5

The back electrode reinforcing film (Ti layer) having thickness of 15 nm was formed by vapor-deposition of Ti (titanium) with a sputtering method, on the solar cell module that had already been processed in lamination, namely on the solar cell module that had already formed the transparent and conductive film and the back electrode layer with a wet coating method on the photoelectric conversion unit. Comparative Example 5 relates to this solar cell module.

### Comparative Example 6

The back electrode reinforcing film (Al layer) having thickness of 200 nm was formed by vapor-deposition of Al (aluminum) with a sputtering method, on the solar cell module that had already been processed in lamination, namely on the solar cell that had already formed the transparent and conductive film and the back electrode layer with a wet coating method on the photoelectric conversion unit. Comparative Example 6 relates to this solar cell module.

Comparative tests 2 and evaluations:

Flash formation, adhesion, and relative output characteristics of the solar cell modules of Examples 18 to 34 and Comparative Examples 4 to 6 were evaluated. As to evaluation of flash formation, degree of flash formation into the inner side of a separation groove (worked surface) and irregularity in width of the separation groove, during the time of working the solar cell module by a laser scriber of a laser processing method, were classified into four groups: Excellent, Good, Fair, and Unacceptable. The separation groove having stable and beautiful worked lines was classified as “Excellent”. The separation groove partly showing a heave and the like but not showing large concavities and convexities or bumps was classified as “Good”. As a whole, the separation groove having unstable line width and constantly showing irregularities and concavities and convexities in worked lines, but always having a space between the lines thereby not having a short-circuit part was classified as “Fair”. The separation groove having exceedingly large concavities and convexities in worked lines thereby having unbroken space between the lines so that there might possibly occur short-circuit, or having cutting scraps that were larger than the groove width and were attached strongly on the lines was classified as “Unacceptable”.

As to evaluation of adhesion, according to the tape test (JIS K-5600), degree of delamination or peel-off of the back electrode reinforcing film and so on observed, when an adhesive tape was attached to and removed from a worked part of the solar cell module, was classified into four groups: Excellent, Good, Fair, and Unacceptable. The solar cell module whose worked part was not attached to the adhesive tape was classified as “Excellent. The solar cell module whose work scraps were partly attached to the adhesive tape but worked lines themselves did not float up was classified as “Good”. The solar cell module whose work scraps were formed and worked lines were partly peeled off in their shape, but line part itself was not changed in its shape was classified as “Fair”. The solar cell module whose work scraps as well as the reinforcing film itself near the lines were attached to the adhesive tape thereby changing shapes of the lines themselves was classified as “Unacceptable”.

Relative output characteristics were evaluated as following. Firstly, lead wiring was made on the substrate after the solar cell module was worked out to make lines; and the measured value of output characteristics (FF (fill factor) is shown by [maximum output]/([open voltage]×[short-circuit current])) upon confirmation of an I-V (current-voltage) characteristic curve was taken as the initial value. After about one week, the value of output characteristics (fill factor FF), upon confirmation whether or not there was any change of Ag itself of the back electrode layer by corrosion, was measured; and the measured value thereby obtained was expressed by the rate (%) relative to the initial value as 100%. These results, together with kind of binders and thickness of the back electrode reinforcing film, are shown in Table 9. Meanwhile, curing method of the coating solution for reinforcing film (composition for reinforcing film), group number and mixing ratio of the base solution, kind and mixing ratio of Additives 1 to 3, coating method of the coating solution for reinforcing film (composition for reinforcing film), and thickness of the back electrode reinforcing film, in Examples 18 to 34 and Comparative Examples 4 to 6, are shown in Table 6. In Table 8, kind and mixing ratio of metal nanoparticles, kind and mixing ratio of Additives 1, kind and mixing ratio of Additives 2, coating method, and conditions of heat treatment, in the coating solution for back electrode (composition for back electrode), are shown.

TABLE 8

| | Coating solution for back electrode (composition for back electrode) | | | | | | | | |
|---|---|---|---|---|---|---|---|---|---|
| | Metal | | | | | | | | |
| | nano- | | | | | | | Temperature of | Time of heat |
| | particles | | Additive 1 | | Additive 2 | | Coating | heat treatment | treatment |
| | Kind | % | Kind | % | Kind | % | method | (° C.) | (minutes) |
| Example 18 | Ag | 94 | Polyvinylpyrrolidone | 5 | Ni acetate | 1 | Spin | 200 | Air, 20 |
| Example 19 | Ag | 96 | Polyvinylpyrrolidone | 3 | Cu acetate | 1 | Spin | 200 | Air, 20 |
| Example 20 | Ag | 94 | Hydroxypropyl methyl | 3 | Sn acetate | 1 | Spin | 200 | Air, 20 |
| | Ru | 2 | cellulose | | | | | | |
| Example 21 | Ag | 92 | Polyvinylpyrrolidone | 3 | Sn acetate | 1 | Dispenser | 130 | Air, 20 |
| | Cu | 4 | | | | | | | |
| Example 22 | Ag | 95.8 | Polyvinylpyrrolidone | 3 | Zn acetate | 1 | Offset | 320 | Air, 20 |
| | Fe | 0.2 | | | | | | | |
| Example 23 | Ag | 95 | Polyvinylpyrrolidone | 4 | TiO₂ | 1 | Spin | 150 | Air, 20 |
| Example 24 | Ag | 95 | Polyvinylpyrrolidone | 4 | Cr₂O₃ | 1 | Spin | 150 | Air, 20 |
| Example 25 | Ag | 95 | Polyvinylpyrrolidone | 4 | MnO₂ | 1 | Spin | 150 | Air, 20 |
| Example 26 | Ag | 95 | Polyvinylpyrrolidone | 4 | Ag₂O | 1 | Spin | 150 | Air, 20 |
| Example 27 | Ag | 95 | Polyvinylpyrrolidone | 4 | MnO₂ | 1 | Spin | 150 | Air, 20 |
| Example 28 | Ag | 95 | Polyvinylpyrrolidone | 4 | SnO₂ | 1 | Spin | 150 | Air, 20 |
| Example 29 | Ag | 95 | Polyvinylpyrrolidone | 4 | Methyl silicate | 1 | Spin | 150 | Air, 20 |
| Example 30 | Ag | 95 | Polyvinylpyrrolidone | 4 | Titanium | 1 | Spin | 150 | Air, 20 |
| | | | | | isopropoxide | | | | |
| Example 31 | Ag | 95.9 | Polyvinylpyrrolidone | 4 | Mn formate | 1 | Spin | 150 | Air, 20 |
| Example 32 | Ag | 95.9 | Polyvinylpyrrolidone | 4 | Co formate | 0.01 | Spin | 200 | Air, 20 |
| Example 33 | Ag | 95 | Cu acetate | 5 | — | — | Spin | 150 | Air, 20 |
| Example 34 | Ag | 95 | Sn acetate | 5 | — | — | Die | 150 | Air, 20 |
| Comparative | Ag | 94 | Polyvinylpyrrolidone | 5 | Ni acetate | 1 | Spin | 200 | Air, 20 |
| Example 4 | | | | | | | | | |
| Comparative | Ag | 94 | Polyvinylpyrrolidone | 5 | Ni acetate | 1 | Spin | 200 | Air, 20 |
| Example 5 | | | | | | | | | |
| Comparative | Ag | 94 | Polyvinylpyrrolidone | 5 | Ni acetate | 1 | Spin | 200 | Air, 20 |
| Example 6 | | | | | | | | | |

TABLE 9

| | Back electrode reinforcing film | | | | Relative output |
|---|---|---|---|---|---|
| | Binder | Thickness (nm) | Flash formation | Adhesion | characteristics (%) |
| Example 18 | Acryl type | 500 | Excellent | Excellent | 97 or more |
| Example 19 | Acryl type | 200 | Excellent | Excellent | 97 |
| Example 20 | Acryl type | 400 | Good | Excellent | 97 |
| Example 21 | Acryl type | 300 | Excellent | Excellent | 95 |
| Example 22 | Acryl type | 150 | Good | Excellent | 95 |
| Example 23 | Epoxy type | 400 | Excellent | Good | 97 |
| Example 24 | Epoxy type | 200 | Excellent | Excellent | 96 |
| Example 25 | Epoxy type | 150 | Excellent | Excellent | 96 |
| Example 26 | Epoxy type | 400 | Excellent | Excellent | 95 |
| Example 27 | Epoxy type | 900 | Excellent | Excellent | 97 |
| Example 28 | Cellulose type | 400 | Good | Excellent | 95 |
| Example 29 | SiO₂ binder type | 200 | Excellent | Excellent | 97 |
| Example 30 | SiO₂ binder type | 150 | Excellent | Excellent | 97 |
| Example 31 | SiO₂ binder type | 350 | Excellent | Good | 95 |
| Example 32 | SiO₂ binder type | 200 | Excellent | Excellent | 96 |
| Example 33 | Acryl type | 250 | Good | Excellent | 97 |
| Example 34 | Acryl type | 400 | Excellent | Excellent | 96 |

| | | | | |
|---|---|---|---|---|
| Comparative Example 4 | Without reinforcing film | Unacceptable | Unacceptable | 60 |
| Comparative Example 5 | Ti layer with 15 nm thickness | Fair | Unacceptable | 90 |
| Comparative Example 6 | Al layer with 200 nm thickness | Fair | Unacceptable | 85 |

As can be seen in the column “Flash formation” of Table 9, in Comparative Example 4 in which the reinforcing film was not formed, the separation groove had exceedingly large concavities and convexities in worked lines with unbroken space therebetween; and in addition, cutting scraps that were larger than the line width had remained on the lines by attaching thereon strongly. In Comparative Examples 5 and 6, in which the reinforcing film of Ti or Al was used, no short-circuit sites were seen because there was always a space between the lines; but in the entire separation groove, the line width was not stable and irregular concavities and convexities were seen in the worked lines. On the other hand, in Examples 18 to 34, in which the reinforcing film was formed by curing the binder having dispersed silica particles, mica particles, or the like, worked lines of the separation groove were stable and beautiful; and in addition, there were no large concavities and convexities or bumps, though there was a heave in part of the separation groove. As can be seen in the column of “Adhesion” of Table 9, in Comparative Example 4 not having the reinforcing film, Comparative Example 5 having the reinforcing film of Ti, and Comparative Example 6 having the reinforcing film of Al, work scraps of the solar cell module as well as the reinforcing film itself near the lines were attached to the adhesive tape, indicating that shapes of the lines themselves were changed. On the other hand, in Examples 18 to 34, in which the reinforcing film was formed by curing the binder having dispersed silica particles, mica particles, or the like, worked lines themselves did not float up; and thus, there was no significant change in shape of the lines themselves. As can be seen in the column of “Relative output characteristics” of Table 9, in Comparative Examples 5 and 6, in which the reinforcing film of Ti or Al was used, the relative output characteristics were high (90% and 85%, respectively), while in Comparative Example 4 not having the reinforcing film, the relative output characteristics was decreased to as low as 60%; on the other hand, in Examples 18 to 34, in which the reinforcing film was formed by curing the binder having dispersed silica particles, mica particles, or the like, the relative output characteristics were extremely high (95% or higher).

As described above, it can be seen the following. When the separation groove is formed with a laser scriber in the solar cell module, the back electrode reinforcing film plays a key role in processing. The back electrode layer (silver electrode layer) is a soft material, and is used as a reflection film as well; and thus, the shape thereof is easily changeable so that the processing of it is difficult. Namely, formation of flashes and poor adhesion such as peel-off during formation of the separation groove take place mostly in the back electrode layer. As a result, it was found that, when the back electrode layer was covered with a hard and brittle back electrode reinforcing film, breaking properties (workability) were improved so that poor adhesion and formation of flashes during formation of the separation groove could be avoided in the back electrode layer. In addition, the back electrode layer (silver electrode layer) was easily deteriorated and discolored upon contacting with an oxidative or a sulfidizing atmosphere. As a result, there had been such problems as decreased conductivity and poor output due to lack of necessary reflectance. However, it was found that, when the back electrode layer was covered with the back electrode reinforcing film, deterioration of the back electrode layer could be avoided; and as a result, relative output characteristics were hardly decreased even if the solar cell module of the Examples having the back electrode layer covered with the back electrode reinforcing film was allowed to stand in an air for about one week.

### Example 35

Firstly, as shown in FIG. 4, on the back electrode layer 16 (silver electrode layer) of the solar cell module that had already been processed in lamination was formed the reinforcing film 17 according to Reinforcing Film No. 12 of the above Table 2. Then, patterning was made by irradiating a laser beam from the side of the substrate 11 at 50 μm laterally apart from the patterned position (separation groove 23) of the photoelectric conversion unit 13, as described later. Namely, separation process into strips was conducted by forming the separation groove 18, extended from surface of the reinforcing film 17 to the front electrode layer 12, by a laser scriber that blast-cut the photoelectric conversion unit 13, the transparent and conductive film 14, the back electrode layer 16, and the back electrode reinforcing film 17. Here, the separation process (formation of the separation groove 18) by using a laser scriber was conducted by using a Nd:YAG laser with energy density of 0.7 J/cm³ and pulse frequency of 4 kHz. Finally, the separation groove 18 was filled, and the single barrier film according to Barrier Film No. 1 of the above Table 3 was formed on the reinforcing film 17. Example 35 relates to this solar cell module.

Meanwhile, “the solar cell module that has already been processed in lamination” means the following state. At first, as shown in FIG. 4, a glass plate formed with a SiO₂ layer having thickness of 50 nm (not shown in the figure) on its one main surface is prepared as the substrate 11. Then, on surface of the SiO₂ layer was formed with a sputtering method the front electrode layer 12 (SnO₂ film) with thickness of 800 nm having surface of a concave-convex texture and doped with F (fluorine). The front electrode layer 12 is patterned with a laser processing method. Namely, separation process in strips was conducted by forming the separation groove 22. Here, the separation process (formation of the separation groove 22) by using a laser processing method was conducted by using a Nd:YAG laser with wavelength of about 1.06 μm, energy density of 13 J/cm³, and pulse frequency of 3 kHz. Then, on the front electrode layer 12 was formed the photoelectric conversion unit 13 with a plasma CVD method. In this Example, the photoelectric conversion unit 13 was made to have a tandem type structure comprised of two layers; an amorphous silicon layer laminated, in order, from the side of the substrate 11, with a p-type a-Si (amorphous silicon), an i-type a-Si, and an n-type a-Si, and a microcrystalline silicon layer further laminated, on this amorphous silicon layer, with a p-type μc-Si (microcrystalline silicon), an i-type and an n-type μc-Si. Specifically, the amorphous silicon layer was formed with a plasma CVD method by laminating: a p-type a-Si having film thickness of 10 nm formed with a gas mixture of SiH₄, CH₄, H₂, and B₂H₆; an i-type a-Si having film thickness of 300 nm formed with a gas mixture of SiH₄ and H₂; and an n-type a-Si having film thickness of 20 nm formed with a gas mixture of SiH₄, H₂, and PH₃, in this order. The microcrystalline silicon layer was formed with a plasma CVD method by laminating: a p-type μc-Si having film thickness of 10 nm formed with a gas mixture of SiH₄, H₂, and H₂, and B₂H₆; and i-type μc-Si having film thickness of 2000 nm formed with a gas mixture of SiH₄ and H₂; and an n-type μc-Si having film thickness of 20 nm formed with a gas mixture of SiH₄, H₂, and PH₃, in this order. Detailed conditions of the foregoing plasma CVD method are shown in the above Table 5. Further, the foregoing photoelectric conversion unit 13 was patterned into strips with a laser processing method. Namely, separation process was conducted to form the separation groove 23. The separation groove 23 was formed at 50 μm laterally apart from the patterned position of the front electrode layer 12. Then, on the photoelectric conversion unit 13 were formed the transparent and conductive film 14 (ZnO layer) having thickness of 80 nm and the back electrode layer 16 (silver electrode layer) having thickness of 200 nm, in this order, by using a magnetron in-line sputtering instrument. Here, the separation process (formation of the separation groove 23) by using a laser scriber was conducted by using a Nd: YAG laser with energy density of 0.7 J/cm³ and pulse frequency of 3 kHz.

### Example 36

The solar cell module was fabricated in a manner similar to those of Example 35, except that the reinforcing film was formed with Reinforcing Film No. 1 and the barrier film was formed with Barrier Film No. 12, as shown in the following Table 10.

### Example 37

The solar cell module was fabricated in a manner similar to those of Example 35, except that the reinforcing film was formed with Reinforcing Film No. 13 and the barrier film was formed with Barrier Film No. 4, as shown in the following Table 10.

### Example 38

The solar cell module was fabricated in a manner similar to those of Example 35, except that the reinforcing film was formed with Reinforcing Film No. 7 and the barrier film was formed with Barrier Film No. 7, as shown in the following Table 10.

### Example 39

The solar cell module was fabricated in a manner similar to those of Example 35, except that the reinforcing film was formed with Reinforcing Film No. 2 and the barrier film was formed with Barrier Film No. 14, as shown in the following Table 10.

### Example 40

The solar cell module was fabricated in a manner similar to those of Example 35, except that, the reinforcing film was formed by Reinforcing Film No. 3, and after Barrier Film No. 16 was formed, Barrier Film No. 1 was further formed thereon thereby forming a barrier film comprised of two layers, as shown in the following Table 10.

### Example 41

The solar cell module was fabricated in a manner similar to those of Example 35, except that, the reinforcing film was formed by Reinforcing Film No. 8, and after Barrier Film No. 14 was formed, Barrier Film No. 6 was further formed thereon thereby forming a barrier film comprised of two layers, as shown in the following Table 10.

### Example 42

The solar cell module was fabricated in a manner similar to those of Example 35, except that, the reinforcing film was formed by Reinforcing Film No. 10, and after Barrier Film No. 15 were formed, Barrier Film No. 7 was further formed thereon thereby forming a barrier film comprised of two layers, as shown in the following Table 10.

### Example 43

The solar cell module was fabricated in a manner similar to those of Example 35, except that, the reinforcing film was formed by Reinforcing Film No. 16, and after Barrier Film No. 13 was formed, Barrier Film No. 10 was further formed thereon thereby forming a barrier film comprised of two layers, as shown in the following Table 10.

### Example 44

The solar cell module was fabricated in a manner similar to those of Example 35, except that, the reinforcing film was formed by Reinforcing Film No. 14, and after Barrier Film No. 4 was formed, Barrier Film No. 16 was further formed thereon thereby forming a barrier film comprised of two layers, as shown in the following Table 10.

### Example 45

The solar cell module was fabricated in a manner similar to those of Example 35, except that, the reinforcing film was formed by Reinforcing Film No. 15, and after Barrier Film No. 15 was formed, Barrier Film No. 1 and then Barrier Film No. 21 were further formed thereon thereby forming a barrier film comprised of three layers, as shown in the following Table 10.

### Example 46

The solar cell module was fabricated in a manner similar to those of Example 35, except that, the reinforcing film was formed by Reinforcing Film No. 9, and after Barrier Film No. 17 was formed, Barrier Film No. 2 and then Barrier Film No. 19 were further formed thereon thereby forming a barrier film comprised of three layers, as shown in the following Table 10.

### Example 47

The solar cell module was fabricated in a manner similar to those of Example 35, except that, the reinforcing film was formed by Reinforcing Film No. 4, and after Barrier Film No. 20 was formed, Barrier Film No. 18 and then Barrier Film No. 3 were further formed thereon thereby forming a barrier film comprised of three layers, as shown in the following Table 10.

### Example 48

The solar cell module was fabricated in a manner similar to those of Example 35, except that, the reinforcing film was formed by Reinforcing Film No. 12, and after Barrier Film No. 13 were formed, Barrier Film No. 22 and then Barrier Film No. 5 was further formed thereon thereby forming a barrier film comprised of three layers, as shown in the following Table 10.

### Example 49

The solar cell module was fabricated in a manner similar to those of Example 35, except that, the reinforcing film was formed by Reinforcing Film No. 5, and after Barrier Film No. 17 was formed, Barrier Film No. 20 and then Barrier Film No. 23 were further formed thereon thereby forming a barrier film comprised of three layers, as shown in the following Table 10.

### Example 50

The solar cell module was fabricated in a manner similar to those of Example 35, except that, the reinforcing film was formed by Reinforcing Film No. 11, and Barrier Film No. 12, Barrier Film No. 9, Barrier Film No. 19, and then Barrier Film No. 1 were further formed thereon in this order thereby forming a barrier film comprised of four layers, as shown in the following Table 10.

### Example 51

The solar cell module was fabricated in a manner similar to those of Example 35, except that, the reinforcing film was formed by Reinforcing Film No. 2, and Barrier Film No. 18, Barrier Film No. 11, Barrier Film No. 22, and then Barrier Film No. 4 were further formed thereon in this order thereby forming a barrier film comprised of four layers, as shown in the following Table 10.

### Example 52

The solar cell module was fabricated in a manner similar to those of Example 35, except that, the reinforcing film was formed by Reinforcing Film No. 6, and Barrier Film No. 13, Barrier Film No. 6, Barrier Film No. 17, and then Barrier Film No. 24 were further formed thereon in this order thereby forming a barrier film comprised of four layers, as shown in the following Table 10.

### Example 53

The solar cell module was fabricated in a manner similar to those of Example 35, except that, the reinforcing film was formed by Reinforcing Film No. 14, and Barrier Film No. 14, Barrier Film N . 7, Barrier Film No. 12, Barrier Film No. 1, and then Barrier Film No. 16 were further formed thereon in this order thereby forming a barrier film comprised of five layers, as shown in the following Table 10.

### Example 54

The solar cell module was fabricated in a manner similar to those of Example 35, except that, the reinforcing film was formed by Reinforcing Film No. 13, and Barrier Film No. 20, Barrier Film No. 10, Barrier Film No. 20, Barrier Film No. 3, and then Barrier Film No. 21 were further formed thereon in this order thereby forming a barrier film comprised of five layers, as shown in the following Table 10.

### Example 55

The solar cell module was fabricated in a manner similar to those of Example 35, except that, the reinforcing film was formed by Reinforcing Film No. 1, and Barrier Film No. 15, Barrier Film No. 8, Barrier Film No. 18, Barrier Film No. 4, and then Barrier Film No. 22 were further formed thereon in this order thereby forming a barrier film comprised of five layers, as shown in the following Table 10.

### Example 56

The solar cell module was fabricated in a manner similar to those of Example 35, except that, the reinforcing film was formed by Reinforcing Film No. 17, and Barrier Film No. 17, Barrier Film No. 19, Barrier Film No. 4, Barrier Film No. 19, and then Barrier Film No. 5 were further formed thereon in this order thereby forming a barrier film comprised of five layers, as shown in the following Table 10. In this Example, the electric generator layer 13 was made of the photoelectric conversion unit to be comprised of an amorphous silicon monolayer that was laminated, from the substrate 11 side, with a p-type a-Si (amorphous silicon), an i-type a-Si, and an n-type a-Si, in this order.

### Example 57

The solar cell module was fabricated in a manner similar to those of Example 35, except that, the reinforcing film was formed by Reinforcing Film No. 10, Barrier Film No. 13, Barrier Film No. 21, Barrier Film No. 2, Barrier Film No. 21, and then Barrier Film No. 2 were further formed thereon in this order thereby forming a barrier film comprised of five layers, as shown in the following Table 10. In this Example, the electric generator layer 13 was made of the photoelectric conversion unit to be comprised of a microcrystalline silicon monolayer that was laminated, from the substrate 11 side, with a p-type μc-Si (microcrystalline silicon), an i-type μc-Si, and an n-type μc-Si, in this order.

### Comparative Example 7

A titanium layer having thickness of 15 nm was formed as the back silver electrode reinforcing film in such a manner that the back silver electrode layer of the solar cell module that had already been processed in lamination might be covered; and then, after scribing with a laser processing method, EVA resin and PET film, as the barrier materials, were thermally adhered therewith. Comparative Example 7 relates to this solar cell module.

### Comparative Example 8

A titanium layer having thickness of 15 nm was formed as the back silver electrode reinforcing film in such a manner that the back silver electrode layer of the solar cell module that had already been processed in lamination might be covered; and then, after scribing with a laser processing method, EVA resin and Tedlar film (manufactured by E. I. du Pont de Nemours and Company), as the barrier materials, were thermally adhered thereon. Comparative Example 8 relates to this solar cell module.

TABLE 10

| | | Barrier Film No. | | | | |
|---|---|---|---|---|---|---|
| | Reinforcing | First | Second | Third | Fourth | Fifth |
| | Film No. | layer | layer | layer | layer | layer |
| Example 35 | 12 | 1 | — | — | — | — |
| Example 36 | 1 | 12 | — | — | — | — |
| Example 37 | 13 | 4 | — | — | — | — |
| Example 38 | 7 | 7 | — | — | — | — |
| Example 39 | 2 | 14 | — | — | — | — |
| Example 40 | 3 | 16 | 1 | — | — | — |
| Example 41 | 8 | 14 | 6 | — | — | — |
| Example 42 | 10 | 15 | 7 | — | — | — |
| Example 43 | 16 | 13 | 10 | — | — | — |
| Example 44 | 14 | 4 | 16 | — | — | — |
| Example 45 | 15 | 15 | 1 | 21 | — | — |
| Example 46 | 9 | 17 | 2 | 19 | — | — |
| Example 47 | 4 | 20 | 18 | 3 | — | — |
| Example 48 | 12 | 13 | 22 | 5 | — | — |
| Example 49 | 5 | 17 | 20 | 23 | — | — |
| Example 50 | 11 | 12 | 9 | 19 | 1 | — |
| Example 51 | 2 | 18 | 11 | 22 | 4 | — |
| Example 52 | 6 | 13 | 6 | 17 | 24 | — |
| Example 53 | 14 | 14 | 7 | 12 | 1 | 16 |
| Example 54 | 13 | 20 | 10 | 20 | 3 | 21 |
| Example 55 | 1 | 15 | 8 | 18 | 4 | 22 |
| Example 56 | 17 | 17 | 19 | 4 | 19 | 5 |
| Example 57 | 10 | 13 | 21 | 2 | 21 | 2 |
| Comparative | — | — | — | — | — | — |
| Example 7 | | | | | | |
| Comparative | — | — | — | — | — | — |
| Example 8 | | | | | | |

Comparative tests 3 and Evaluations:

Each solar cell module of examples 35 to 57 and Comparative Examples 7 to 8 was evaluated as to the following items. The results are shown in the following Table 11.

### (1) Hygrothermal Cycle:

The hygrothermal cycle test between -40° C./one hour and 85° C./85% RH/four hours was repeated for 20 cycles; and then, appearance of the solar cell module after the test was observed.

### (2) Conversion Efficiency:

At first, lead wiring was made on the substrate after the solar cell module was worked out to make lines, and then an I-V (current-voltage) characteristic upon irradiation of light with AM 1.5 and 100 mW/cm² was measured by using a solar simulator and a digital source meter; and then, conversion efficiency was obtained based on calculated values. In this calculation, conversion efficiency was obtained as the relative value to Comparative Example 7, which was taken as 1.

### (3) Reliability Test:

The solar cell module was kept under atmosphere of 85° C. and 85% RH for 2000 hours; and conversion efficiencies of the solar cell module before and after the test were compared to obtain relative decrease rate.

### (4) Adhesion:

Adhesion of the barrier film was evaluated by the tape test method according to JIS K-5400. Specifically, evaluation was made based on degree of conditions of delamination or peel-off of the formed film when an adhesive tape was attached to and removed from a worked part, so that the classification was made into three groups: Good, Fair, and Unacceptable. Upon peeling-off of the tape, the film whose worked part did not change while only the tape being peeled-off was classified as “Good”; the film whose work scraps were partly attached to the tape but film surface was not changed was classified as “Fair”; and the film which was delaminated or peeled-off, or formed a space such as an air bubble in its interface, or was attached to the tape was classified as “Unacceptable”.

TABLE 11

| | | Conversion | Reliability test | |
|---|---|---|---|---|
| | | efficiency | (relative | |
| | Hygrothermal | (relative | decrease | |
| | cycle | value) | rate (%)) | Adhesion |
| Example 35 | No change | 1.11 | 5% or less | Good |
| Example 36 | No change | 1.07 | 5% or less | Good |
| Example 37 | No change | 1.17 | 5% or less | Good |
| Example 38 | No change | 1.13 | 5% or less | Good |
| Example 39 | No change | 1.04 | 5% or less | Good |
| Example 40 | No change | 1.05 | 5% or less | Good |
| Example 41 | No change | 1.15 | 5% or less | Good |
| Example 42 | No change | 1.09 | 5% or less | Good |
| Example 43 | No change | 1.12 | 5% or less | Good |
| Example 44 | No change | 1.12 | 5% or less | Good |
| Example 45 | No change | 1.41 | 5% or less | Fair |
| Example 46 | No change | 1.23 | 5% or less | Good |
| Example 47 | No change | 1.19 | 5% or less | Good |
| Example 48 | No change | 1.31 | 5% or less | Good |
| Example 49 | No change | 1.33 | 5% or less | Good |
| Example 50 | No change | 1.39 | 5% or less | Good |
| Example 51 | No change | 1.24 | 5% or less | Good |
| Example 52 | No change | 1.29 | 5% or less | Good |
| Example 53 | No change | 1.21 | 5% or less | Good |
| Example 54 | No change | 1.19 | 5% or less | Good |
| Example 55 | No change | 1.22 | 5% or less | Good |
| Example 56 | No change | 1.39 | 5% or less | Good |
| Example 57 | No change | 1.42 | 5% or less | Good |
| Comparative | No change | 1.0 | 15% | Fair |
| Example 7 | | | | |
| Comparative | No change | 1.03 | 10% | Good |
| Example 8 | | | | |

As can be seen in Table 11, in comparison between Examples 35 to 57 and Comparative Examples 7 to 8 in the hygrothermal test, it was confirmed that Examples 35 to 57 showed excellent humidity resistance in appearance, similarly to Comparative Examples 7 to 8, which were based on conventional methods. Especially in the reliability test, all of Examples 35 to 57 received high rating as compared with Comparative Example 7, so that high humidity resistance could be confirmed.

### Example 58

At first, as shown in FIG. 4, with a sputtering method by using a magnetron in-line sputtering instrument, on the photoelectric conversion unit 13 of the solar cell module that had already been processed in lamination was formed a ZnO film having thickness of 80 nm, which was made as the transparent and conductive film 14. Then, the back electrode layer 16 (silver electrode layer) according to Back Electrode Layer No. 12 of the above Table 1 was formed. On this back electrode layer 16 was formed the reinforcing film 17 according to Reinforcing Film No. 12 of the above Table 2. Then, patterning was made by irradiating a laser beam from the substrate 11 side at 50 μm laterally apart from the patterned position (separation groove 23) of the photoelectric conversion unit 13, as described later. Namely, separation process into strips was conducted by forming the separation groove 18, extended from surface of the reinforcing film 17 to the front electrode layer 12, by a laser scriber that blast-cuts the photoelectric conversion unit 13, the transparent and conductive film 14, the back electrode layer 16, and the back electrode reinforcing film 17. Here, the separation process (formation of the separation groove 18) by using a laser scriber was conducted by using a Nd:YAG laser with energy density of 0.7 J/cm³ and pulse frequency of 4 kHz. Finally, the separation groove 18 was filled, and the single barrier film 19 according to Barrier Film No. 1 of the above Table 3 was formed on the reinforcing film 17. Example 58 relates to this solar cell module.

Meanwhile, “the solar cell module that has already been processed in lamination” means the following state. At first, as shown in FIG. 4, a glass plate formed with a SiO₂ layer having thickness of 50 nm (not shown in the figure) on its one main surface is prepared as the substrate 11. Then, on surface of the SiO₂ layer was formed with a sputtering method the front electrode layer 12 (SnO₂ film) with thickness of 800 nm having surface of a concave-convex texture and doped with F (fluorine). The front electrode layer 12 is patterned with a laser processing method. Namely, separation process in strips was conducted by forming the separation groove 22. Here, the separation process (formation of the separation groove 22) by using a laser processing method was conducted by using a Nd:YAG laser with wavelength of about 1.06 μm, energy density of 13 J/cm³, and pulse frequency of 3 kHz. Then, on the front electrode layer 12 was formed the photoelectric conversion unit 13 with a plasma CVD method. In this Example, the photoelectric conversion unit 13 was made to have a tandem type structure comprised of two layers; an amorphous silicon layer laminated, in order, from the substrate 11 side, with a p-type a-Si (amorphous silicon), an i-type a-Si, and an n-type a-Si, and a microcrystalline silicon layer further laminated, on this amorphous silicon layer, with a p-type μc-Si (microcrystalline silicon), an i-type μc-Si, and an n-type μc-Si. Specifically, the amorphous silicon layer was formed with a plasma CVD method by laminating: a p-type a-Si having film thickness of 10 nm formed with a gas mixture of SiH₄, CH₄, H₂, and B₂H₆; an i-type a-Si having film thickness of 300 nm formed with a gas mixture of SiH₄ and H₂; and an n-type a-Si having film thickness of 20 nm formed with a gas mixture of SiH₄, H₂, and PH₃, in this order. The microcrystalline silicon layer was formed with a plasma CVD method by laminating: a p-type μc-Si having film thickness of 10 nm formed with a gas mixture of SiH₄, H₂, and B₂H₆; an i-type μc-Si having film thickness of 2000 nm formed with a gas mixture of SiH₄ and H₂; and an n-type μc-Si having film thickness of 20 nm formed with a gas mixture of SiH₄, H₂, and PH₃, in this order. Detailed conditions of the foregoing plasma CVD method are shown in the above Table 5. Further, the foregoing photoelectric conversion unit 13 was patterned into strips with a laser processing method. Namely, separation process was conducted to form the separation groove 23. The separation groove 23 was formed at 50 μm laterally apart from the patterned position of the front electrode layer 12. Here, the separation process (formation of the separation groove 23) by using a laser processing method was conducted by using a Nd:YAG laser with energy density of 0.7 J/cm³ and pulse frequency of 3 kHz.

### Example 59

The solar cell module was fabricated in a manner similar to those of Example 58, except that the back electrode layer was formed with Back Electrode Layer No. 1, the reinforcing film was formed with Reinforcing Film No. 1, and the barrier film was formed with Barrier Film No. 12, as shown in the following Table 12.

### Example 60

The solar cell module was fabricated in a manner similar to those of Example 58, except that the back electrode layer was formed with Back Electrode Layer No. 13, the reinforcing film was formed with Reinforcing Film No. 13, and the barrier film was formed with Barrier Film No. 4, as shown in the following Table 12.

### Example 61

The solar cell module was fabricated in a manner similar to those of Example 58, except that the back electrode layer was formed with Back Electrode Layer No. 7, the reinforcing film was formed with Reinforcing Film No. 7, and the barrier film was formed with Barrier Film No. 7, as shown in the following Table 12.

### Example 62

The solar cell module was fabricated in a manner similar to those of Example 58, except that the back electrode layer was formed with Back Electrode Layer No. 2, the reinforcing film was formed with Reinforcing Film No. 2, and the barrier film was formed with Barrier Film No. 14, as shown in the following Table 12.

### Example 63

The solar cell module was fabricated in a manner similar to those of Example 58, except that the back electrode layer was formed with Back Electrode Layer No. 3, the reinforcing film was formed by Reinforcing Film No. 3, and then after Barrier Film No. 16 was formed, Barrier Film No. 1 was further formed thereon thereby forming a barrier film comprised of two layers, as shown in the following Table 12.

### Example 64

The solar cell module was fabricated in a manner similar to those of Example 58, except that the back electrode layer was formed with Back Electrode Layer No. 8, the reinforcing film was formed by Reinforcing Film No. 8, and then after Barrier Film No. 14 was formed, Barrier Film No. 6 was further formed thereon thereby forming a barrier film comprised of two layers, as shown in the following Table 12.

### Example 65

The solar cell module was fabricated in a manner similar to those of Example 58, except that the back electrode layer was formed with Back Electrode Layer No. 10, the reinforcing film was formed by Reinforcing Film No. 10, and then after Barrier Film No. 15 was formed, Barrier Film No. 7 was further formed thereon thereby forming a barrier film comprised of two layers, as shown in the following Table 12.

### Example 66

The solar cell module was fabricated in a manner similar to those of Example 58, except that the back electrode layer was formed with Back Electrode Layer No. 16, the reinforcing film was formed by Reinforcing Film No. 16, and then after Barrier Film No. 13 was formed, Barrier Film No. 10 was further formed thereon thereby forming a barrier film comprised of two layers, as shown in the following Table 12.

### Example 67

The solar cell module was fabricated in a manner similar to those of Example 58, except that the back electrode layer was formed with Back Electrode Layer No. 14, the reinforcing film was formed by Reinforcing Film No. 14, and then after Barrier Film No. 4 was formed, Barrier Film No. 16 was further formed thereon thereby forming a barrier film comprised of two layers, as shown in the following Table 12.

### Example 68

The solar cell module was fabricated in a manner similar to those of Example 58, except that the back electrode layer was formed with Back Electrode Layer No. 15, the reinforcing film was formed by Reinforcing Film No. 15, and then after Barrier Film No. 15 was formed, Barrier Film No. 1 and then Barrier Film No. 21 were further formed thereon thereby forming a barrier film comprised of three layers, as shown in the following Table 12.

### Example 69

The solar cell module was fabricated in a manner similar to those of Example 58, except that the back electrode layer was formed with Back Electrode Layer No. 9, the reinforcing film was formed by Reinforcing Film No. 9, and then after Barrier Film No. 17 was formed, Barrier Film No. 2 and then Barrier Film No. 19 were further formed thereon thereby forming a barrier film comprised of three layers, as shown in the following Table 12.

### Example 70

The solar cell module was fabricated in a manner similar to those of Example 58, except that the back electrode layer was formed with Back Electrode Layer No. 4, the reinforcing film was formed by Reinforcing Film No. 4, and then after Barrier Film No. 20 was formed, Barrier Film No. 18 and then Barrier Film No. 3 were further formed thereon thereby forming a barrier film comprised of three layers, as shown in the following Table 12.

### Example 71

The solar cell module was fabricated in a manner similar to those of Example 58, except that the back electrode layer was formed with Back Electrode Layer No. 12, the reinforcing film was formed by Reinforcing Film No. 12, and then after Barrier Film No. 13 was formed, Barrier Film No. 22 and then Barrier Film No. 5 were further formed thereon thereby forming a barrier film comprised of three layers, as shown in the following Table 12.

### Example 72

The solar cell module was fabricated in a manner similar to those of Example 58, except that the back electrode layer was formed with Back Electrode Layer No. 5, the reinforcing film was formed by Reinforcing Film No. 5, and then after Barrier Film No. 17 was formed, Barrier Film No. 20 and then Barrier Film No. 23 were further formed thereon thereby forming a barrier film comprised of three layers, as shown in the following Table 12.

### Example 73

The solar cell module was fabricated in a manner similar to those of Example 58, except that the back electrode layer was formed with Back Electrode Layer No. 11, the reinforcing film was formed by Reinforcing Film No. 11, and then Barrier Films No. 12, No. 9, No. 19, and No. 1 were further formed thereon in this order thereby forming a barrier film comprised of four layers, as shown in the following Table 12.

### Example 74

The solar cell module was fabricated in a manner similar to those of Example 58, except that the back electrode layer was formed with Back Electrode Layer No. 2, the reinforcing film was formed by Reinforcing Film No. 2, and then Barrier Films No. 18, No. 11, No. 22, and No. 4 were further formed thereon in this order thereby forming a barrier film comprised of four layers, as shown in the following Table 12.

### Example 75

The solar cell module was fabricated in a manner similar to those of Example 58, except that the back electrode layer was formed with Back Electrode Layer No. 6, the reinforcing film was formed by Reinforcing Film No. 6, and then Barrier Films No. 13, No. 6, No. 17, and No. 24 were further formed thereon in this order thereby forming a barrier film comprised of four layers, as shown in the following Table 12.

### Example 76

The solar cell module was fabricated in a manner similar to those of Example 58, except that the back electrode layer was formed with Back Electrode Layer No. 14, the reinforcing film was formed by Reinforcing Film No. 14, and then Barrier Films No. 14, No. 7, No. 12, No. 1, and No. 16 were further formed thereon in this order thereby forming a barrier film comprised of five layers, as shown in the following Table 12.

### Example 77

The solar cell module was fabricated in a manner similar to those of Example 58, except that the back electrode layer was formed with Back Electrode Layer No. 13, the reinforcing film was formed by Reinforcing Film No. 13, and then Barrier Films No. 20, No. 10, No. 20, No. 3, and No. 21 were further formed thereon in this order thereby forming a barrier film comprised of five layers, as shown in the following Table 12.

### Example 78

The solar cell module was fabricated in a manner similar to those of Example 58, except that the back electrode layer was formed with Back Electrode Layer No. 1, the reinforcing film was formed by Reinforcing Film No. 1, and then Barrier Films No. 15, No. 8, No. 18, No. 4, and No. 22 were further formed thereon in this order thereby forming a barrier film comprised of five layers, as shown in the following Table 12.

### Example 79

The solar cell module was fabricated in a manner similar to those of Example 58, except that the back electrode layer was formed with Back Electrode Layer No. 17, the reinforcing film was formed by Reinforcing Film No. 17, and then Barrier Films No. 17, No. 19, No. 4, No. 19, and No. 5 were further formed thereon in this order thereby forming a barrier film comprised of five layers, as shown in the following Table 12. In this Example, the electric generator layer 13 was made of the photoelectric conversion unit to be comprised of an amorphous silicon monolayer that was laminated, from the side of the insulative substrate 11, with a p-type a-Si (amorphous silicon), an i-type a-Si, and an n-type a-Si, in this order.

### Example 80

The solar cell module was fabricated in a manner similar to those of Example 58, except that the back electrode layer was formed with Back Electrode Layer No. 10, the reinforcing film was formed by Reinforcing Film No. 10, and then Barrier Films No. 13, No. 21, No. 2, No. 21, and No. 2 were further formed thereon in this order thereby forming a barrier film comprised of five layers, as shown in the following Table 12. In this Example, the electric generator layer 13 was made of the photoelectric conversion unit to be comprised of a microcrystalline silicon monolayer that was laminated, from the insulative substrate 11 side, with a p-type μc-Si (microcrystalline silicon), an i-type μc-Si, and an n-type μc-Si, in this order.

### Comparative Example 9

A titanium layer having thickness of 15 nm was formed as the back silver electrode reinforcing film in such a manner that the back silver electrode layer of the solar cell module that had already been processed in lamination might be covered; and then, after scribing with a laser processing method, EVA resin and PET film, as the barrier materials, were thermally adhered therewith. Comparative Example 9 relates to this solar cell module.

### Comparative Example 10

A titanium layer having thickness of 15 nm was formed as the back silver electrode reinforcing film in such a manner that the back electrode (silver) layer of the solar cell module that had already been processed in lamination might be covered; and then, after scribing with a laser processing method, EVA resin and Tedlar film (manufactured by E. I. du Pont de Nemours and Company), as the barrier materials, were thermally adhered therewith. Comparative Example 10 relates to this solar cell module.

TABLE 12

| | Back | | | | | | |
|---|---|---|---|---|---|---|---|
| | Elec- | | | | | | |
| | trode | Rein- | Barrier Film No. | | | | |
| | Layer | forcing | First | Second | Third | Fourth | Fifth |
| | No. | Film No. | layer | layer | layer | layer | layer |
| Example 58 | 12 | 12 | 1 | — | — | — | — |
| Example 59 | 1 | 1 | 12 | — | — | — | — |
| Example 60 | 13 | 13 | 4 | — | — | — | — |
| Example 61 | 7 | 7 | 7 | — | — | — | — |
| Example 62 | 2 | 2 | 14 | — | — | — | — |
| Example 63 | 3 | 3 | 16 | 1 | — | — | — |
| Example 64 | 8 | 8 | 14 | 6 | — | — | — |
| Example 65 | 10 | 10 | 15 | 7 | — | — | — |
| Example 66 | 16 | 16 | 13 | 10 | — | — | — |
| Example 67 | 14 | 14 | 4 | 16 | — | — | — |
| Example 68 | 15 | 15 | 15 | 1 | 21 | — | — |
| Example 69 | 9 | 9 | 17 | 2 | 19 | — | — |
| Example 70 | 4 | 4 | 20 | 18 | 3 | — | — |
| Example 71 | 12 | 12 | 13 | 22 | 5 | — | — |
| Example 72 | 5 | 5 | 17 | 20 | 23 | — | — |
| Example 73 | 11 | 11 | 12 | 9 | 19 | 1 | — |
| Example 74 | 2 | 2 | 18 | 11 | 22 | 4 | — |
| Example 75 | 6 | 6 | 13 | 6 | 17 | 24 | — |
| Example 76 | 14 | 14 | 14 | 7 | 12 | 1 | 16 |
| Example 77 | 13 | 13 | 20 | 10 | 20 | 3 | 21 |
| Example 78 | 1 | 1 | 15 | 8 | 18 | 4 | 22 |
| Example 79 | 17 | 17 | 17 | 19 | 4 | 19 | 5 |
| Example 80 | 10 | 10 | 13 | 21 | 2 | 21 | 2 |
| Comparative | — | — | — | — | — | — | — |
| Example 9 | | | | | | | |
| Comparative | — | — | — | — | — | — | — |
| Example 10 | | | | | | | |

### Comparative Tests 4 and Evaluations:

Each solar cell module of examples 58 to 80 and Comparative Examples 9 to 10 was evaluated as to the following items. The results are shown in the following Table 13.

### (1) Hygrothermal Cycle:

The hygrothermal cycle test between −40° C./one hour and 85° C./85% RH/four hours was repeated for 20 cycles; and then, appearance of the solar cell module after the test was observed.

### (2) Conversion Efficiency:

At first, lead wiring was made on the substrate after the solar cell module was worked out to make lines, and then an I-V (current-voltage) characteristic upon irradiation of light with AM 1.5 and 100 mW/cm² was measured by using a solar simulator and a digital source meter; and then, conversion efficiency was obtained based on calculated values. In this calculation, conversion efficiency was obtained as the relative value to Comparative Example 9, which was taken as 1.00.

### (3) Reliability Test:

The solar cell module was kept under atmosphere of 85° C. and 85% RH for 2000 hours; and conversion efficiencies of the solar cell module before and after the test were compared to obtain relative decrease rate.

### (4) Adhesion:

Adhesion of the barrier film was evaluated by the tape test method according to JIS K-5400. Specifically, evaluation was made based on degree of delamination or peel-off of the formed film when an adhesive tape was attached to and removed from a worked part, so that the classification was made into three groups: Good, Fair, and Unacceptable. Upon peeling-off of the tape, the film whose worked part did not change while only the tape being peeled-off was classified as “Good”; the film whose work scraps were partly attached to the tape but film surface was not changed was classified as “Fair”; and the film which was delaminated or peeled-off, or formed a space such as an air bubble in its interface, or was attached to the tape was classified as “Unacceptable”.

TABLE 13

| | | Conversion | Reliability test | |
|---|---|---|---|---|
| | | efficiency | (relative | |
| | Hygrothermal | (relative | decrease | |
| | cycle | value) | rate (%)) | Adhesion |
| Example 58 | No change | 1.11 | 5% or less | Good |
| Example 59 | No change | 1.07 | 5% or less | Good |
| Example 60 | No change | 1.18 | 5% or less | Good |
| Example 61 | No change | 1.13 | 5% or less | Good |
| Example 62 | No change | 1.04 | 5% or less | Good |
| Example 63 | No change | 1.05 | 5% or less | Good |
| Example 64 | No change | 1.15 | 5% or less | Good |
| Example 65 | No change | 1.09 | 5% or less | Good |
| Example 66 | No change | 1.12 | 5% or less | Good |
| Example 67 | No change | 1.12 | 5% or less | Good |
| Example 68 | No change | 1.41 | 5% or less | Good |
| Example 69 | No change | 1.23 | 5% or less | Good |
| Example 70 | No change | 1.19 | 5% or less | Good |
| Example 71 | No change | 1.31 | 5% or less | Good |
| Example 72 | No change | 1.33 | 5% or less | Good |
| Example 73 | No change | 1.39 | 5% or less | Good |
| Example 74 | No change | 1.24 | 5% or less | Good |
| Example 75 | No change | 1.29 | 5% or less | Good |
| Example 76 | No change | 1.21 | 5% or less | Good |
| Example 77 | No change | 1.19 | 5% or less | Good |
| Example 78 | No change | 1.22 | 5% or less | Good |
| Example 79 | No change | 1.39 | 5% or less | Good |
| Example 80 | No change | 1.42 | 5% or less | Good |
| Comparative | No change | 1.00 | 15% | Fair |
| Example 9 | | | | |
| Comparative | No change | 1.03 | 10% | Good |
| Example 10 | | | | |

As can be seen in Table 13, in comparison between Examples 58 to 80 and Comparative Examples 9 to. 10 in the hygrothermal test, it was confirmed that Examples 58 to 80 showed excellent humidity resistance in appearance, similarly to Comparable Examples 9 to 10, which were based on conventional methods. Especially in the reliability test, all of Examples 58 to 80 received high rating as compared with Comparative Example 9, so that it was confirmed that high humidity resistance could be obtained.

### Example 81

At first, as shown in FIG. 4, by a sputtering method, on the back electrode layer 16 (silver electrode layer) of the solar cell module that had already been processed in lamination was formed a titanium layer having thickness of 15 nm, which was made as the back electrode reinforcing film 17, in such a manner to cover the back electrode layer 16 (silver electrode layer). Then, patterning was made by irradiating a laser beam from the substrate 11 side at 50 μm laterally apart from the patterned position (separation groove 23) of the photoelectric conversion unit 13, as described later. Namely, the separation groove 18, extended from surface of the reinforcing film 17 to the front electrode layer 12, was formed by a laser scriber that blast-cut the photoelectric conversion unit 13, the transparent and conductive film 14, the back electrode layer 16, and the back electrode reinforcing film 17. Here, the separation process (formation of the separation groove 18) by using a laser scriber was conducted by using a Nd:YAG laser with energy density of 0.7 J/cm³ and pulse frequency of 4 kHz. Finally, the separation groove 18 was filled, and the single barrier film according to Barrier Film No. 1 of the above Table 3 was formed on the reinforcing film 17. Example 81 relates to this solar cell module.

Meanwhile, “the solar cell module that has already been processed in lamination” means the following state. At first, as shown in FIG. 4, a glass plate formed with a SiO₂ layer having thickness of 50 nm (not shown in the figure) on its one main surface is prepared as the substrate 11. Then, on surface of the SiO₂ layer was formed with a sputtering method the front electrode layer 12 (SnO₂ film) with thickness of 800 nm having surface of a concave-convex texture and doped with F (fluorine). The front electrode layer 12 is patterned with a laser processing method. Namely, separation process in strips was conducted by forming the separation groove 22. Here, the separation process (formation of the separation groove 22) by using a laser processing method was conducted by using a Nd:YAG laser with wavelength of about 1.06 μm, energy density of 13 J/cm³, and pulse frequency of 3 kHz. Then, on the front electrode layer 12 was formed the photoelectric conversion unit 13 with a plasma CVD method. In this Example, the photoelectric conversion unit 13 was made to have a tandem type structure comprised of two layers; an amorphous silicon layer laminated, in order, from the substrate 11 side, with a p-type a-Si (amorphous silicon), an i-type a-Si, and an n-type a-Si, and a microcrystalline silicon layer further laminated, on this amorphous silicon layer, with a p-type μc-Si (microcrystalline silicon), an i-type μc-Si, and an n-type μc-Si. Specifically, the amorphous silicon layer was formed with a plasma CVD method by laminating: a p-type a-Si having film thickness of 10 nm formed with a gas mixture of SiH₄, CH₄, H₂, and B₂H₆; an i-type a-Si having film thickness of 300 nm formed with a gas mixture of SiH₄ and H₂; and an n-type a-Si having film thickness of 20 nm formed with a gas mixture of SiH₄, H₂, and PH₃, in this order. The microcrystalline silicon layer was formed with a plasma CVD method by laminating: a p-type μc-Si having film thickness of 10 nm formed with a gas mixture of SiH₄, H₂, and B₂H₆; an i-type μc-Si having film thickness of 2000 nm formed with a gas mixture of SiH₄ and H₂; and an n-type μc-Si having film thickness of 20 nm formed with a gas mixture of SiH₄, H₂, and PH₃, in this order. Detailed conditions of the foregoing plasma CVD method are shown in the above Table 5. Further, the foregoing photoelectric conversion unit 13 was patterned into strips with a laser processing method. Namely, separation process was conducted to form the separation groove 23. The separation groove 23 was formed at 50 μm laterally apart from the patterned position of the front electrode layer 12. Then, on the photoelectric conversion unit 13 were formed the transparent and conductive film 14 (ZnO layer) having thickness of 80 nm and the back electrode layer 16 (silver electrode layer) having thickness of 200 nm, in this order, by using a magnetron in-line sputtering instrument. Here, the separation process (formation of the separation groove 23) by using a laser scriber was conducted by using a Nd:YAG laser with energy density of 0.7 J/cm³ and pulse frequency of 3 kHz.

### Example 82

The solar cell module was fabricated in a manner similar to those of Example 81, except that the barrier film was formed with Barrier Film No. 12, as shown in the following Table 14.

### Example 83

The solar cell module was fabricated in a manner similar to those of Example 81, except that the barrier film was formed with Barrier Film No. 4, as shown in the following Table 14.

### Example 84

The solar cell module was fabricated in a manner similar to those of Example 81, except that the barrier film was formed with Barrier Film No. 7, as shown in the following Table 14.

### Example 85

The solar cell module was fabricated in a manner similar to those of Example 81, except that the barrier film was formed with Barrier Film No. 14, as shown in the following Table 14.

### Example 86

The solar cell module was fabricated in a manner similar to those of Example 81, except that after Barrier Film No. 16 was formed, Barrier Film No. 1 was further formed thereon thereby forming a barrier film comprised of two layers, as shown in the following Table 14.

### Example 87

The solar cell module was fabricated in a manner similar to those of Example 81, except that after Barrier Film No. 14 was formed, Barrier Film No. 6 was further formed thereon thereby forming a barrier film comprised of two layers, as shown in the following Table 14.

### Example 88

The solar cell module was fabricated in a manner similar to those of Example 81, except that after Barrier Film No. 15 was formed, Barrier Film No. 7 was further formed thereon thereby forming a barrier film comprised of two layers, as shown in the following Table 14.

### Example 89

The solar cell module was fabricated in a manner similar to those of Example 81, except that after Barrier Film No. 13 was formed, Barrier Film No. 10 was further formed thereon thereby forming a barrier film comprised of two layers, as shown in the following Table 14.

### Example 90

The solar cell module was fabricated in a manner similar to those of Example 81, except that after Barrier Film No. 4 was formed, Barrier Film No. 16 was further formed thereon thereby forming a barrier film comprised of two layers, as shown in the following Table 14.

### Example 91

The solar cell module was fabricated in a manner similar to those of Example 81, except that after Barrier Film No. 15 was formed, Barrier Film No. 1 and Barrier film No. 21 were further formed thereon thereby forming a barrier film comprised of three layers, as shown in the following Table 14.

### Example 92

The solar cell module was fabricated in a manner similar to those of Example 81, except that after Barrier Film No. 17 was formed, Barrier Film No. 2 and Barrier film No. 19 were further formed thereon thereby forming a barrier film comprised of three layers, as shown in the following Table 14.

### Example 93

The solar cell module was fabricated in a manner similar to those of Example 81, except that after Barrier Film No. 20 was formed, Barrier Film No. 18 and Barrier film No. 3 were further formed thereon thereby forming a barrier film comprised of three layers, as shown in the following Table 14.

### Example 94

The solar cell module was fabricated in a manner similar to those of Example 81, except that after Barrier Film No. 13 was formed, Barrier Film No. 22 and Barrier film No. 5 were further formed thereon thereby forming a barrier film comprised of three layers, as shown in the following Table 14.

### Example 95

The solar cell module was fabricated in a manner similar to those of Example 81, except that after Barrier Film No. 17 was, formed, Barrier Film No. 20 and Barrier film No. 23 were further formed thereon thereby forming a barrier film comprised of three layers, as shown in the following Table 14.

### Example 96

The solar cell module was fabricated in a manner similar to those of Example 81, except that Barrier Film No. 12, Barrier Film No. 9, Barrier Film No. 19, and Barrier film No. 1 were formed in this order thereby forming a barrier film comprised of four layers, as shown in the following Table 14.

### Example 97

The solar cell module was fabricated in a manner similar to those of Example 81, except that Barrier Film No. 18, Barrier Film No. 11, Barrier Film No. 22, and Barrier film No. 4 were formed in this order thereby forming a barrier film comprised of four layers, as shown in the following Table 14.

### Example 98

The solar cell module was fabricated in a manner similar to those of Example 81, except that Barrier Film No. 13, Barrier Film No. 6, Barrier Film No. 17, and Barrier film No. 24 were formed in this order thereby forming a barrier film comprised of four layers, as shown in the following Table 14.

### Example 99

The solar cell module was fabricated in a manner similar to those of Example 81, except that Barrier Film No. 14, Barrier Film No. 7, Barrier Film No. 12, Barrier Film No. 1, and Barrier film No. 16 were formed in this order thereby forming a barrier film comprised of five layers, as shown in the following Table 14.

### Example 100

The solar cell module was fabricated in a manner similar to those of Example 81, except that Barrier Film No. 20, Barrier Film No. 10, Barrier Film No. 20, Barrier Film No. 3, and Barrier film No. 21 were formed in this order thereby forming a barrier film comprised of five layers, as shown in the following Table 14.

### Example 101

The solar cell module was fabricated in a manner similar to those of Example 81, except that Barrier Film No. 15, Barrier Film No. 8, Barrier Film No. 18, Barrier Film No. 4, and Barrier film No. 22 were formed in this order thereby forming a barrier film comprised of five layers, as shown in the following Table 14.

### Example 102

The solar cell module was fabricated in a manner similar to those of Example 81, except that Barrier Film No. 17, Barrier Film No. 19, Barrier Film No. 4, Barrier Film No. 19, and Barrier film No. 5 were formed in this order thereby forming a barrier film comprised of five layers, as shown in the following Table 14. In this Example, the electric generator layer 13 was made of the photoelectric conversion unit to be comprised of an amorphous silicon monolayer that was laminated, from the substrate 11 side, with a p-type a-Si (amorphous silicon), an i-type a-Si, and an n-type a-Si, in this order.

### Example 103

The solar cell module was fabricated in a manner similar to those of Example 81, except that Barrier Film No. 13, Barrier Film No. 21, Barrier Film No. 2, Barrier Film No. 21, and Barrier film No. 2 were formed in this order thereby forming a barrier film comprised of five layers, as shown in the following Table 14. In this Example, the electric generator layer 13 was made of the photoelectric conversion unit to be comprised of a microcrystalline silicon monolayer that was laminated, from the substrate 11 side, with a p-type μc-Si (microcrystalline silicon), an i-type μc-Si, and an n-type μc-Si, in this order.

### Comparative Example 11

A titanium layer having thickness of 15 nm was formed as the back silver electrode reinforcing film in such a manner that the back silver electrode layer of the solar cell module that had already been processed in lamination might be covered; and then, after scribing with a laser processing method, EVA resin and PET film, as the barrier materials, were thermally adhered thereon. Comparative Example 11 relates to this solar cell module.

### Comparative Example 12

A titanium layer having thickness of 15 nm was formed as the back silver electrode reinforcing film in such a manner that the back silver electrode layer of the solar cell module that had already been processed in lamination might be covered; and then, after scribing with a laser processing method, EVA resin and Tedlar film (manufactured by E. I. du Pont de Nemours and Company), as the barrier materials, were thermally adhered thereon. Comparative Example 12 relates to this solar cell module.

TABLE 14

| | Barrier Film No. | | | | |
|---|---|---|---|---|---|
| | First | Second | Third | Fourth | Fifth |
| | layer | layer | layer | layer | layer |
| Example 81 | 1 | — | — | — | — |
| Example 82 | 12 | — | — | — | — |
| Example 83 | 4 | — | — | — | — |
| Example 84 | 7 | — | — | — | — |
| Example 85 | 14 | — | — | — | — |
| Example 86 | 16 | 1 | — | — | — |
| Example 87 | 14 | 6 | — | — | — |
| Example 88 | 15 | 7 | — | — | — |
| Example 89 | 13 | 10 | — | — | — |
| Example 90 | 4 | 16 | — | — | — |
| Example 91 | 15 | 1 | 21 | — | — |
| Example 92 | 17 | 2 | 19 | — | — |
| Example 93 | 20 | 18 | 3 | — | — |
| Example 94 | 13 | 22 | 5 | — | — |
| Example 95 | 17 | 20 | 23 | — | — |
| Example 96 | 12 | 9 | 19 | 1 | — |
| Example 97 | 18 | 11 | 22 | 4 | — |
| Example 98 | 13 | 6 | 17 | 24 | — |
| Example 99 | 14 | 7 | 12 | 1 | 16 |
| Example 100 | 20 | 10 | 20 | 3 | 21 |
| Example 101 | 15 | 8 | 18 | 4 | 22 |
| Example 102 | 17 | 19 | 4 | 19 | 5 |
| Example 103 | 13 | 21 | 2 | 21 | 2 |
| Comparative | — | — | — | — | — |
| Example 11 | | | | | |
| Comparative | — | — | — | — | — |
| Example 12 | | | | | |

### Comparative Tests 5 and Evaluations:

Each solar cell module of examples 81 to 103 and Comparative Examples 11 to 12 was evaluated as to the following items. The results are shown in the following Table 15.

### (1) Hygrothermal Cycle:

The hygrothermal cycle test between −40° C./one hour and 85° C./85% RH/four hours was repeated for 20 cycles; and then, appearance of the solar cell module after the test was observed.

### (2) Conversion Efficiency:

At first, lead wiring was made on the substrate after the solar cell module was worked out to make lines, and then an I-V (current-voltage) characteristic upon irradiation of light with AM 1.5 and 100 mW/cm² was measured by using a solar simulator and a digital source meter; and then, conversion efficiency was obtained on the basis of calculated values. In this calculation, conversion efficiency was obtained as the relative value to Comparative Example 11, which was taken as 1

### (3) Reliability Test:

The solar cell module was kept under atmosphere of 85° C. and 85% RH for 2000 hours; and conversion efficiencies of the solar cell module before and after the test were compared to obtain relative decrease rate.

### (4) Adhesion:

Adhesion of the barrier film was evaluated by the tape test method according to JIS K-5400. Specifically, evaluation was made based on degree of delamination or peel-off of the formed film when an adhesive tape was attached to and removed from a worked part, so that the classification was made into three groups: Good, Fair, and Unacceptable. Upon peeling-off of the tape, the film whose worked part did not change while only the tape being peeled-off was classified as “Good”; the film whose work scraps were partly attached to the tape but film surface was not changed was classified as “Fair”; and the film which was delaminated or peeled-off, or formed a space such as an air bubble in its interface, or was attached to the tape was classified as “Unacceptable”.

TABLE 15

| | | Conversion | Reliability test | |
|---|---|---|---|---|
| | | efficiency | (relative | |
| | Hygrothermal | (relative | decrease | |
| | cycle | value) | rate (%)) | Adhesion |
| Example 81 | No change | 1.08 | 5% or less | Good |
| Example 82 | No change | 1.07 | 5% or less | Good |
| Example 83 | No change | 1.17 | 5% or less | Good |
| Example 84 | No change | 1.13 | 5% or less | Good |
| Example 85 | No change | 1.00 | 5% or less | Fair |
| Example 86 | No change | 1.03 | 5% or less | Good |
| Example 87 | No change | 1.15 | 5% or less | Good |
| Example 88 | No change | 1.08 | 5% or less | Good |
| Example 89 | No change | 1.12 | 5% or less | Good |
| Example 90 | No change | 1.09 | 5% or less | Good |
| Example 91 | Partly | 1.41 | 5% or less | Fair |
| | cracked | | | |
| | No color | | | |
| | change | | | |
| Example 92 | No change | 1.22 | 5% or less | Good |
| Example 93 | No change | 1.19 | 5% or less | Good |
| Example 94 | No change | 1.31 | 5% or less | Good |
| Example 95 | No change | 1.33 | 5% or less | Good |
| Example 96 | No change | 1.37 | 5% or less | Good |
| Example 97 | No change | 1.23 | 5% or less | Good |
| Example 98 | No change | 1.29 | 5% or less | Good |
| Example 99 | No change | 1.15 | 5% or less | Good |
| Example 100 | No change | 1.18 | 5% or less | Good |
| Example 101 | No change | 1.21 | 5% or less | Good |
| Example 102 | No change | 1.39 | 5% or less | Good |
| Example 103 | No change | 1.42 | 5% or less | Good |
| Comparative | No change | 1.0 | 15% | Fair |
| Example 11 | | | | |
| Comparative | No change | 1.03 | 10% | Good |
| Example 12 | | | | |

As can be seen in Table 15, in comparison between Examples 81 to 103 and Comparative Examples 11 to 12, in the hygrothermal test, it was confirmed that Examples 81 to 103 showed excellent humidity resistance in appearance, similarly to Comparable Examples 11 to 12, which were based on conventional methods, although partial crack was observed in Example 91. Especially in the reliability test, all of Examples 81 to 103 received high rating as compared with Comparative Example 11, and it was confirmed that high humidity resistance could be obtained.

### Example 104

At first, as shown in FIG. 4, with a sputtering method by using a magnetron in-line sputtering instrument, on the photoelectric conversion unit 13 of the solar cell module that had already been processed in lamination was formed a ZnO film having thickness of 80 nm, which was made as the transparent and conductive film 14. Then, the back electrode layer 16 (silver electrode layer) according to Back Electrode Layer No. 12 of the above Table 1 was formed. With a sputtering method by using a magnetron in-line sputtering instrument, on this back electrode layer 16 was formed a titanium layer having thickness of 15 nm, which was made as the reinforcing film 17 of the back electrode layer, in such a manner to cover the back electrode layer 16 (silver electrode layer). Then, patterning was made by irradiating a laser beam from the substrate 11 side at 50 μm laterally apart from the patterned position (separation groove 23) of the photoelectric conversion unit 13, as described later. Namely, separation process into strips was conducted by forming the separation groove 18, extended from surface of the reinforcing film 17 to the front electrode layer 12, by a laser scriber that blast-cut the photoelectric conversion unit 13, the transparent and conductive film 14, the back electrode layer 16, and the back electrode reinforcing film 17. Here, the separation process (formation of the separation groove 18) by using a laser scriber was conducted by using a Nd:YAG laser with energy density of 0.7 J/cm³ and pulse frequency of 4 kHz. Finally, the separation groove 18 was filled, and the single barrier film 19 according to Barrier Film No. 1 of the above Table 3 was formed on the reinforcing film 17. Example 104 relates to this solar cell module.

Meanwhile, “the solar cell module that has already been processed in lamination” means the following state. At first, as shown in FIG. 4, a glass plate formed with a SiO₂ layer having thickness of 50 nm (not shown in the figure) on its one main surface is prepared as the substrate 11. Then, on surface of the SiO₂ layer was formed with a sputtering method the front electrode layer 12 (SnO₂ film) with thickness of 800 nm having surface of a concave-convex texture and doped with F (fluorine). The front electrode layer 12 is patterned with a laser processing method. Namely, separation process in strips was conducted by forming the separation groove 22. Here, the separation process (formation of the separation groove 22) by using a laser processing method was conducted by using a Nd:YAG laser with wavelength of about 1.06 μm, energy density of 13 J/cm³, and pulse frequency of 3 kHz. Then, on the front electrode layer 12 was formed the photoelectric conversion unit 13 with a plasma CVD method. In this Example, the photoelectric conversion unit 13 was made to have a tandem type structure comprised of two layers; an amorphous silicon layer laminated, in order, from the substrate 11 side, with a p-type a-Si (amorphous silicon), an i-type a-Si, and an n-type a-Si, and a microcrystalline silicon layer further laminated, on this amorphous silicon layer, with a p-type μc-Si (microcrystalline silicon), an i-type μc-Si, and an n-type μc-Si. Specifically, the amorphous silicon layer was formed with a plasma CVD method by laminating: a p-type a-Si having film thickness of 10 nm formed with a gas mixture of SiH₄, CH₄, H₂, and B₂H₆; an i-type a-Si having film thickness of 300 nm formed with a gas mixture of SiH₄ and H₂; and an n-type a-Si having film thickness of 20 nm formed with a gas mixture of SiH₄, H₂, and PH₃, in this order. The microcrystalline silicon layer was formed with a plasma CVD method by laminating: a p-type μc-Si having film thickness of 10 nm formed with a gas mixture of SiH₄, H₂, and B₂H₆; an i-type μc-Si having film thickness of 2000 nm formed with a gas mixture of SiH₄ and H₂; and an n-type μc-Si having film thickness of 20 nm formed with a gas mixture of SiH₄, H₂, and PH₃, in this order. Detailed conditions of the foregoing plasma CVD method are shown in the above Table 5. Further, the foregoing photoelectric conversion unit 13 was patterned into strips with a laser processing method. Namely, separation process was conducted to form the separation groove 23. The separation groove 23 was formed at 50 μm laterally apart from the patterned position of the front electrode layer 12. Here, the separation process (formation of the separation groove 23) by using a laser scriber was conducted by using a Nd:YAG laser with energy density of 0.7 J/cm³ and pulse frequency of 3 kHz.

### Example 105

The solar cell module was fabricated in a manner similar to those of Example 104, except that the back electrode layer was formed with Back Electrode Layer No. 1 and the barrier film was formed with Barrier Film No. 12, as shown in the following Table 16.

### Example 106

The solar cell module was fabricated in a manner similar to those of Example 104, except that the back electrode layer was formed with Back Electrode Layer No. 13 and the barrier film was formed with Barrier Film No. 4, as shown in the following Table 16.

### Example 107

The solar cell module was fabricated in a manner similar to those of Example 104, except that the back electrode layer was formed with Back Electrode Layer No. 7 and the barrier film was formed with Barrier Film No. 7, as shown in the following Table 16.

### Example 108

The solar cell module was fabricated in a manner similar to those of Example 104, except that the back electrode layer was formed with Back Electrode Layer No. 2 and the barrier film was formed with Barrier Film No. 14, as shown in the following Table 16.

### Example 109

The solar cell module was fabricated in a manner similar to those of Example 104, except that the back electrode layer was formed with Back Electrode Layer No. 3, and then after Barrier Film No. 16 was formed, Barrier. Film No. 1 was further formed thereon thereby forming a barrier film comprised of two layers, as shown in the following Table 16.

### Example 110

The solar cell module was fabricated in a manner similar to those of Example 104, except that the back electrode layer was formed with Back Electrode Layer No. 8, and then after Barrier Film No. 14 was formed, Barrier Film No. 6 was further formed thereon thereby forming a barrier film comprised of two layers, as shown in the following Table 16.

### Example 111

The solar cell module was fabricated in a manner similar to those of Example 104, except that the back electrode layer was formed with Back Electrode Layer No. 10, and then after Barrier Film No. 15 was formed, Barrier Film No. 7 was further formed thereon thereby forming a barrier film comprised of two layers, as shown in the following Table 16.

### Example 112

The solar cell module was fabricated in a manner similar to those of Example 104, except that the back electrode layer was formed with Back Electrode Layer No. 16, and then after Barrier Film No. 13 was formed, Barrier Film No. 10 was further formed thereon thereby forming a barrier film comprised of two layers, as shown in the following Table 16.

### Example 113

The solar cell module was fabricated in a manner similar to those of Example 104, except that the back electrode layer was formed with Back Electrode Layer No. 14, and then after Barrier Film No. 4 was formed, Barrier Film No. 16 was further formed thereon thereby forming a barrier film comprised of two layers, as shown in the following Table 16.

### Example 114

The solar cell module was fabricated in a manner similar to those of Example 104, except that the back electrode layer was formed with Back Electrode Layer No. 15, and then after Barrier Film No. 15 was formed, Barrier Film No. 1 and then Barrier Film No. 21 were further formed thereon thereby forming a barrier film comprised of three layers, as shown in the following Table 16.

### Example 115

The solar cell module was fabricated in a manner similar to those of Example 104, except that the back electrode layer was formed with Back Electrode Layer No. 9, and then after Barrier Film No. 17 was formed, Barrier Film No. 2 and then Barrier Film No. 19 were further formed thereon thereby forming a barrier film comprised of three layers, as shown in the following Table 16.

### Example 116

The solar cell module was fabricated in a manner similar to those of Example 104, except that the back electrode layer was formed with Back Electrode Layer No. 4, and then after Barrier Film No. 20 was formed, Barrier Film No. 18 and then Barrier Film No. 3 were further formed thereon thereby forming a barrier film comprised of three layers, as shown in the following Table 16.

### Example 117

The solar cell module was fabricated in a manner similar to those of Example 104, except that the back electrode layer was formed with Back Electrode Layer No. 12, and then after Barrier Film No. 13 was formed, Barrier Film No. 22 and then Barrier Film No. 5 were further formed thereon thereby forming a barrier film comprised of three layers, as shown in the following Table 16.

### Example 118

The solar cell module was fabricated in a manner similar to those of Example 104, except that the back electrode layer was formed with Back Electrode Layer No. 5, and then after Barrier Film No. 17 was formed, Barrier Film No. 20 and then Barrier Film No. 23 were further formed thereon thereby forming a barrier film comprised of three layers, as shown in the following Table 16.

### Example 119

The solar cell module was fabricated in a manner similar to those of Example 104, except that the back electrode layer was formed with Back Electrode Layer No. 11, and then Barrier Films No. 12, No. 9, No. 19, and No. 1 were further formed thereon in this order thereby forming a barrier film comprised of four layers, as shown in the following Table 16.

### Example 120

The solar cell module was fabricated in a manner similar to those of Example 104, except that the back electrode layer was formed with Back Electrode Layer No. 2, and then Barrier Films No. 18, No. 11, No. 22, and No. 4 were further formed thereon in this order thereby forming a barrier film comprised of four layers, as shown in the following Table 16.

### Example 121

The solar cell module was fabricated in a manner similar to those of Example 104, except that the back electrode layer was formed with Back Electrode Layer No. 6, and then Barrier Films No. 13, No. 6, No. 17, and No. 24 were further formed thereon in this order thereby forming a barrier film comprised of four layers, as shown in the following Table 16.

### Example 122

The solar cell module was fabricated in a manner similar to those of Example 104, except that the back electrode layer was formed with Back Electrode Layer No. 14, and then Barrier Films No. 14, No. 7, No. 12, No. 1, and No. 16 were further formed thereon in this order thereby forming a barrier film comprised of five layers, as shown in the following Table 16.

### Example 123

The solar cell module was fabricated in a manner similar to those of Example 104, except that the back electrode layer was formed with Back Electrode Layer No. 13, and then Barrier Films No. 20, No. 10, No. 20, No. 3, and No. 21 were further formed thereon in this order thereby forming a barrier film comprised of five layers, as shown in the following Table 16.

### Example 124

The solar cell module was fabricated in a manner similar to those of Example 104, except that the back electrode layer was formed with Back Electrode Layer No. 1, and then Barrier Films No. 15, No. 8, No. 18, No. 4, and No. 22 were further formed thereon in this order thereby forming a barrier film comprised of five layers, as shown in the following Table 16.

### Example 125

The solar cell module was fabricated in a manner similar to those of Example 104, except that the back electrode layer was formed with Back Electrode Layer No. 17, and then Barrier Films No. 17, No. 19, No. 4, No. 19, and No. 5 were further formed thereon in this order thereby forming a barrier film comprised of five layers, as shown in the following Table 16. In this Example, the electric generator layer was made of the photoelectric conversion unit 13 to be comprised of an amorphous silicon monolayer that was laminated, from the insulative substrate 11 side, with a p-type a-Si (amorphous silicon), an i-type a-Si, and an n-type a-Si, in this order.

### Example 126

The solar cell module was fabricated in a manner similar to those of Example 104, except that the back electrode layer was formed with Back Electrode Layer No. 10, and then Barrier Films No. 13, No. 21, No. 2, No. 21, and No. 2 were further formed thereon in this order thereby forming a barrier film comprised of five layers, as shown in the following Table 16. In this Example, the electric generator layer was made of the photoelectric conversion unit 13 to be comprised of a microcrystalline silicon monolayer that was laminated, from the insulative substrate 11 side, with a p-type μc-Si (microcrystalline silicon), an i-type μc-Si, and an n-type μc-Si, in this order.

### Comparative Example 13

A titanium layer having thickness of 15 nm was formed as the back silver electrode reinforcing film in such a manner that the back silver electrode layer of the solar cell module that had already been processed in lamination might be covered; and then, after scribing with a laser processing method, EVA resin and PET film, as the barrier materials, were thermally adhered thereon. Comparative Example 13 relates to this solar cell module.

### Comparative Example 14

A titanium layer having thickness of 15 nm was formed as the back silver electrode reinforcing film in such a manner that the back silver electrode layer of the solar cell module that ‘had already been processed in lamination might be covered; and then, after scribing with a laser processing method, EVA resin and Tedlar film (manufactured by E. I. du Pont de Nemours and Company), as the barrier materials, were thermally adhered thereon. Comparative Example 14 relates to this solar cell module.

TABLE 16

| | Back | Barrier Film No. | | | | |
|---|---|---|---|---|---|---|
| | Electrode | First | Second | Third | Fourth | Fifth |
| | Layer No. | layer | layer | layer | layer | layer |
| Example 104 | 12 | 1 | — | — | — | — |
| Example 105 | 1 | 12 | — | — | — | — |
| Example 106 | 13 | 4 | — | — | — | — |
| Example 107 | 7 | 7 | — | — | — | — |
| Example 108 | 2 | 14 | — | — | — | — |
| Example 109 | 3 | 16 | 1 | — | — | — |
| Example 110 | 8 | 14 | 6 | — | — | — |
| Example 111 | 10 | 15 | 7 | — | — | — |
| Example 112 | 16 | 13 | 10 | — | — | — |
| Example 113 | 14 | 4 | 16 | — | — | — |
| Example 114 | 15 | 15 | 1 | 21 | — | — |
| Example 115 | 9 | 17 | 2 | 19 | — | — |
| Example 116 | 4 | 20 | 18 | 3 | — | — |
| Example 117 | 12 | 13 | 22 | 5 | — | — |
| Example 118 | 5 | 17 | 20 | 23 | — | — |
| Example 119 | 11 | 12 | 9 | 19 | 1 | — |
| Example 120 | 2 | 18 | 11 | 22 | 4 | — |
| Example 121 | 6 | 13 | 6 | 17 | 24 | — |
| Example 122 | 14 | 14 | 7 | 12 | 1 | 16 |
| Example 123 | 13 | 20 | 10 | 20 | 3 | 21 |
| Example 124 | 1 | 15 | 8 | 18 | 4 | 22 |
| Example 125 | 17 | 17 | 19 | 4 | 19 | 5 |
| Example 126 | 10 | 13 | 21 | 2 | 21 | 2 |
| Comparative | — | — | — | — | — | — |
| Example 13 | | | | | | |
| Comparative | — | — | — | — | — | — |
| Example 14 | | | | | | |

### Comparative Test 6 and Evaluations:

Each solar cell module of examples 104 to 126 and Comparative Examples 13 to 14 was evaluated as to the following items. The results are shown in the following Table 17.

### (1) Hygrothermal Cycle:

The hygrothermal cycle test between −40° C./one hour and 85° C./85% RH/four hours was repeated for 20 cycles; and then, appearance of the solar cell module after the test was observed.

### (2) Conversion Efficiency:

At first, lead wiring was made on the substrate after the solar cell module was worked out to make lines, and then an I-V (current-voltage) characteristic upon irradiation of light with AM 1.5 and 100 mW/cm² was measured by using a solar simulator and a digital source meter; and then, conversion efficiency was obtained on the basis of calculated values. In this calculation, conversion efficiency was obtained as the relative value to Comparative Example 13, which was taken as 1.00.

### (3) Reliability Test:

The solar cell module was kept under atmosphere of 85° C. and 85% RH for 2000 hours; and conversion efficiencies of the solar cell module before and after the test were compared to obtain relative decrease rate.

### (4) Adhesion:

Adhesion of the barrier film was evaluated by the tape test method according to JIS K-5400. Specifically, evaluation was made based on degree of conditions of delamination or peel-off of the formed film when an adhesive tape was attached to and removed from a worked part, so that the classification was made into three groups: Good, Fair, and Unacceptable. Upon peeling-off of the tape, the film whose worked part did not change while only the tape being peeled-off was classified as “Good”; the film whose work scraps were partly attached to the tape but film surface was not changed was classified as “Fair”; and the film which was delaminated or peeled-off, or formed a space such as an air bubble in its interface, or was attached to the tape was classified as “Unacceptable”.

TABLE 17

| | | Conversion | Reliability test | |
|---|---|---|---|---|
| | | efficiency | (relative | |
| | Hygrothermal | (relative | decrease | |
| | cycle | value) | rate (%)) | Adhesion |
| Example 104 | No change | 1.12 | 5% or less | Good |
| Example 105 | No change | 1.07 | 5% or less | Good |
| Example 106 | No change | 1.18 | 5% or less | Good |
| Example 107 | No change | 1.13 | 5% or less | Good |
| Example 108 | No change | 1.04 | 5% or less | Good |
| Example 109 | No change | 1.07 | 5% or less | Good |
| Example 110 | No change | 1.15 | 5% or less | Good |
| Example 111 | No change | 1.09 | 5% or less | Good |
| Example 112 | No change | 1.12 | 5% or less | Good |
| Example 113 | No change | 1.19 | 5% or less | Good |
| Example 114 | No change | 1.41 | 5% or less | Fair |
| Example 115 | No change | 1.23 | 5% or less | Good |
| Example 116 | No change | 1.19 | 5% or less | Good |
| Example 117 | No change | 1.31 | 5% or less | Good |
| Example 118 | No change | 1.33 | 5% or less | Good |
| Example 119 | No change | 1.39 | 5% or less | Good |
| Example 120 | No change | 1.24 | 5% or less | Good |
| Example 121 | No change | 1.29 | 5% or less | Good |
| Example 122 | No change | 1.21 | 5% or less | Good |
| Example 123 | No change | 1.19 | 5% or less | Good |
| Example 124 | No change | 1.22 | 5% or less | Good |
| Example 125 | No change | 1.39 | 5% or less | Good |
| Example 126 | No change | 1.42 | 5% or less | Good |
| Comparative | No change | 1.00 | 15 | Fair |
| Example 13 | | | | |
| Comparative | No change | 1.03 | 10 | Good |
| Example 14 | | | | |

As can be seen in Table 17, in comparison between Examples 104 to 126 and Comparative Examples 13 to 14, in the hygrothermal test, it was confirmed that Examples 104 to 126 showed excellent humidity resistance in appearance, similarly to Comparable Examples 13 to 14, which were based on conventional methods. Especially in the reliability test, all of Examples 104 to 126 received high rating as compared with Comparative Example 13, and it was confirmed that high humidity resistance could be obtained.

### INDUSTRIAL APPLICABILITY

The method of producing a solar cell module of the present invention can be used to produce a solar cell with small deterioration of power generation efficiency under high moisture environment and with stable performance for a long period of time.

### DESCRIPTION OF SYMBOLS

10, 50 Solar cell module
11 Substrate
12 Front electrode layer
13, 53 Photoelectric conversion unit
14 Transparent and conductive film
15, 55 Photovoltaic element
16 Back electrode layer
17 Back electrode reinforcing film
19 Filler layer
24 Barrier film

1. A method of producing a solar cell module, wherein the method comprises:
a step of forming a transparent and conductive front electrode layer on a substrate,
a step of forming, on the front electrode layer, one, or two or more of a photoelectric conversion unit that generates an electric power by a light,
a step of forming, on the photoelectric conversion unit, a transparent and conductive film,
a step of forming, on the transparent and conductive film, a back electrode layer, and
a step of forming, on the back electrode layer, a back electrode reinforcing film by UV-irradiation of, or by heating of, or by heating after UV-irradiation of a layer that is obtained by applying a composition for reinforcing film with a wet coating method.

2. The method of producing a solar cell module according to claim 1, wherein the photoelectric conversion unit includes one, or two or more layers of any one of an amorphous silicon layer and a microcrystalline silicon layer, or one or more layers in each of the amorphous silicon layer and the microcrystalline silicon layer.

3. The method of producing a solar cell module according to claim 1, wherein the composition for reinforcing film contains any one of an organic-based or an inorganic-based material of a polymer type binder and an inorganic-based material of a non-polymer type binder or both, wherein the materials are curable by UV-irradiation, or by heating, or by heating after UV-irradiation.

4. The method of producing a solar cell module according to claim 1, wherein the method further includes, after the step of forming the back electrode reinforcing film, a step of forming, on the reinforcing film, a barrier film by UV-irradiation of, or by heating of, or by heating after UV-irradiation of a layer that is obtained by applying a composition for barrier film on the reinforcing film with a wet coating method.

5. The method of producing a solar cell module according to claim 4, wherein the composition for barrier film contains any one of an organic-based or an inorganic-based material of a polymer type binder and an inorganic-based material of a non-polymer type binder or both, wherein the materials are curable by UV-irradiation, or by heating, or by heating after UV-irradiation.

6. The method of producing a solar cell module according to claim 4, wherein the barrier film is formed by alternately layering one, or two or more inorganic barrier films, using a composition for barrier film that contains an inorganic-based material of a polymer type binder or an inorganic-based material of a non-polymer type binder, and one, or two or more organic barrier films, using a composition for barrier film that contains an organic-based material of a polymer type.

7. The method of producing a solar cell module according to claim 1, wherein the composition for reinforcing film contains one, or two or more kinds of metal oxide microparticles or planular particles selected from the group consisting of colloidal silica, fumed silica particles, silica particles, mica particles, and smectite particles.

8. The method of producing a solar cell module according to claim 4, wherein the composition for barrier film contains one, or two or more kinds of metal oxide microparticles or planular particles selected from the group consisting of colloidal silica, fumed silica particles, silica particles, mica particles, and smectite particles.

9. The method of producing a solar cell module according to claim 1, wherein the composition for reinforcing film contains microparticles or planular microparticles containing one, or two or more metals, or metal oxides of a metal, selected from the group consisting of gold, platinum, palladium, ruthenium, nickel, copper, tin, indium, zinc, iron, chromium, manganese, and aluminum, with amount of the metal or the metal oxide in the microparticles or planular microparticles being 70% or more by mass.

10. The method of producing a solar cell module according to claim 4, wherein the composition for barrier film contains microparticles or planular microparticles containing one, or two or more metals, or metal oxides of a metal, selected from the group consisting of gold, platinum, palladium, ruthenium, nickel, copper, tin, indium, zinc, iron, chromium, manganese, and aluminum, with amount of the metal or the metal oxide in the microparticles or planular microparticles being 70% or more by mass.

11. The method of producing a solar cell module according to claim 1, wherein the back electrode layer is formed by heating a layer that is obtained by applying a silver-containing composition for electrode on the transparent and conductive film with a wet coating method.

12. The method of producing a solar cell module according to claim 1, wherein thickness of the back electrode reinforcing film is 0.2 to 1 fold relative to thickness of the back electrode layer.

13. The method of producing a solar cell module according to claim 1, wherein
thickness of the transparent and conductive film is in the range between 0.03 and 0.5 μm,
thickness of the back electrode layer is in the range between 0.05 and 2.0 μm, and
thickness of the back electrode reinforcing film formed by UV-irradiation, or by heating at temperature of 120 to 140° C., or by heating at temperature of 120 to 140° C. after UV-irradiation, of the composition for reinforcing film is in the range between 0.01 and 2.0 μm.

14. The method of producing a solar cell module according to claim 4, wherein thickness of the barrier film formed by UV-irradiation, or by heating at temperature of 120 to 400° C., or by heating at temperature of 120 to 400° C. after UV-irradiation, of the composition for barrier film is in the range between 0.2 and 20 μm.

15. The method of producing a solar cell module according to claim 1, wherein a photovoltaic element is comprised of the front electrode layer formed on the substrate, the photoelectric conversion unit, a transparent electrode layer, and the back electrode layer; a plurality of the photovoltaic elements are formed on the substrate with a space; a plurality of the photovoltaic elements are connected electrically in series; and a filler layer is formed in the space.

16. The method of producing a solar cell module according to claim 4, wherein a photovoltaic element is comprised of the front electrode layer formed on the substrate, the photoelectric conversion unit, a transparent electrode layer, and the back electrode layer; a plurality of the photovoltaic elements are formed on the substrate with a space; a plurality of the photovoltaic elements are connected electrically in series; and the barrier film is formed in the space.

17. A method of producing a solar cell module, wherein the method comprises:
a step of forming a transparent and conductive front electrode layer on a substrate,
a step of forming, on the front electrode layer, one, or two or more of a photoelectric conversion unit that generates an electric power by a light,
a step of forming, on the photoelectric conversion unit, a transparent and conductive film,
a step of forming, on the transparent and conductive film, a back electrode layer, and
a step of forming, on the back electrode layer, a barrier film by UV-irradiation of, or by heating of, or by heating after UV-irradiation of a layer that is obtained by applying a composition for barrier film with a wet coating method.

18. The method of producing a solar cell module according to claim 17, wherein the photoelectric conversion unit includes one, or two or more layers of any one of an amorphous silicon layer and a microcrystalline silicon layer, or one or more layers of both of the amorphous silicon layer and the microcrystalline silicon layer.

19. The method of producing a solar cell module according to claim 17, wherein the composition for barrier film contains any one of an organic-based or an inorganic-based material of a polymer type binder and an inorganic-based material of a non-polymer type binder or both, wherein the materials are curable by UV-irradiation, or by heating, or by heating after UV-irradiation.

20. The method of producing a solar cell module according to claim 17, wherein the barrier film is formed by alternately layering one, or two or more inorganic barrier films, using a composition for barrier film that contains an inorganic-based material of a polymer type binder or an inorganic-based material of a non-polymer type binder, and one, or two or more organic barrier films, using a composition for barrier film that contains an organic-based material of a polymer type.

21. The method of producing a solar cell module according to claim 17, wherein the composition for barrier film contains one, or two or more kinds of metal oxide microparticles or planular particles selected from the group consisting of colloidal silica, fumed silica particles, silica particles, mica particles, and smectite particles.

22. The method of producing a solar cell module according to claim 17, wherein the composition for barrier film contains microparticles or planular microparticles containing one, or two or more metals, or metal oxides of a metal, selected from the group consisting of gold, platinum, palladium, ruthenium, nickel, copper, tin, indium, zinc, iron, chromium, manganese, and aluminum, with amount of the metal or the metal oxide in the microparticles or planular microparticles being 70% or more by mass.

23. The method of producing a solar cell module according to claim 17, wherein the back electrode layer is formed by heating a layer that is obtained by applying a silver-containing composition for electrode on the transparent and conductive film with a wet coating method.

24. The method of producing a solar cell module according to claim 17, wherein
thickness of the transparent and conductive film is in the range between 0.03 and 0.5 μm,
thickness of the back electrode layer is in the range between 0.05 and 2.0 μm, and
thickness of the barrier film formed by UV-irradiation, or by heating at temperature of 120 to 400° C., or by heating at temperature of 120 to 400° C. after UV-irradiation, of the composition for barrier film is in the range between 0.2 and 20 μm.

25. The method of producing a solar cell module according to claim 17, wherein a photovoltaic element is comprised of the front electrode layer formed on the substrate, the photoelectric conversion unit, a transparent electrode layer, and the back electrode layer; a plurality of the photovoltaic elements are formed on the substrate with a space; a plurality of the photovoltaic elements are connected electrically in series; and the barrier film is formed in the space.
